(19) United States
(12) Patent Application Publication
(10) Pub. No.: US 2024/0132739 A1
(43) Pub. Date: Apr. 25, 2024

(54) OPTIMIZED SOLVENT-BASED LIQUID METAL COMPOSITIONS AND METHODS OF USING SAME

(71) Applicant: Meta Platforms Technologies, LLC, Menlo Park, CA (US)

(72) Inventors: Omar Awartani, Redmond, WA (US); Marcos Antonio Santana Andrade, JR., Seattle, WA (US); Wenyang Pan, Redmond, WA (US); Kristopher Erickson, Sammamish, WA (US); Thomas John Farrell Wallin, Redmond, WA (US)

(21) Appl. No.: 18/479,782

(22) Filed: Oct. 2, 2023

Related U.S. Application Data
(60) Provisional application No. 63/412,336, filed on Sep. 30, 2022.
(60) Provisional application No. 63/412,338, filed on Sep. 30, 2022.

(51) Int. Cl. C09D 11/54; C22C 28/00; H05K 1/02

(52) U.S. Cl. CPC C09D 11/54; C22C 28/00; H05K 1/028

(57) ABSTRACT

An optimized solvent-based liquid metal composition includes a solution and a liquid metal mixed with the solution. The solution includes at least one solvent and a polymeric binder dissolved in the at least one solvent. Additionally or optionally, the composition includes a metallic filler. The ingredients of the composition are tailored to extend decap time while maintaining other beneficial properties to permit the use of the composition in various printing techniques.

### CROSS-REFERENCE TO RELATED APPLICATION

The present application claims priority to U.S. Provisional Patent Application No. 63/412,336, entitled “Optimized Solvent-Based Liquid Metal Compositions And Methods Of Using Same,” filed Sep. 30, 2022, and U.S. Provisional Patent Application No. 63/412,338, entitled “Optimized Solvent-Based Liquid Metal Compositions And Methods Of Using Same,” filed Sep. 30, 2022, each of which is hereby incorporated by reference in its entirety for all purposes.

### FIELD OF THE PRESENT DISCLOSURE

The present application relates to solvent-based liquid metal compositions and methods of using the same.

### BACKGROUND

Liquid metal (LM) inks are very promising for making printable, highly stretchable, and conductive traces within electronic circuits. However, conventional LM inks are based on a solution of styrene isoprene styrene (SIS) dissolved in toluene. SIS has the lowest hardness and lowest viscosity of all the styrenic block copolymers. It is easy to process and compatible with various tackifying chemistries. Toluene is a volatile, low boiling point solvent. As a result, these LM inks have a short decap time, a time that print nozzles distributing LM can be uncovered and idle before requiring wiping or purging. For instance, many existing LM inks have a decap time of about a minute or less. This creates challenges in direct ink writing or stencil printing where longer decap times are required. Moreover, most existing LM inks dry too fast to be viable for scalable solutions.

Accordingly, there is a need in the art for suitable solutions to extend decap times without sacrificing other beneficial properties of LM inks so that they can be used in various printing techniques.

### SUMMARY

One aspect of the present disclosure provides an optimized solvent-based liquid metal composition including a solution and a liquid metal mixed with the solution. The solution includes at least one solvent and a polymeric binder dissolved in the at least one solvent. In some embodiments, additionally or optionally, the composition includes a metallic filler. The composition is tailored to extend the decap time while maintaining other beneficial properties, such as viscosity, electrical conductivity, or the like, to permit the use of the composition in various printing techniques. In some embodiments, the composition has a decap time of at least 1 minute, at least 2 minutes, at least 5 minutes, at least 15 minutes, at least 20 minutes, at least half an hour, at least 1 hour, at least 2 hours, at least 3 hours, at least 4 hours, at least 5 hours, or greater than 5 hours.

In certain embodiments, the at least one solvent includes a first solvent and the first solvent includes TXIB. In such embodiments, the polymeric binder can be any suitable polymer or polymer mixture, including but not limited to styrene isoprene styrene (SIS), styrene ethylene butylene styrene (SEBS), silicones or any combination thereof disclosed herein.

In some embodiments, the at least one solvent includes the first solvent of about 100% by volume.

Alternatively, in some embodiments, the at least one solvent is a solvent mixture including two, three, four or more than four solvents. For instance, the at least one solvent includes a second solvent. In an embodiment, the second solvent is toluene. In another embodiment, the second solvent is THF, cycolohexane, xylene, decane, or octyle acelate. In some embodiments, the at least one solvent includes the first solvent at an amount from about 3% to about 5%, from about 5% to 10%, from about 10% to 20%, from about 30% to 40%, from about 40% to 50%, or more than 50% by volume. In an embodiment, the first solvent is TXIB, the second solvent is toluene, and TXIB is at an amount from about 2% to about 5%, from about 5% to 10%, or from about 10% to 20% by volume of toluene.

In certain embodiments, the polymeric binder includes a first polymer, and the first polymer includes SEBS. In such embodiments, the at least one solvent can be any suitable solvent or solvent mixture, including but not limited to toluene, THF, cycolohexane, xylene, decane, octyle acelate, TXIB, or any combination thereof disclosed herein.

In some embodiments, the first polymer has a molecular weight of greater than 50 kg/mol, greater than about 100 kg/mol, greater than about 150 kg/mol, greater than about 200 kg/mol, greater than about 250 kg/mol, greater than about 300 kg/mol, greater than about 350 kg/mol, or greater than about 400 kg/mol. In some embodiments, the styrene content in the first polymer is from about 10 wt % to about 15 wt %, from about 15 wt % to about 20 wt %, from about 25 wt % to about 30 wt %, from about 30 wt % to about 35 wt %, from about 35 wt % to about 40 wt %, or from about 40 wt % to about 45 wt % of the first polymer. In some embodiments, a styrene block in the first polymer has a molar mass of less than about 50 kg/mol, less than about 45 kg/mol, less than about 40 kg/mol, less than about 35 kg/mol, less than about 30 kg/mol, less than about 25 kg/mol, less than about 20 kg/mol, less than about 15 kg/mol, less than about 10 kg/mol, or less than about 8 kg/mol. In some embodiments, an ethylene/butylene ratio in the first polymer is from about 2:10 to about 3:10, from about 3:10 to about 4:10, from about 4:10 to about 5:10, from about 5:10 to about 6:10, or from about 6:10 to about 7:10.

In some embodiments, the polymeric binder consists of only the first polymer.

Alternatively, in some embodiments, the polymeric binder is a mixture including two, three, four or more than four polymers. For instance, in some embodiments, the polymeric binder includes a second polymer. In an embodiment, the second polymer is cellulose, poly(vinyl alcohol), poly(acrylic acid), polyvinylidene fluoride, polyvinyl acetate-polyvinylpyrrolidone, poly(ethylene glycol), amine, silicone, styrene isoprene styrene (SIS), styrene ethylene, or any combination thereof. In some embodiments, the polymeric binder includes the first polymer at an amount of more than about 10 wt %, more than about 20 wt %, more than about 30 wt %, more than about 40 wt %, more than about 50 wt %, more than about 60 wt %, more than about 70 wt %, or more than about 80 wt % of the binder. For instance, when the polymeric binder includes the first polymer at an amount of 10 wt %, then 10 percent of the weight of the polymeric binder is attributed to the first polymer whereas the remaining 90 percent of the weight of the polymeric binder is attributable to one or more other polymers.

In some embodiments, considering the polymeric binder dissolved in the at least one solvent, the polymeric binder dissolved in at least one solvent is present in a weight percentage in the solvent that is from about 5 wt % to about 10 wt %, from about 10 wt % to about 15 wt %, from about 15 wt % to about 20 wt %, from about 20 wt % to about 25 wt %, or from about 25 wt % to about 30 wt % with respect to the solvent into which the polymeric binder is mixed.

In some embodiments, the composition includes the liquid metal at an amount from about 50% to about 60%, from about 60% to about 70%, from about 70% to about 80%, or from about 80% to about 90% of the overall composition by weight. In some embodiments, the liquid metal is a Ga-based alloy. In some embodiments, the Ga-based alloy includes gallium at an amount of from about 50 wt % to about 55 wt %, from about 55 wt % to about 60 wt %, from about 60 wt % to about 65 wt %, from about 65 wt % to about 70 wt %, from about 70 wt % to about 80 wt %, or from about 80 wt % to about 85 wt % of the overall composition. In some embodiments, the Ga-based alloy includes gallium indium alloy, gallium tin alloy, gallium indium tin alloy, gallium indium tin zinc alloy, or any combination thereof.

In some embodiments, the metallic filler is in a form of microflakes, nanoflakes, microparticles, nanoparticles, nanowires, nanotubes, or a combination thereof. In some embodiments, the metallic filler is at an amount from about 10% to about 20%, from about 20% to 30%, from about 30% to about 40%, or from about 40% to about 50% by weight of the liquid metal. Thus, in the case where the metallic filler is 10% by weight of the liquid metal and the liquid metal is 50% of the overall weight of the composition, the metallic filler is 10% by weight of the liquid metal and 5% by weight of the overall composition at the time the composition is used for tracing. However, subsequent to the tracing, it is expected that the solvent will evaporate causing weight percentages to the overall composition to adjust accordingly. In some embodiments, the metallic filler includes at least one of silver, copper, gold, titanium, nitinol, or a mixture thereof.

Another aspect of the present disclosure provides a method for manufacturing an electronic device that includes at least a first circuit component, a second circuit component, and a line or via made of a composition of the present disclosure that electrically connects the first and second circuit components. The method includes forming a first circuit component at a first portion of a deformable substrate, and forming a second circuit component at a second portion of the deformable substrate. In some embodiments the circuit includes a single layer on the substrate whereas in other embodiments the circuit comprises a plurality of layers (e.g., 2 or more, 3 or more 4, or more, 5 or more layers) stacked on the deformable substrate. In some embodiments, each of these layers is deformable.

The method also includes tracing out at least one line or at least one via that couples the first circuit component and second circuit component, with any of the compositions disclosed herein. For instance, in some embodiments, the first and second circuit components are formed on the same layer of a circuit, and a line is traced out to couple the first and second circuit components. Alternatively, in some embodiments, the first and second circuit components are formed on two different layers of the circuit, and a via is formed to couple the first and second circuit components. The line or via can be traced using, for instance, an extrusion-based additive manufacturing method such as direct printing techniques. Subsequent to the tracing, the polymeric binder or at least a portion of it polymerizes thereby forming the line or via that couples, and electrically connects, the first circuit component and second circuit component.

### BRIEF DESCRIPTION OF THE DRAWINGS

FIG. 1 illustrates a polymer solubility test for screening solvents in accordance with some embodiments of the present disclosure.

FIG. 2 is a bar chart illustrating drying times of solution drops on a glass slide at lab temperature in accordance with some embodiments of the present disclosure.

FIGS. 3A, 3B, 3C and 3D are images of traces made of exemplary compositions in accordance with some embodiments of the present disclosure.

FIGS. 4A and 4B are graphs showing a resistance of a first trace measured at 100% cyclic strain in accordance with some embodiments of the present disclosure.

FIGS. 5A, 5B and 5C are graphs showing a resistance of a second trace measured at 100% cyclic strain in accordance with some embodiments of the present disclosure.

FIG. 6 is a graph showing a resistance of a third trace measured at 100% cyclic strain in accordance with some embodiments of the present disclosure.

FIGS. 7A and 7B are graphs showing a resistance of a fourth trace measured at 100% cyclic strain in accordance with some embodiments of the present disclosure.

FIGS. 8A, 8B and 8C are graphs showing a resistance of a fifth trace measured at 100% cyclic strain in accordance with some embodiments of the present disclosure.

FIG. 9 is a block diagram schematically illustrating an electronic device in accordance with some embodiments of the present disclosure.

FIG. 10 is a flowchart illustrating a method for manufacturing an electronic device, in which optional embodiments are indicated by dashed boxes, in accordance with some embodiments of the present disclosure.

FIG. 11 is a flowchart illustrating a method for manufacturing an exemplary circuit of an electronic device in accordance with some embodiments of the present disclosure.

FIG. 12 is a flowchart illustrating a method for manufacturing another exemplary circuit of an electronic device in accordance with some embodiments of the present disclosure.

FIG. 13 illustrates exemplary logic functions that can be implemented into an exemplary circuit of an electronic device in accordance with some embodiments of the present disclosure.

FIG. 14 is a bar chart comparing measured conductivities of inks of the present disclosure against a commercial ink, an ink based on a literature, pure EGaIn and copper in accordance with some embodiments of the present disclosure.

### DETAILED DESCRIPTION OF THE INVENTION

### I. Introduction

The present disclosure is directed to the use of solvent-based liquid metal (LM) compositions in manufacturing electronic devices, where the solvent-based LM compositions have longer decap times to meet the challenges in various printing techniques, such as direct ink writing, stencil printing, or screen printing that are used in the manufacture of electronic devices (e.g., in the manufacture of circuits). In various embodiments, a solvent-based LM composition of the present disclosure has a decap time of at least 1 minute, at least 2 minutes, at least 5 minutes, at least 15 minutes, at least 20 minutes, or greater than 20 minutes. In some embodiments, a solvent-based LM composition of the present disclosure has a decap time of at least half an hour, at least 1 hour, at least 2 hours, at least 3 hours, at least 4 hours, at least 5 hours, or greater than 5 hours.

Before the invention is described in greater detail, it is to be understood that the invention is not limited to particular embodiments described herein as such embodiments may vary. It is also to be understood that the terminology used herein is for the purpose of describing particular embodiments only, and the terminology is not intended to be limiting. The scope of the invention will be limited only by the appended claims. Unless defined otherwise, all technical and scientific terms used herein have the same meaning as commonly understood by one of ordinary skill in the art to which this invention belongs. Where a range of values is provided, it is understood that each intervening value, to the tenth of the unit of the lower limit unless the context clearly dictates otherwise, between the upper and lower limit of that range and any other stated or intervening value in that stated range, is encompassed within the invention. The upper and lower limits of these smaller ranges may independently be included in the smaller ranges and are also encompassed within the invention, subject to any specifically excluded limit in the stated range. Where the stated range includes one or both of the limits, ranges excluding either or both of those included limits are also included in the invention.

The term “about” or “approximately” is used herein to provide literal support for the exact number that it precedes, as well as a number that is near to or approximately the number that the term precedes. In determining whether a number is near to or approximately a specifically recited number, the near or approximating unrecited number may be a number, which, in the context in which it is presented, provides the substantial equivalent of the specifically recited number. It should be appreciated that all numerical values and ranges disclosed herein are approximate values and ranges, whether “about” is used in conjunction therewith. It should also be appreciated that the term “about,” as used herein, in conjunction with a numeral refers to a value that may be ±0.01% (inclusive), ±0.1% (inclusive), ±0.5% (inclusive), ±1% (inclusive) of that numeral, ±2% (inclusive) of that numeral, ±3% (inclusive) of that numeral, ±5% (inclusive) of that numeral, ±10% (inclusive) of that numeral, or ±15% (inclusive) of that numeral. It should further be appreciated that when a numerical range is disclosed herein, any numerical value falling within the range is also specifically disclosed.

Furthermore, when a reference number is given an “ i^{th}” denotation, the reference number refers to a generic component, set, or embodiment. For instance, a layer “layer i” refers to the i^{th} layer in a plurality of layers.

All publications, patents, and patent applications cited in this specification are incorporated herein by reference to the same extent as if each individual publication, patent, or patent application were specifically and individually indicated to be incorporated by reference. Furthermore, each cited publication, patent, or patent application is incorporated herein by reference to disclose and describe the subject matter in connection with which the publications are cited. The citation of any publication is for its disclosure prior to the filing date and should not be construed as an admission that the invention described herein is not entitled to antedate such publication by virtue of prior invention. Further, the dates of publication provided might be different from the actual publication dates, which may need to be independently confirmed.

It is noted that the claims may be drafted to exclude any optional element. As such, this statement is intended to serve as antecedent basis for use of such exclusive terminology as “solely,” “only,” and the like in connection with the recitation of claim elements, or use of a “negative” limitation. As will be apparent to those of skill in the art upon reading this disclosure, each of the individual embodiments described and illustrated herein has discrete components and features which may be readily separated from or combined with the features of any of the other several embodiments without departing from the scope or spirit of the invention. Any recited method may be carried out in the order of events recited or in any other order that is logically possible. Although any methods and materials similar or equivalent to those described herein may also be used in the practice or testing of the invention, representative illustrative methods and materials are now described.

In describing the present invention, the following terms will be employed, and are defined as indicated below.

### II. Definitions

Where substituent groups are specified by their conventional chemical formula, written from left to right, the structures optionally also encompass the chemically identical substituents, which would result from writing the structure from right to left, e.g., —CH₃— is intended to also optionally recite —CH₃—.

The term “aryl” means, unless otherwise stated, a polyunsaturated, aromatic, substituent that can be a single ring or multiple rings (preferably from 1 to 3 rings), which are fused together or linked covalently. The term “heteroaryl” refers to aryl substituent groups (or rings) that contain from one to four heteroatoms selected from nitrogen (N), oxygen (O), sulpher (S), silicon (Si) and boron (B), where the nitrogen and sulfur atoms are optionally oxidized, and the nitrogen atom(s) are optionally quaternized. An exemplary heteroaryl group is a six-membered azine, e.g., pyridinyl, diazinyl and triazinyl. A heteroaryl group can be attached to the remainder of the molecule through a heteroatom. Non-limiting examples of aryl and heteroaryl groups include phenyl, 1-naphthyl, 2-naphthyl, 4-biphenyl, 1-pyrrolyl, 2-pyrrolyl, 3-pyrrolyl, 3-pyrazolyl, 2-imidazolyl, 4-imidazolyl, pyrazinyl, 2-oxazolyl, 4-oxazolyl, 2-phenyl-4-oxazolyl, 5-oxazolyl, 3-isoxazolyl, 4-isoxazolyl, 5-isoxazolyl, 2-thiazolyl, 4-thiazolyl, 5-thiazolyl, 2-furyl, 3-furyl, 2-thienyl, 3-thienyl, 2-pyridyl, 3-pyridyl, 4-pyridyl, 2-pyrimidyl, 4-pyrimidyl, 5-benzothiazolyl, purinyl, 2-benzimidazolyl, 5-indolyl, 1-isoquinolyl, 5-isoquinolyl, 2-quinoxalinyl, 5-quinoxalinyl, 3-quinolyl, and 6-quinolyl.

Substituents for the aryl and heteroaryl radicals are generically referred to as “aryl group substituents,” and they can be one or more of a variety of groups selected from, but not limited to: H, —R, —OR′, —NR′R″, —SR′, halogen, —SiR′R″R″′, —OC(O)R′, —C(O)R′, —CO₂R′, —CONR′R″, —OC(O)NR′R″, —NR″C(O)R′, —NR′—C(O)NR″R″′, —NR″C(O)₂R′, —NR—C(NR′R″R′″)═NR″″, —NR—C(NR′R″)═NR′″, —S(O)R′, —S(O)₂R′, —S(O)₂NR′R″, —NRSO₂R′, —CN and —NO₂ in a number ranging from zero to (m′), where m′ is the total number of carbon atoms in the aryl or heteroaryl, and R′, R″, R″′ and R″″ each preferably independently refer to hydrogen, substituted or unsubstituted alkyl, substituted or unsubstituted heteroalkyl, alkoxy or thioalkoxy groups. When a compound of the invention includes more than one R group, for example, each of the R groups is independently selected as are each R′, R″, R′″ and R″″ groups when more than one of these groups is present. From the above discussion of substituents, one of skill in the art will understand that the term “substituted aryl” is meant to include groups including carbon atoms bound to groups other than hydrogen groups, such as haloalkyl (e.g., —CF₃ and —CH₂CF₃) and acyl (e.g., —C(O)CH₃, —C(O)CF₃, —C(O)CH₂OCH₃, and the like). These terms encompass groups considered exemplary “aryl group substituents”, which are components of exemplary “substituted aryl” and “substituted heteroaryl” moieties.

The symbol “R” is a general abbreviation that represents a substituent group that is selected from H, substituted or unsubstituted alkyl, and substituted or unsubstituted heteroalkyl.

The term “alkyl,” by itself or as part of another substituent, means, unless otherwise stated, a straight or branched chain, or cyclic hydrocarbon radical, or combination thereof, which may be fully saturated, mono- or polyunsaturated and can include di-, tri- and multivalent radicals, having the number of carbon atoms designated (i.e. C₁-C₁₀ means one to ten carbons). Examples of saturated hydrocarbon radicals include, but are not limited to, groups such as methyl, ethyl, n-propyl, isopropyl, n-butyl, t-butyl, isobutyl, sec-butyl, cyclohexyl, (cyclohexyl)methyl, cyclopropylmethyl, homologs and isomers of, for example, n-pentyl, n-hexyl, n-heptyl, n-octyl, and the like. An unsaturated alkyl group is one having one or more double bonds or triple bonds. Examples of unsaturated alkyl groups include, but are not limited to, vinyl, 2-propenyl, crotyl, 2-isopentenyl, 2-(butadienyl), 2,4-pentadienyl, 3-(1,4-pentadienyl), ethynyl, 1- and 3-propynyl, 3-butynyl, and the higher homologs and isomers. The term “alkyl,” unless otherwise noted, is also meant to optionally include those derivatives of alkyl defined in more detail below, such as “heteroalkyl.” Alkyl groups that are limited to hydrocarbon groups are termed “homoalkyl”. Exemplary alkyl groups include the monounsaturated C₉₋₁₀, oleoyl chain or the diunsaturated C₉₋₁₀, ₁₂₋₁₃ linoeyl chain. Typically, an alkyl group will have from 1 to 24 carbon atoms, with those groups having 10 or fewer carbon atoms being preferred in the present invention. A “lower alkyl” is a shorter chain alkyl group, generally having eight or fewer carbon atoms.

The term “heteroalkyl,” by itself or in combination with another term, means, unless otherwise stated, a stable straight or branched chain, or cyclic hydrocarbon radical, or combinations thereof, consisting of the stated number of carbon atoms and at least one heteroatom selected from the group consisting of O, N, Si and S, and where the nitrogen and sulfur atoms may optionally be oxidized and the nitrogen heteroatom may optionally be quaternized. The heteroatom(s) O, N and S and Si may be placed at any interior position of the heteroalkyl group or at the position at which the alkyl group is attached to the remainder of the molecule. Examples include, but are not limited to, —CH₂—CH₂—O—CH₃, —CH₂—CH₂—NH—CH₃, —CH₂—CH₂—N(CH₃)—CH₃, —CH₂—S—CH₂—CH₃, —CH₂—CH₂, —S(O)—CH₃, —CH₂—CH₂—S(O)₂—CH₃, —CH═CH—O—CH₃, —Si(CH₃)₃, —CH₂—CH═N—OCH₃, and —CH═CH—N(CH₃)—CH₃. Up to two heteroatoms may be consecutive, such as, for example, —CH2—NH—OCH₃ and —CH₂—O—Si(CH₃)₃.

Each of the above terms (e.g., “alkyl,” and “heteroalkyl”) are meant to optionally include both substituted and unsubstituted forms of the indicated species. Exemplary substituents for these species are provided below.

Substituents for the alkyl and heteroalkyl radicals (including those groups often referred to as alkylene, alkenyl, heteroalkylene, heteroalkenyl, alkynyl, cycloalkyl, heterocycloalkyl, cycloalkenyl, and heterocycloalkenyl) are generically referred to as “alkyl group sub stituents,” and they can be one or more of a variety of groups selected from, but not limited to: H, substituted or unsubstituted aryl, substituted or unsubstituted heteroaryl, substituted or unsubstituted heterocycloalkyl, —OR′, ═O, ═NR′, ═N—OR′, —NR′R″, —SR′, halogen, —SiR′R″R″′, —OC(O)R′, —C(O)R′, —CO₂R′, —CONR′R″, —OC(O)NR′R″, —NR″C(O)R′, —NR′—C(O)NR″R″′, —NR″C(O)₂R′, —NR—C(NR′R″R′″)═NR″″, —NR—C(NR′R″)═NR′″, —S(O)R′, —S(O)₂R′, —S(O)₂NR′R″, —NRSO₂R′, —CN and —NO₂ in a number ranging from zero to (2m′+1), where m′ is the total number of carbon atoms in such radical. R′, R″, R″′ and R″″ each preferably independently refer to hydrogen, substituted or unsubstituted heteroalkyl, substituted or unsubstituted aryl, e.g., aryl substituted with 1-3 halogens, substituted or unsubstituted alkyl, alkoxy or thioalkoxy groups, or arylalkyl groups. When a compound of the invention includes more than one R group, for example, each of the R groups is independently selected as are each R′, R″, R′″ and R″″ groups when more than one of these groups is present. When R′ and R″ are attached to the same nitrogen atom, they can be combined with the nitrogen atom to form a 5-, 6-, or 7-membered ring. For example, —NR′R″ is meant to include, but not be limited to, 1-pyrrolidinyl and 4-morpholinyl. From the above discussion of substituents, one of skill in the art will understand that the term “alkyl” is meant to include groups including carbon atoms bound to groups other than hydrogen groups, such as haloalkyl (e.g., —CF₃ and —CH₂CF₃) and acyl (e.g., —C(O)CH₃, —C(O)CF₃, —C(O)CH₂OCH₃, and the like). These terms encompass groups considered exemplary “alkyl group sub stituents”, which are components of exemplary “substituted alkyl” and “substituted heteroalkyl” moieties.

The terms “alkoxy,” “alkylamino” and “alkylthio” (or thioalkoxy) are used in their conventional sense, and refer to those alkyl groups attached to the remainder of the molecule via an oxygen atom, an amino group, or a sulfur atom, respectively.

The compounds disclosed herein may also contain unnatural proportions of atomic isotopes at one or more of the atoms that constitute such compounds. For example, the compounds may be radiolabeled with radioactive isotopes, such as for example tritium (³H), iodine-125 (¹²⁵I) or carbon-14 (¹⁴C). All isotopic variations of the compounds of the present invention, whether radioactive or not, are intended to be encompassed within the scope of the present invention.

It is understood that, in any compound described herein having one or more chiral centers, if an absolute stereochemistry is not expressly indicated, then each center may independently be of R-configuration or S-configuration or a mixture thereof. Thus, the compounds provided herein may be enantiomerically pure or be stereoisomeric mixtures. In addition it is understood that, in any compound described herein having one or more double bond(s) generating geometrical isomers that can be defined as E or Z, each double bond may independently be E or Z a mixture thereof. Likewise, it is understood that, in any compound described, all tautomeric forms are also intended to be included.

Below are examples of specific embodiments of the present disclosure. The examples are offered for illustrative purposes only, and are not intended to limit the scope of the present invention in any way.

### III. Compositions

One aspect of the present disclosure provides a solvent-based liquid metal compositions. The compositions are used, for instance, in the manufacture of electronic devices as disclosed herein. The compositions generally include a solution having at least one solvent and a polymeric binder dissolved in the at least one solvent. The compositions also include a liquid metal (LM) mixed with the solution. In some embodiments, additionally or optionally, the compositions include a metallic filler. The metallic filler can be added prior to, currently with, or subsequent to the LM being mixed with the solution.

The compositions of the present disclosure can be tuned to have one or more beneficial attributes, such as extended decap time, optimal viscosity, higher electrical conductivity, appropriate wettability, or any combination thereof. As used herein, the term “decap time” refers to a time that print nozzles can be uncovered and idle before requiring wiping or purging, or a usable time of a composition before it dries out. As used herein, the term “electrical conductivity” of a composition refers to an electrical conductivity of the composition once it is printed, dried or cured. In some embodiments, the electrical conductivity of a composition is a measured electrical conductivity of an electrical component (e.g., trace, circuit) made of the composition.

In some embodiments, the compositions of the present disclosure are tuned to a large range of decap times. For instance, in some embodiments, a composition of the present disclosure has a decap time of at least 1 minute, at least 2 minutes, at least 5 minutes, at least 15 minutes, at least 20 minutes, or greater than 20 minutes. In some embodiments, a composition of the present disclosure has a decap time of at least half an hour, at least 1 hour, at least 2 hours, at least 3 hours, at least 4 hours, at least 5 hours, or greater than 5 hours.

Additionally or optionally, the compositions of the present disclosure are tuned to have a suitable viscosity to suit different applications. For instance, in some embodiments, a composition of the present disclosure, at a temperature between 64 degrees Fahrenheit (° F.) and 72° F., has a viscosity between 0.5 Pascal seconds (Pa·s) and 3 Pa·s, between 0.5 Pa·s and 2.7 Pa·s, between 0.5 Pa·s and 2.5 Pa·s, between 0.5 Pa·s and 2.2 Pa·s, between 0.5 Pa·s and 2 Pa·s, between 0.5 Pa·s and 1.7 Pa·s, between 0.5 Pa·s and 1.5 Pa·s, between 0.5 Pa·s and 1.2 Pa·s, between 0.5 Pa·s and 1 Pa·s, between 0.5 Pa·s and 0.7 Pa·s, between 1 Pa·s and 3 Pa·s, between 1 Pa·s and 2.7 Pa·s, between 1 Pa·s and 2.5 Pa·s, between 1 Pa·s and 2.2 Pa·s, between 1 Pa·s and 2 Pa·s, between 1 Pa·s and 1.7 Pa·s, between 1 Pa·s and 1.5 Pa·s, between 1 Pa·s and 1.2 Pa·s, between 1.5 Pa·s and 3 Pa·s, between 1.5 Pa·s and 2.7 Pa·s, between 1.5 Pa·s and 2.5 Pa·s, between 1.5 Pa·s and 2.2 Pa·s, between 1.5 Pa·s and 2 Pa·s, between 1.5 Pa·s and 1.7 Pa·s, between 2 Pa·s and 3 Pa·s, between 2 Pa·s and 2.7 Pa·s, between 2 Pa·s and 2.5 Pa·s, between 2 Pa·s and 2.2 Pa·s, between 2.5 Pa·s and 3 Pa·s, or between 2.5 Pa·s and 2.7 Pa·s.

In some embodiments, a composition of the present disclosure, at a temperature between 64° F. and 72° F., has a viscosity of at least 0.5 Pa·s, at least 0.7 Pa·s, at least 0.9 Pa·s, at least 1 Pa·s, at least 1.1 Pa·s, at least 1.3 Pa·s, at least 1.5 Pa·s, at least 1.7 Pa·s, at least 1.9 Pa·s, at least 2 Pa·s, at least 2.1 Pa·s, at least 2.3 Pa·s, at least 2.5 Pa·s, at least 2.7 Pa·s, at least 2.9 Pa·s, or at least 3 Pa·s. In some embodiments, a composition of the present disclosure, at a temperature between 64° F. and 72° F., has a viscosity of at most 0.5 Pa·s, at most 0.7 Pa·s, at most 0.9 Pa·s, at most 1 Pa·s, at most 1.1 Pa·s, at most 1.3 Pa·s, at most 1.5 Pa·s, at most 1.7 Pa·s, at most 1.9 Pa·s, at most 2 Pa·s, at most 2.1 Pa·s, at most 2.3 Pa·s, at most 2.5 Pa·s, at most 2.7 Pa·s, at most 2.9 Pa·s, or at most 3 Pa·s.

In some embodiments, a composition of the present disclosure, at a temperature between 18 degrees Celcius (° C.) and 22° C., has a viscosity between 500 centipoise (cps) and 3,000 cps, between 500 cps and 2,750 cps, between 500 cps and 2,500 cps, between 500 cps and 2,250 cps, between 500 cps and 2,000 cps, between 500 cps and 1,750 cps, between 500 cps and 1,500 cps, between 500 cps and 1,250 cps, between 500 cps and 1,000 cps, between 500 cps and 750 cps, between 700 cps and 3,000 cps, between 700 cps and 2,750 cps, between 700 cps and 2,500 cps, between 700 cps and 2,250 cps, between 700 cps and 2,000 cps, between 700 cps and 1,750 cps, between 700 cps and 1,500 cps, between 700 cps and 1,250 cps, between 700 cps and 1,000 cps, between 700 cps and 750 cps, between 900 cps and 3,000 cps, between 900 cps and 2,750 cps, between 900 cps and 2,500 cps, between 900 cps and 2,250 cps, between 900 cps and 2,000 cps, between 900 cps and 1,750 cps, between 900 cps and 1,500 cps, between 900 cps and 1,250 cps, between 900 cps and 1,000 cps, between 1,100 cps and 3,000 cps, between 1,100 cps and 2,750 cps, between 1,100 cps and 2,500 cps, between 1,100 cps and 2,250 cps, between 1,100 cps and 2,000 cps, between 1,100 cps and 1,750 cps, between 1,100 cps and 1,500 cps, between 1,100 cps and 1,250 cps, between 1,300 cps and 3,000 cps, between 1,300 cps and 2,750 cps, between 1,300 cps and 2,500 cps, between 1,300 cps and 2,250 cps, between 1,300 cps and 2,000 cps, between 1,300 cps and 1,750 cps, between 1,300 cps and 1,500 cps, between 1,500 cps and 3,000 cps, between 1,500 cps and 2,750 cps, between 1,500 cps and 2,500 cps, between 1,500 cps and 2,250 cps, between 1,500 cps and 2,000 cps, between 1,500 cps and 1,750 cps, between 1,700 cps and 3,000 cps, between 1,700 cps and 2,750 cps, between 1,700 cps and 2,500 cps, between 1,700 cps and 2,250 cps, between 1,700 cps and 2,000 cps, between 1,700 cps and 1,750 cps, between 1,700 cps and 1,500 cps, between 1,700 cps and 1,250 cps, between 1,700 cps and 1,000 cps, between 1,900 cps and 3,000 cps, between 1,900 cps and 2,750 cps, between 1,900 cps and 2,500 cps, between 1,900 cps and 2,250 cps, between 1,900 cps and 2,000 cps, between 2,100 cps and 3,000 cps, between 2,100 cps and 2,750 cps, between 2,100 cps and 2,500 cps, between 2,100 cps and 2,250 cps, between 2,300 cps and 3,000 cps, between 2,300 cps and 2,750 cps, between 2,300 cps and 2,500 cps, between 2,500 cps and 3,000 cps, between 2,500 cps and 2,750 cps, between 2,700 cps and 3,000 cps, between 2,700 cps and 2,750 cps, or between 2,900 cps and 3,000 cps.

In some embodiments, a composition of the present disclosure, at a temperature between 18° C. and 22° C., has a viscosity of at least 500 cps, at least 600 cps, at least 700 cps, at least 800 cps, at least 900 cps, at least 1,000 cps, at least 1,100 cps, at least 1,200 cps, at least 1,300 cps, at least 1,400 cps, at least 1,500 cps, at least 1,600 cps, at least 1,700 cps, at least 1,800 cps, at least 1,900 cps, at least 2,000 cps, at least 2,100 cps, at least 2,200 cps, at least 2,300 cps, at least 2,400 cps, at least 2,500 cps, at least 2,600 cps, at least 2,700 cps, at least 2,800 cps, at least 2,900 cps, or at least 3,000 cps. In some embodiments, a composition of the present disclosure, at a temperature between 18° C. and 22° C., has a viscosity of at most 500 cps, at most 600 cps, at most 700 cps, at most 800 cps, at most 900 cps, at most 1,000 cps, at most 1,100 cps, at most 1,200 cps, at most 1,300 cps, at most 1,400 cps, at most 1,500 cps, at most 1,600 cps, at most 1,700 cps, at most 1,800 cps, at most 1,900 cps, at most 2,000 cps, at most 2,100 cps, at most 2,200 cps, at most 2,300 cps, at most 2,400 cps, at most 2,500 cps, at most 2,600 cps, at most 2,700 cps, at most 2,800 cps, at most 2,900 cps, or at most 3,000 cps.

Additionally or optionally, the compositions of the present disclosure are tuned to achieve a higher electrical conductivity (e.g., a conductivity measured after the composition is printed, dried or cured). For instance, in some embodiments, a composition of the present disclosure has a measured conductivity, at either the time the composition is used for tracing or after polymerization following tracing, of greater than about 3×10⁵ S/m (siemens per meter), greater than about 4×10⁵ S/m, greater than about 5×10⁵ S/m, greater than about 6×10⁵ S/m, greater than 7×10⁵ S/m, greater than 8×10⁵ S/m, greater than 9×10⁵ S/m, greater than 1×10⁶ S/m, greater than 1.1×10⁶ S/m, or greater than 1.2×10⁶ S/m.

### Solvent

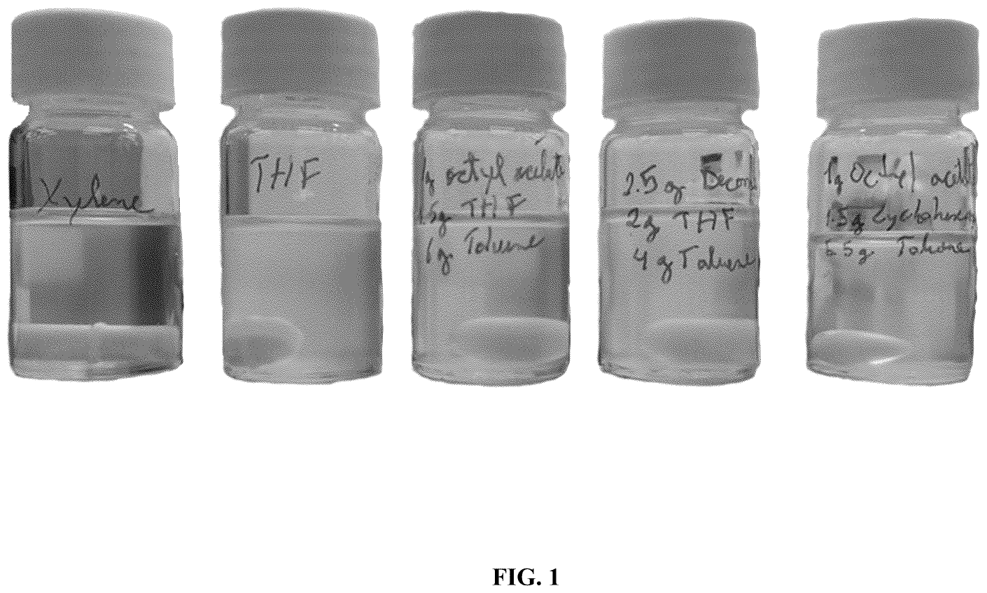

In searching for a solvent or solvent mixture to substitute or combine with toluene, polymer solubility tests have been performed to screen potential solvents. It has been found that styrene isoprene styrene (SIS), an organic resin commonly used in LM inks, can dissolve in 2,2,4-trimethyl-1,3-pentanediol diisobutyrate (TXIB). Specifically, at a room temperature, SIS can dissolve in TXIB at an amount of 15 wt % or more. In addition to TXIB, SIS is also soluble in tetrahydrofuran (THF), cycolohexane, xylene, decane, and octyle acelate. FIG. 1 shows solutions of 15 wt % SIS in various solvents or solvent mixtures.

Table I below shows these solvents along with their boiling temperatures and vapor pressures. As can be seen, xylene, decane, octyle acelate and TXIB have higher boiling temperatures and lower vapor pressures than toluene. Accordingly, these solvents are less volatile than toluene, and using them in the formulations will result in longer decap times.

TABLE I
Physical Properties of Some Solvents

| Solvent | Boiling Point (° C.) | Vapor Pressure at 20° C. (mbar) |
|---|---|---|
| THF | 66 | 173 |
| Cyclohexane | 80.7 | 124 |
| Toluene | 110 | 38 |
| Xylene | 138 | 9 |
| Decane | 174 | 1.9 |
| Octyl Acetate | 211 | 0.5 |
| TXIB | 380 | 0.01 (at 25° C.) |

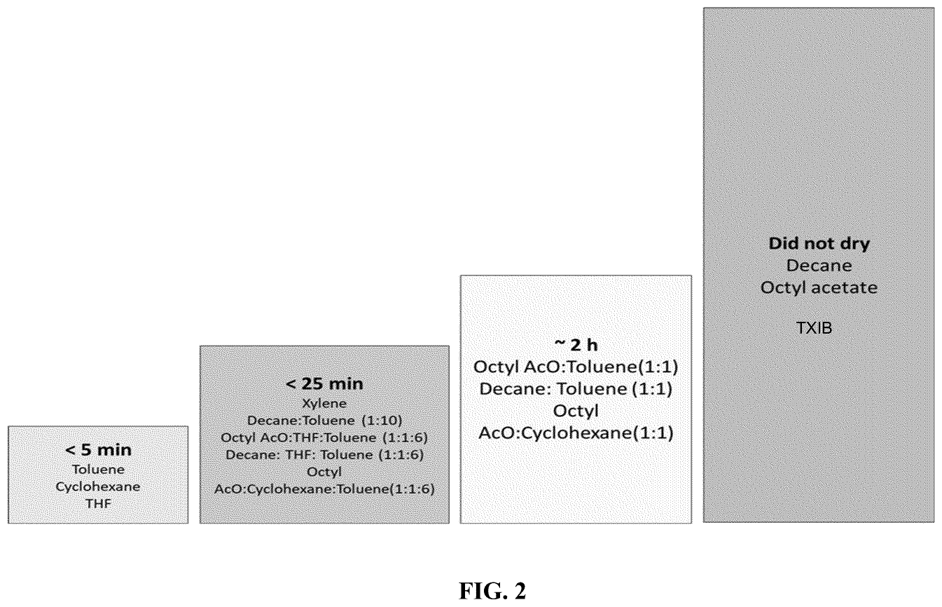

FIG. 2 shows drying times of various 15 wt % SIS solutions (i.e., the weight of SIS is 15% with respect to the weight of the solvent). The drying test is performed on a glass slide at lab temperature. Drops of 15 wt % SIS in different solvents or solvent mixtures are deposited on a glass slide and dry times are recorded. That is, after adding SIS to the solvent, the SIS makes up fifteen percent by weight of the solvent/solute combination whereas the solvent makes up the remaining 85 wt %. As shown in FIG. 2, at lab temperature, a drop of 15 wt % SIS in toluene would dry within less than 5 minutes, while a drop of 15 wt % SIS in xylene would dry within less than 25 minutes, and a drop of 15 wt % SIS in decane, octyle acelate or TXIB would not dry for over 2 hours.

TXIB is safe to use. It can be found in apparel, weather stripper, furniture, wallpaper, nail care, plastisols, sheet vinyl flooring, toys/sporting goods, traffic cones, vinyl compounding, vinyl gloves, inks, coatings, urethane elastomers, and water-based paints.

Accordingly, in some embodiments, the at least one solvent includes a first solvent, and the first solvent is any compound encompassed by general formula I:

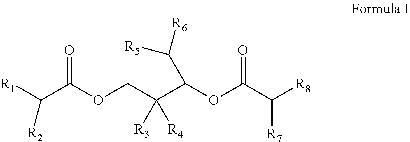

where R₁, R₂, R₃, R₄, R₅, R₆, R₇, and R₈ are each independently selected from substituted or unsubstituted alkyl, or substituted or unsubstituted heteroalkyl.

In some embodiments, the substituted or unsubstituted alkyl or substituted or unsubstituted heteroalkyl has between three and ten carbon atoms.

In some embodiments, the first solvent is TXIB having the chemical structure of Formula II:

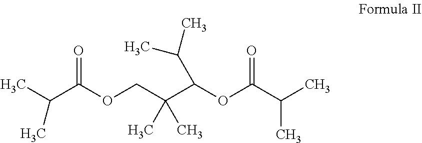 [SMILES: CC(C)C(=O)OCC(C)(C)C(OC(=O)C(C)C)C(C)C]

The at least one solvent is selected based on a number of factors, such as polymer solubility, boiling temperature, vapor pressure, viscosity, toxicity, and/or wettability. The selected solvent or solvent mixture extends a decap time of the composition and thus permits the use of the composition in various different printing techniques.

Depending on the use (e.g., for direct ink writing, screen printing, or the like), the at least one solvent can have different amount of the first solvent. For instance, in some embodiments, the at least one solvent includes the first solvent at about 100% by volume, e.g., the at least one solvent consisting of essentially a single solvent (the first solvent) except one or more optional additives, such as a small amount of surfactant for altering the surface tension of the composition.

In some embodiments, the at least one solvent is a solvent mixture including the first solvent and one, two, three, four, or more than four additional solvents. In some embodiments, the at least one solvent is a solvent mixture including the first solvent of chemical formula I and one, two, three, four, or more than four additional solvents. In some embodiments, the at least one solvent is a solvent mixture including the first solvent of chemical formula II and one, two, three, four, or more than four additional solvents.

For instance, in some embodiments, the at least one solvent includes the first solvent of chemical formula I or II and a second solvent. In an embodiment, the second solvent is toluene. In an alternative embodiment, the second solvent is tetrahydrofuran (THF), cycolohexane, xylene, decane, or octyle acelate. In some embodiments, in addition to the first solvent, the at least one solvent includes two or more of toluene, THF, cycolohexane, xylene, decane, and octyle acelate.

The solvent mixture can be tuned, e.g., having each solvent at a specific concentration, to achieve certain properties and/or to suit particular applications. For instance, the solvent mixture can be tuned to extend the decap time for the needs of different printing techniques, while maintaining a reasonable drying time to reduce smearing and ensure quality of printed circuits. In some embodiments, the at least one solvent includes the first solvent of chemical formula I or II at an amount from about 3% to about 5%, from about 5% to 10%, from about 10% to 20%, from about 30% to 40%, from about 40% to 50%, or more than 50% by volume of the solvent mixture.

In certain embodiments, the first solvent is TXIB and the second solvent is toluene.

In an embodiment, TXIB is at an amount from about 2% to about 5%, from about 5% to 10%, from about 10% to 20% by volume of the solvent mixture.

In some embodiments, the at least one solvent includes a first solvent having chemical formula I or II at an amount from about 3% to about 5%, from about 5% to 10%, from about 10% to 20%, from about 30% to 40%, from about 40% to 50%, or more than 50% by volume of the solvent mixture, and a second solvent at an amount from about 3% to about 5%, from about 5% to 10%, from about 10% to 20%, from about 30% to 40%, by volume of the solvent mixture, where the second solvent is one of tetrahydrofuran (THF), cycolohexane, xylene, hexanes, decane, or octyle acelate.

In some embodiments, the at least one solvent includes (i) a first solvent having chemical formula I or II at an amount from about 3% to about 5%, from about 5% to 10%, from about 10% to 20%, or from about 30% to 40%, by volume, (ii) a second solvent at an amount from about 3% to about 5%, from about 5% to 10%, or from about 10% to 20%, by volume, and (iii) a third solvent at an amount from about 3% to about 5%, from about 5% to 10%, or from about 10% to 20%, by volume where the second solvent and the third solvent are each independently one of tetrahydrofuran (THF), cycolohexane, xylene, hexanes, decane, or octyle acelate.

In certain embodiments, the at least one solvent includes TXIB, toluene, anisole (methoxybenzene), or any combination thereof. In some embodiments, the at least one solvent includes TXIB and anisole (e.g., TXIB as the first solvent and anisole as the second solvent). In some embodiments, the at least one solvent includes toluene, with or without other solvents. In some embodiments, the toluene is at an amount from about 2% to about 5%, from about 5% to 10%, from about 10% to 20%, from about 20% to 30%, or from about 30% to 40% by volume of the solvent mixture. In some embodiments, the at least one solvent includes anisole, with or without other solvents. In some embodiments, the anisole is at an amount from about 2% to about 5%, from about 5% to 10%, from about 10% to 20%, from about 20% to 30%, or from about 30% to 40% by volume of the solvent mixture.

### Polymeric Binder

The polymeric binder typically provides the composition with a desired viscosity, thermal stability, flexibility, and/or adhesion properties. Non-limiting examples of the polymeric binder include, but are not limited to, thermoplastic polymer, cellulose, poly(vinyl alcohol), poly(acrylic acid), polyvinylidene fluoride, polyvinyl acetate-polyvinylpyrrolidone, poly(ethylene glycol), amines, silicones, styrene isoprene styrene (SIS), styrene ethylene butylene styrene (SEBS), or any combination thereof.

In some embodiments, the polymeric binder includes a first polymer. The first polymer is SEBS having any chemical formula in accordance with formula III:

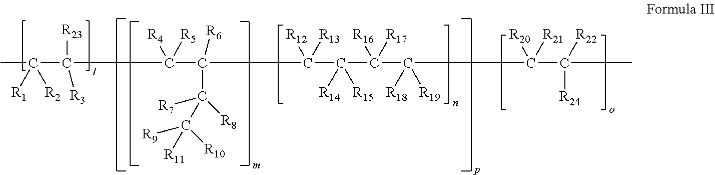

where: l, m, n, p, and o are the same or different and are each a positive integer; R₁, R₂, R₃, R₄, R₅, R₆, R₇, R₈, R₉, R₁₀, R₁₁, R₁₂, R₁₃, R₁₄, R₁₅, R₁₆, R₁₇, R₁₈, R₁₉, R₂₀, R₂₁, and R₂₂ are each independently hydrogen, halogen, or hydroxyl; and R₂₃, and R₂₄ are each independently substituted or unsubstituted aryl, or substituted or unsubstituted heteroaryl.

For instance, in some embodiments, l, m, n, p, and o are each the same or different and are each a positive integer of 1, 2, 3, 4, 5, 6, 7, 8, 9, 10, or greater than 10.

In some embodiments, the first polymer has the chemical structure of formula IV:

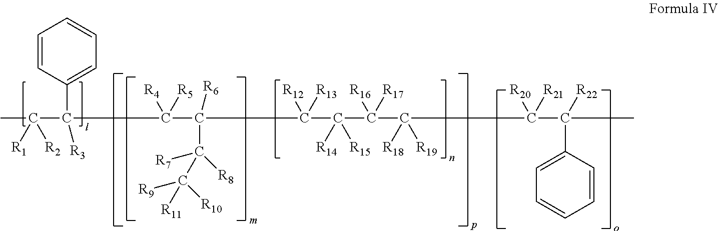

where l, m, n, p, o, R₁, R₂, R₃, R₄, R₅, R₆, R₇, R₈, R₉, R₁₀, R₁₁, R₁₂, R₁₃, R₁₄, R₁₅, R₁₆, R₁₇, R₁₈, R₁₉, R₂₀, R₂₁, and R₂₂ are the same as defined above for Formula III.

In some embodiments, the first polymer is styrene ethylene butylene styrene (SEBS), which has the chemical composition of Formula IV in which R₁, R₂, R₃, R₄, R₅, R₆, R₇, R₈, R₉, R₁₀, R₁₁, R₁₂, R₁₃, R₁₄, R₁₅, R₁₆, R₁₇, R₁₈, R₁₉, R₂₀, R₂₁, and R₂₂ are each hydrogen. Various SEBS grades differ in the molecular weight, styrene content, and ethylene/butylene ratio used. For instance, in some embodiments, SEBS has a molecular weight of greater than 50 kg/mol, greater than about 100 kg/mol, greater than about 150 kg/mol, greater than about 200 kg/mol, greater than about 250 kg/mol, greater than about 300 kg/mol, greater than about 350 kg/mol, or greater than about 400 kg/mol. In some embodiments, a styrene content in the SEBS is from about 10 wt % to about 15 wt %, from about 15 wt % to about 20 wt %, from about 25 wt % to about 30 wt %, from about 30 wt % to about 35 wt %, from about 35 wt % to about 40 wt %, or from about 40 wt % to about 45 wt % of the SEBS. In some embodiments, a styrene block in the SEBS has a molar mass of less than about 50 kg/mol, less than about 45 kg/mol, less than about 40 kg/mol, less than about 35 kg/mol, less than about 30 kg/mol, less than about 25 kg/mol, less than about 20 kg/mol, less than about 15 kg/mol, less than about 10 kg/mol, or less than about 8 kg/mol. In some embodiments, an ethylene/butylene ratio in the SEBS is from about 20% to about 30%, from about 30% to about 40%, from about 40% to about 50%, from about 50% to about 60%, or from about 60% to about 70%.

In an embodiment, the first polymer includes SEBS-345-28-64, i.e., SEBS having molecular weight of 345 kg/mol, styrene content of 28 wt. %, and 64% ethylene content in the ethylene/butylene phase. In certain embodiments, the first polymer includes SEBS-345-28-64, SEBS-194-31-65, SEBS-138-31-65, SEBS-087-18-27, SEBS-085-18-52, SEBS-080-29-66, SEBS-065-41-66, SEBS-065-30-67, or any combination thereof.

In some embodiments, the polymeric binder consists essentially of SEBS at one or more grades. Alternatively, in some embodiments, the polymeric binder is a mixture including two, three, four or more than four polymers. For instance, in some embodiments, the polymeric binder includes a second polymer. Non-limiting examples of the second polymer include, but are not limited to, cellulose, poly(vinyl alcohol), poly(acrylic acid), polyvinylidene fluoride, polyvinyl acetate-polyvinylpyrrolidone, poly(ethylene glycol), amine, silicone, styrene isoprene styrene (SIS), styrene ethylene, or any combination thereof. In some embodiments, the polymeric binder includes the first polymer at an amount of more than about 10 wt %, more than about 20 wt %, more than about 30 wt %, more than about 40 wt %, more than about 50 wt %, more than about 60 wt %, more than about 70 wt %, or more than about 80 wt % of the polymeric binder.

### Solution

The solution of the disclosed solvent-based liquid metal compositions can be tailored with appropriate solvent(s) and polymer(s) to achieve desired properties, such as extended decap time, optimal viscosity, or the like. For instance, in some embodiments, the solution is composed of any one or more polymers (e.g., SIS, SEBS, silicone, or the like) dissolved in TXIB, or in a solvent mixture including TXIB. Non-limiting examples of such embodiments include, but are not limited to, a solution of SIS dissolved in TXIB, a solution of SIS dissolved in a mixture of TXIB and toluene, or a solution of a polymer mixture including SIS dissolved in TXIB. In some embodiments, the solution is composed of SEBS or a polymer mixture including SEBS dissolved in any solvent or solvent mixture. Non-limiting examples of such embodiments include, but are not limited to, a solution of SEBS dissolved in toluene, a solution of a polymer mixture including SEBS dissolved in toluene, or a solution of SEBS dissolved in a mixture of TXIB and toluene.

A solution of the present disclosure can include the at least one solvent and the polymeric binder at any suitable weight ratios. For instance, in some embodiments, a solution of the present disclosure includes the polymeric binder at an amount from about 5% to about 10% by weight, from about 10% to about 20% by weight, or from about 20% to about 30% by weight of the solution.

### Liquid Metal

The liquid metal (LM) makes the composition electrically conductive once it is printed, dried or cured. As used herein, the term “liquid metal” or “LM” generally refers to any metal or metal alloy that has a relatively low melting temperature under normal pressure and atmospheric conditions. For instance, a liquid metal can have a relatively low melting temperature that is at or below about 100° C., at or below about 80° C., at or below about 60° C., at or below about 40° C., at or below about 20° C., at or below about 10° C., at or below about 0° C., at or below about −10° C., at or below about −20° C., or at or below about −30° C. In certain embodiments, a liquid metal is liquid at or near room temperature (e.g., from about 0° C. to about 40° C., or from about 10° C. to about 30° C.) in stressed or unstressed, deformed or undeformed state.

As used herein, the term “alloy” refers to a mixture of two or more substances, with at least one substance being metal. For instance, an alloy can be a mixture of two or more metals, or a mixture of one or more metals and one or more non-metals. In certain embodiments, an alloy is a eutectic mixture, i.e., a mixture of two or more substances at specific proportions such that the mixture changes phase to liquid at a eutectic point relatively lower than a melting point of the pure substances. For instance, a eutectic gallium indium mixture (EGaIn) is composed of 75.5% Ga and 24.5% In by weight. EGaIn changes phase to liquid at about 15.7° C., which is lower than the gallium's melting point of about 29.8° C. and the indium's melting point of about 156.6° C.

In some embodiments, the liquid metal includes a pure substance, such as elemental indium (In), tin (Sn), bismuth (Bi), zinc (Zn), lead (Pb), gallium (Ga), aluminum (Al), lithium (Li) or the like. In other embodiments, the liquid metal includes an alloy made of at least one metal (e.g., In, Sn, Bi, Zn, Pb, Ga, Al, and/or Li) and at least one non-metal. Examples of non-metals include, but are not limited to silicon (Si), germanium (Ge), tellurium (Te), arsenic (As), or the like. In some embodiments, the liquid metal includes an alloy made of two or more metals. In some embodiments, the liquid metal includes an alloy made of two or more metals and one or more non-metals.

In certain embodiments, the liquid metal includes a gallium-based (Ga-based) alloy. For instance, in an embodiment, the liquid metal is a gallium indium alloy (e.g., eutectic GaIn), a gallium tin alloy, a gallium indium tin alloy (e.g., Galinstan), a gallium indium tin zinc alloy, or any combination thereof. In some embodiments, the gallium in the liquid metal is between about 75 and 95 percent by weight, between about 50 and 75 percent by weight, between about 25 and 50 percent by weight, or less than about 25 percent by weight of the liquid metal. In an embodiment, the gallium-based alloy is Ga75.5In24.5, Ga67In20.5Sn12.5, Ga75.5In24.5, Ga61In25Sn13Zn1, or any combination thereof. Ga75.5In24.5 has a melting point of about 15.5° C., Ga67In20.5Sn12.5 has a melting point of about 10.5° C., and Ga61In25Sn13Zn1 has a melting point of about 7.6° C.

In certain embodiments, the liquid metal includes a bismuth-based alloy. For instance, in an embodiment, the liquid metal is a bismuth indium alloy, a bismuth indium tin alloy, or a bismuth indium tin zinc alloy. The bismuth in the liquid metal may be between about 75 and 95 percent by weight, between about 50 and 75 percent by weight, between about 25 and 50 percent by weight, or less than about 25 percent by weight of the liquid metal.

In some embodiments, the liquid metal includes more than one alloy. For instance, in an embodiment, the liquid metal includes both eutectic GaIn and Galinstan. In some embodiments, the liquid metal includes one or more other additional, optional or alternative substances. For instance, in an embodiment, the liquid metal includes a metal alloy made of copper along with one or more of gallium, indium, and/or tin. In some embodiments, the liquid metal includes a nickel titanium alloy (nitinoal).

The composition can have any suitable amount of the LM. For instance, in some embodiments, the composition of (i) the solution with a polymeric binder dissolved in at least on solvent and (ii) the liquid metal includes a Ga-based alloy at an amount from about 50% to about 60%, from about 60% to about 70%, from about 70% to about 80%, or from about 80% to about 90% by weight of the composition. In certain embodiments, the Ga-based alloy includes at least one of gallium indium alloy, gallium tin alloy, gallium indium tin alloy, or gallium indium tin zinc alloy. In some embodiments, the Ga-based alloy includes gallium at an amount of from about 50 wt % to about 55 wt %, from about 55 wt % to about 60 wt %, from about 60 wt % to about 65 wt %, from about 65 wt % to about 70 wt %, from about 70 wt % to about 80 wt %, or from about 80 wt % to about 85 wt % of the composition of (i) the solution with a polymeric binder dissolved in at least on solvent and (ii) the liquid metal.

### Additional or Optional Metallic Filler

In some embodiments the composition of (i) the solution with a polymeric binder dissolved in at least on solvent and (ii) the liquid metal further includes a metallic filler. This additional or optional metallic filler is typically in the form of microflakes, nanoflakes, microparticles, nanoparticles, nanowires, nanotubes, or a combination thereof. In some embodiments, the particles of the metallic filler in the composition have a dimension of about 10 μm to 5 μm, about 5 μm to 1 μm, or less than 1 μm. Any suitable metal can be used as the metallic filler, including but not limited to aluminum, titanium, cobalt, nickel, copper, zinc, silver, gold, or indium. In some embodiments, the metallic filler includes silver, copper, gold, titanium, nitinol, or any combination thereof.

The composition of (i) the solution with a polymeric binder dissolved in at least on solvent and (ii) the liquid metal can have any suitable amount of the metallic filler. For instance, in some embodiments, the composition includes the metallic filler at an amount from about 10% to about 20%, from about 20% to 30%, from about 30% to about 40%, or from about 40% to about 50% by weight of the LM (e.g., the Ga-based alloy).

In some embodiments, the metallic filler in the composition reduces reactivity of the Ga-based alloy. As such, once the composition is printed on a substrate, the Ga-based alloy is less corrosive to other components (e.g., pads, electrodes, etc.) on the substrate.

The compositions of the present disclosure can be prepared by a method including (i) producing a solution including the at least one solvent and the polymeric binder disclosed herein, with the polymeric binder dissolved in the at least one solvent, and (ii) mixing the liquid metal disclosed herein with the solution. In some embodiments, additionally or optionally, the method includes (iii) adding, prior to mixing the liquid metal with the solution, the metallic filler disclosed herein into the solution.

### IV. Example Composition

Exemplary compositions are prepared with the LM (e.g., EGaIn), the metallic filler (e.g., Ag), the polymeric binder (e.g., SIS, SEBS) and one or more solvents (e.g., toluene, TXIB). The components and their amounts in these exemplary compositions are selected for comparison reasons, and are non-limiting.

Composition-I. Composition-I is prepared by (i) dissolving 1.5 g of SIS in 8.5 mL of toluene, (ii) adding 1 g of Ag flakes (5 μm) to 1.25 g of 15 wt % SIS solution and mixing them at 2000 rpm for 5 min, (iii) adding 4 g EGaIn to the Ag/SIS solution and mixing them at 2000 rpm for 5 min, and (iv) mixing the composition in a magnetic stirrer at 25° C. overnight.

Composition-II. Composition-II is prepared by (i) dissolving 1.5 g of SIS in 10 mL of 2,2,4-Trimethyl-1,3-pentanediol diisobutyrate (TXIB), (ii) adding 1.65 g of Ag flakes (5 μm) to 1.4 g of 15 wt % SIS solution and mixing them at 2000 rpm for 5 min, (iii) adding 4.4 g EGaIn to the Ag/SIS solution and mixing them at 2000 rpm for 5 min, and (iv) mixing the composition in a magnetic stirrer at 25° C. overnight.

Composition-III. Composition-III is prepared by (i) dissolving 1.5 g of SIS in 8.5 mL of 5% v/v TXIB:toluene, (ii) adding 1.65 g of Ag flakes (5 μm) to 1.4 g of 15 wt % SIS solution and mixing them at 2000 rpm for 5 min, (iii) adding 4.57 g EGaIn to the Ag/SIS solution and mixing them at 2000 rpm for 5 min, and (iv) mixing the composition in a magnetic stirrer at 25° C. overnight.

Composition-IV. Composition-IV is prepared by (i) dissolving 1.5 g of SEBS in 8.5 mL of toluene, (ii) adding 1 g of Ag flakes (5 μm) to 1.8 g of 8 wt % SEBS solution and mixing them at 2000 rpm for 5 min, (iii) adding 4 g EGaIn to the Ag/SEBS solution and mixing them at 2000 rpm for 5 min, and (iv) mixing the composition in a magnetic stirrer at 25° C. overnight.

The ingredients and their percentages of these compositions are summarized in Table-II below. As can be seen, composition-I, composition-II, and composition-III have substantially the same amounts of EGaIn, Ag, SIS, and the solvent based on their weight percentages. The difference among these three compositions lies in the type of the solvent used in the composition, i.e., toluene in composition-I, TXIB in composition-II and a mixture of 5% v/v TXIB:toluene in composition-III. Composition-IV differs from composition-I in that it uses SEBS instead of SIS as the polymeric binder.

TABLE II
Exemplary Compositions

| | EGaIn | Ag | Binder | Solvent | Ag/LM | |
|---|---|---|---|---|---|---|
| Examples | (wt %) | (wt %) | (wt %) | (wt %) | (wt %)¹ | Solution |
| Composition-I | 59.7% | 21.8% | 2.8% | 15.7% | 36.6% | 15% SIS in toluene |
| Composition- | 59.7% | 21.8% | 2.8% | 15.7% | 36.6% | 15% SIS in TXIB |
| II | | | | | | |
| Composition- | 59.9% | 21.5% | 2.8% | 15.7% | 35.9% | 15 wt % SIS |
| III | | | | | | dissolved in |
| | | | | | | TXIB:Toluene 5% |
| | | | | | | v/v |
| Composition- | 53.7% | 22.1% | 1.9% | 22.2% | 41.3% | 8 wt % SEBS |
| IV | | | | | | dissolved in |
| | | | | | | toluene |

¹This column is AG (wt %) divided by EGaln (wt %).

To demonstrate the use of the compositions of the present disclosure, traces are made of these exemplary compositions and resistances of the traces are measured under 100% cyclic strain.

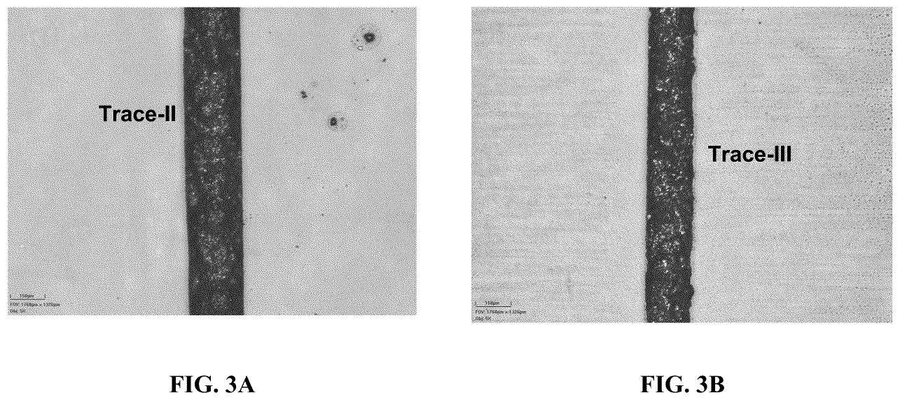

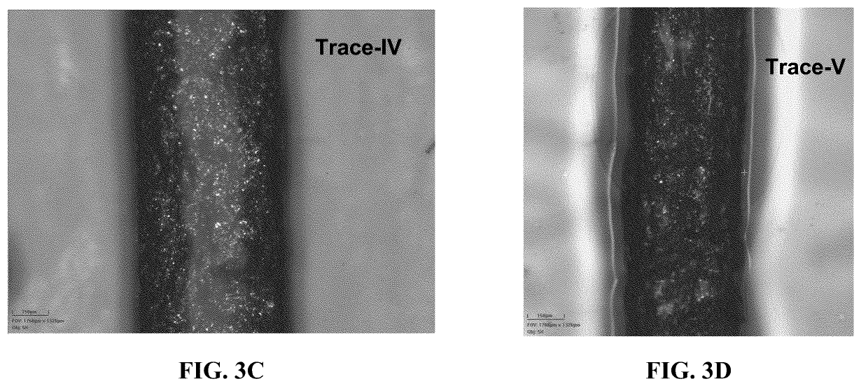

Exemplary traces are listed in Table-III below and shown in FIGS. 3A-3D. Specifically, composition-I, composition-II and composition-III are used to print single traces, i.e., trace-I, trace-II and trace-III, respectively. Composition-I and composition-IV are used to print four traces in parallel, i.e., trace-IV and trace-V, respectively. Both single traces and four traces in parallel are printed using stainless steel stencil.

TABLE III
Exemplary Traces Printed Using Stainless Steel Stencil

| | | | Thickness | Width |
|---|---|---|---|---|
| Examples | Compositions | Encapsulation | (μm) | (μm) |
| Trace-I | Composition-I | Encapsulated | 88 | 204 |
| (single) | | with bluesil | | |
| Trace-II | Composition-II | Not | 48 | 228 |
| (single) | | encapsulated | | |
| Trace-III | Composition-III | Not | 49 | 204 |
| (single) | | encapsulated | | |
| Trace-IV | Composition-I | Encapsulated | 200 | 500 |
| (4 traces) | | with bluesil | | |
| Trace-V | Composition-IV | Encapsulated | 200 | 500 |
| (4 traces) | | with bluesil | | |

For comparison reasons, dimensions of trace-I, trace-II and trace-III are kept more or less the same. Specifically, as shown in Table-III, trace-I (made of composition-I) is encapsulated with bluesil and has a thickness of about 88 μm. Trace-II (made of composition-II) and trace-III (made of composition-III) are not encapsulated and have a thickness of about 48.5 μm±0.5 μm. All of the three traces have a similar width of about 216 μm±12 μm.

Similarly, for comparison reasons, dimensions of trace-IV and trace-V are kept substantially the same. Specifically, as shown in Table-III, both trace-IV (made of composition-I) and trace-V (made of composition-IV) are encapsulated and have a thickness of about 200 μm and a width of about 500 μm.

Resistances of these traces are measured at 100% cyclic strain and 5 second per cycle. A 5 second cycle under 100% strain refers to a process in which a strain is applied in the first half of 5 seconds (2.5 seconds) to stretch the traces to double their lengths and then the strain is released in the second half of 5 seconds.

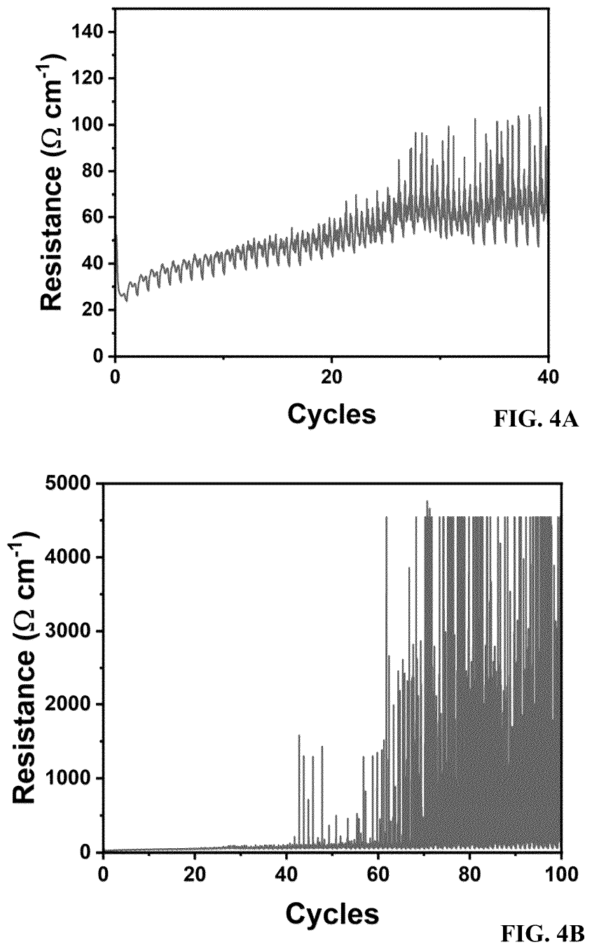

FIGS. 4A and 4B shows the measured resistance of trace-I made of composition-I (i.e., with SIS dissolved in toluene). As shown, the resistance of trace-I starts to rise after about 40 cycles, and reaches 4000 Ω/cm or higher after about 70 cycles. Since the electrical conductivity is inversely proportional to the resistance, this measured resistance indicates a significant decrease in the electrical conductivity of composition-I after about 70 cycles.

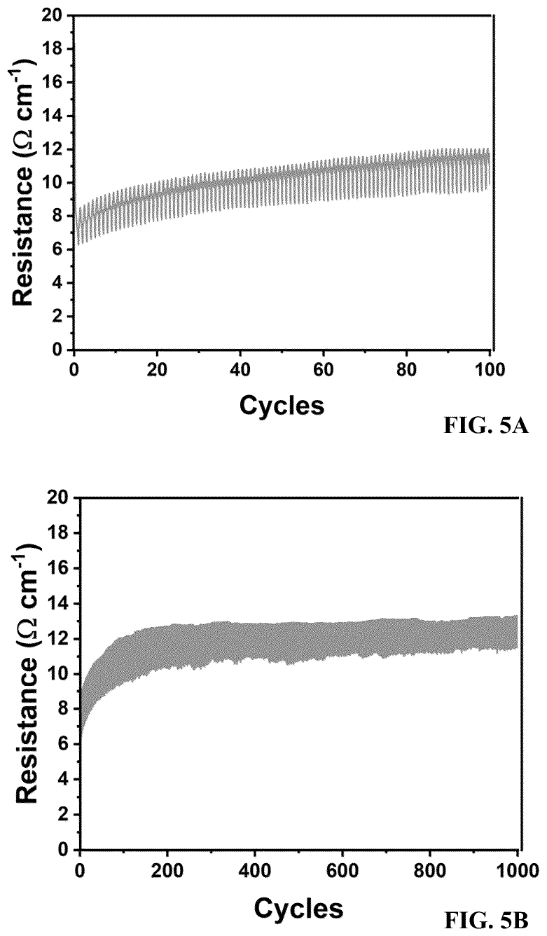

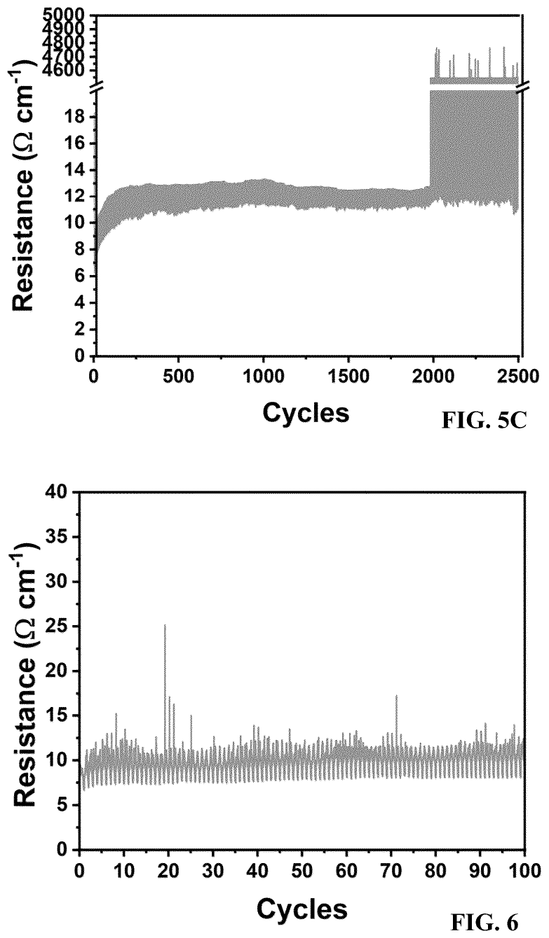

FIGS. 5A, 5B, and 5C show the measured resistance of trace-II made of composition-II (i.e., with SIS dissolved in TXIB). As shown, the resistance of trace-II maintains a low resistance of less than 15 Ω/cm for about 2000 cycles, and only then reaches 4000 Ω/cm or higher. This indicates that the electrical conductivity of composition-II remains at a substantially high level for 2000 cycles.

FIG. 6 shows the measured resistance of trace-III made of composition-III (i.e., with SIS dissolved in TXIB:toluene 5% v/v). As shown, the resistance of trace-III maintains a low resistance of less than 15 Ω/cm for at least 100 cycles. This indicates that the electrical conductivity of composition-II remains at a substantially high level for at least 100 cycles.

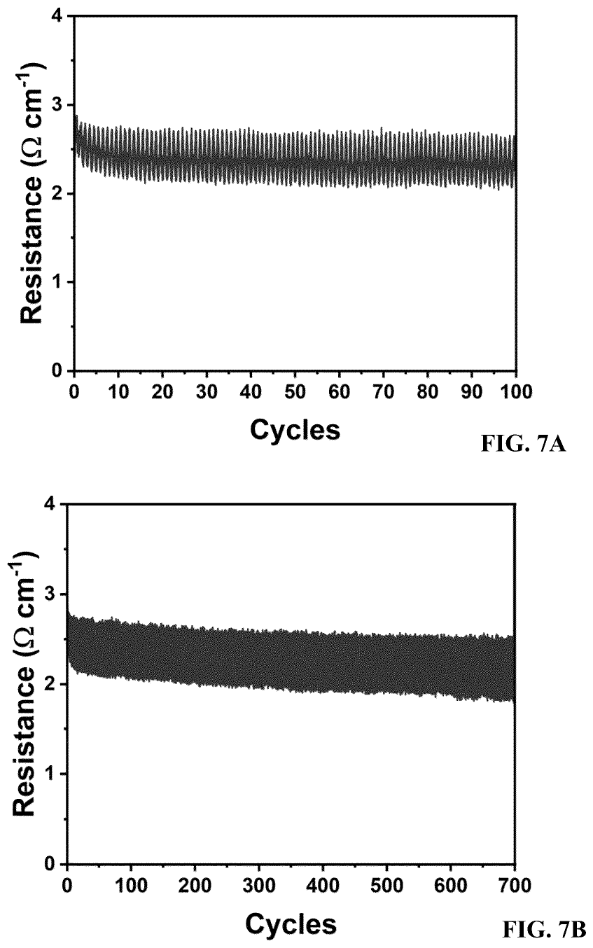

FIGS. 7A and 7B show the measured resistance of trace-IV made of composition-I (i.e., with SIS dissolved in toluene). As shown, the resistance of trace-IV maintains a low resistance of less than 3 Ω/cm for at least 700 cycles. This indicates that the electrical conductivity of composition-IV remains at a substantially high level for at least 100 cycles.

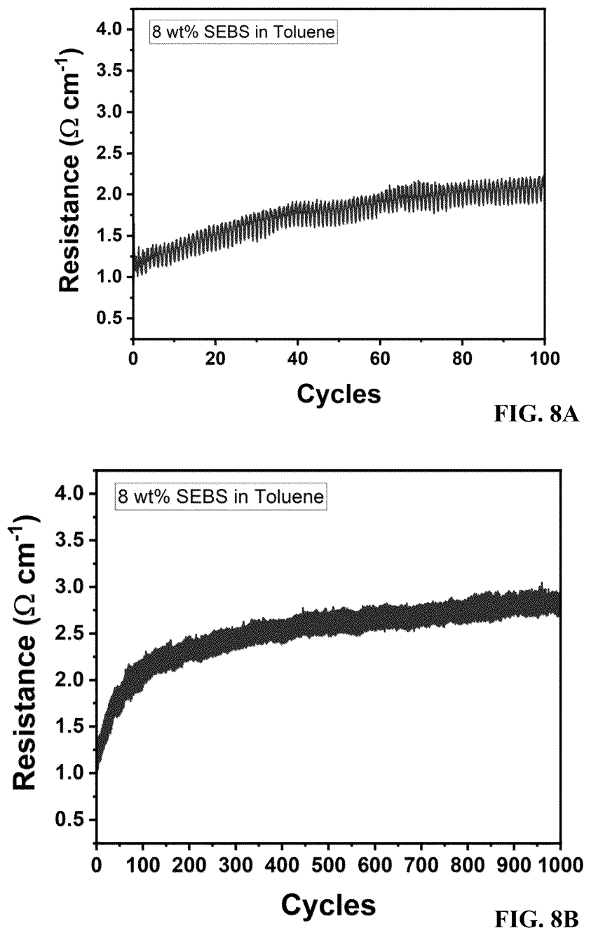

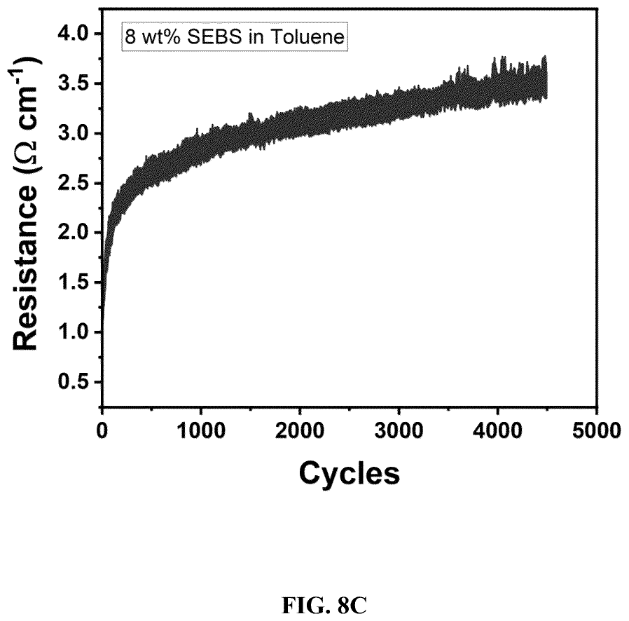

FIGS. 8A, 8B and 8C show the measured resistance of trace-V made of composition-IV (i.e., with SEBS dissolved in toluene). As shown, the resistance of trace-IV maintains a low resistance of less than 4 Ω/cm for at least 4000 cycles. This indicates that the electrical conductivity of composition-IV remains at a substantially high level for at least 4000 cycles.

Comparing the measured resistances of trace-II and trace-III with the measured resistance of trace-I suggests that composition-II (with TXIB as solvent) and composition-III (with TXIB:toluene 5% v/v as solvent) present better electrical properties under strain than composition-I (with toluene as solvent). Comparing the measured resistances of trace-V with the measured resistance of trace-IV suggests that composition-IV (with SEBS as binder) presents similar and possibly better electrical properties under strain than composition-I (with SIS as binder).

Moreover, the measured resistances of the traces indicate that the compositions of the present disclosure has an ability to withstand certain tensile strain with no significant increase in electrical resistance. As such, the compositions of the present disclosure can be used to make electrical circuits of deformable (e.g., flexible, stretchable, inflatable, or the like) electronics.

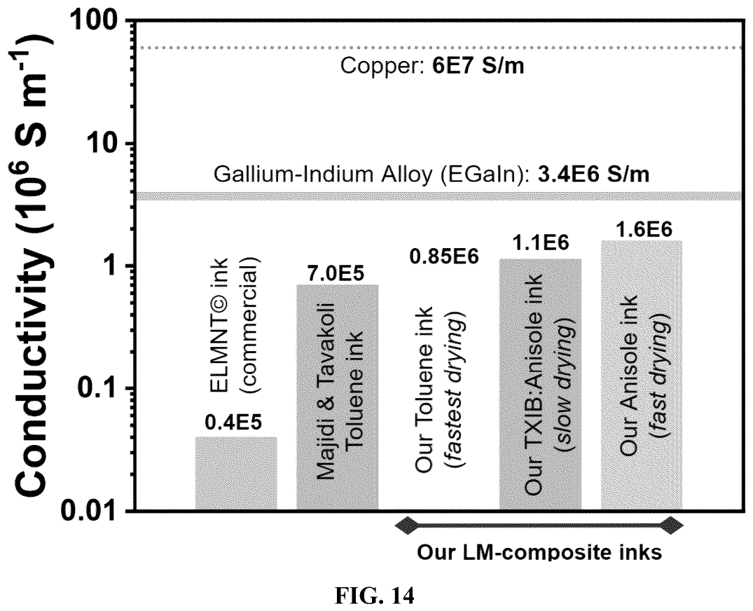

FIG. 14 shows measured conductivities of some exemplary inks of the present disclosure compared against a commercial ink, an ink based on a literature, pure EGaIn and copper in accordance with some embodiments of the present disclosure. In FIG. 14, the commercial ink is an ELMNT® ink. The literature is by Majidi et al., “A Comparative Study of Silver Microflakes in Digitally Printable Liquid Metal Embedded Elastomer Inks for Stretchable Electronics,” Advanced Materials Technologies, Volume 7, Issue 12/2200534, first published on Jul. 15, 2022, which is hereby incorporated by reference in its entirety. The inks of the present disclosure are (i) Toluene ink (e.g., the solvent includes toluene), (ii) TXIB:Anisole ink (e.g., the solvent includes a mixture of TXIB and anisole) and (iii) Anisole ink (e.g., the solvent includes anisole). The three tested inks of the present disclosure are synthesized and printed in a similar fashion as in the Majidi's paper.

As can be seen, the copper has a conductivity of 6×10⁷ S/m, which is the highest among all the tested samples. The pure EGaIn has a conductivity of 3.4×10⁶ S/m, second to the copper. The ELMNT® commercial ink has a conductivity of 4×10⁴ S/m, the lowest among all the tested samples. The ink based on the Majidi's paper has a conductivity of 7.0×10⁵ S/m. The three tested inks of the present disclosure have conductivities of: 0.85×10⁶ S/m for Toluene ink, 1.1×10⁶ S/m for TXIB:Anisole ink, and 1.6×10⁶ S/m for Anisole ink, which are higher than both of the ELMNT® commercial ink and ink based on the Majidi's paper and are approaching that of the pure EGaIn. This indicates that the three tested inks of the present disclosure are more conductive and more useful for making electrical circuits of deformable (e.g., flexible, stretchable, inflatable, or the like) electronics.

### V. Applications

The compositions of the present disclosure have a number of beneficial attributes, such as extended decap time, optimal viscosity, higher electrical conductivity, and/or an ability to withstand certain tensile strain with no significant increase in electrical resistance. As such, they can be used to make a variety of electrical circuits. In particular, they can be used to make electrical circuits for deformable (e.g., flexible, stretchable, inflatable, or the like) electronics, such as smart clothing, conformable photovoltaics, optoelectronics, digital cameras, artificial electronic skins, stretchable batteries, robotics, and mechanically soft and conformable health-monitoring devices, flexible displays, and 3D-transferable electronics.

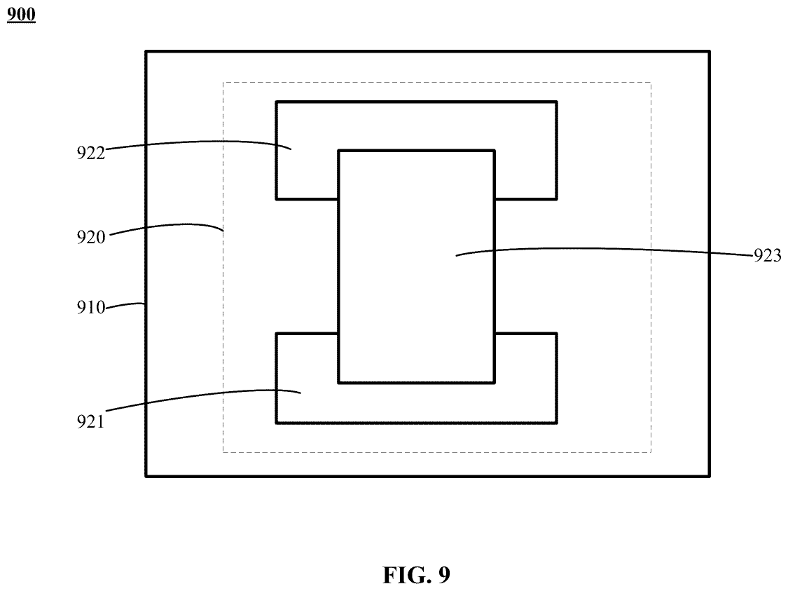

As a non-limiting example, FIG. 9 illustrates an electronic device 900 that includes at least a first circuit 920 formed, applied, secured, or otherwise affixed to a deformable substrate 910. As used herein, the term “deformable substrate” refers to a substrate or a portion of it (e.g., a layer) capable of altering its shape subject to pressure or stress.

For instance, in some embodiments, the substrate or at least a portion of it is flexible, bendable, stretchable, inflatable, or the like. For instance, in some embodiments, the deformable substrate or at least a portion of it (e.g., a layer) is made with a material having a Young's Modulus lower than about 0.5, lower than about 0.4 Gpa, lower than about 0.3 Gpa, or lower than about 0.2 Gpa. Such a material allows the substrate or a portion of it to deform (e.g., bend, stretch or the like) under pressure or strain. In some embodiments, the deformable substrate or at least a portion of it is made of a material having Young's Modulus lower than about 0.1 Gpa to provide enhanced flexibility and tackability. Examples of materials with low Young's Modulus include, but are not limited to elastomeric materials, viscoelastic polymeric materials, synthetic resins having low sliding performance, high corrosion resistance and high strength, such as silicone, medical grade polyurethane, polyethylene terephthalate (PET), polyimide (PI), polyphenylene sulfide (PPS) or fluorine-containing resin.

In some embodiments, the deformable substrate includes a layer or a portion made of a relatively rigid material. For instance, in some embodiments, the deformable substrate includes a layer or a portion made of a material having Young's Modulus higher than about 0.5 Gpa, higher than about 1.0 Gpa, higher than about 2.0 Gpa, higher than about 3.0 Gpa, higher than 4.0 Gpa, or higher than about 5.0 Gpa. Examples of materials with relatively higher Young's Modulus include, but are not limited to, polyethylene, PEEK, polyester, aramid, composite, glass epoxy, and polyethylene naphalate.

In some embodiments, the deformable substrate includes a supporting material upon or within an object is fabricated or attached to or on. In some embodiments, the deformable substrate or a portion of the deformable substrate is processed (e.g., patterned) during manufacture of the object. In some embodiments, the deformable substrate remains substantially unchanged when the object is formed upon or within the deformable substrate. In some embodiments, the deformable substrate includes a planar surface, a substantially planar surface, a curved surface, a round surface (e.g., an edge having a radius of curvature greater than zero), one or more sharp edges, or any combination thereof.

In some embodiments, the deformable substrate is a monolayer substrate consisting of a single layer. In some embodiments, the deformable substrate includes two, three, four, five, or more than five layers. In some embodiments, the deformable substrate includes one or more layers that are removable, e.g., functioning as a sacrificial layer that can be at least partially removed when desired or needed.

The first circuit 920 includes a plurality of circuit components, with at least one circuit component made of a composition of the present disclosure. For instance, in some embodiments, the plurality of circuit components includes a first circuit component 921, a second circuit component 922, and a third circuit component 923 made of a composition of the present disclosure that electrically connects the first and second circuit components.

In some embodiments, the first, second and third circuit components are in a common layer of the circuit, and the third circuit component is a line made of a composition of the present disclosure and electrically connects the first and second circuit components. As used herein, the term “line” refers to a conducting track or trace having a thickness less than a thickness threshold, a width less than a width threshold, or both. In some embodiments, the thickness of a line is less than about 500 μm, less than about 450 μm, less than about 400 μm, less than about 350 μm, less than about 300 μm, less than about 250 μm, less than about 200 μm, less than about 150 μm, or less than about 100 μm. In some embodiments, the width of a line is less than about 1000 μm, less than about 900 μm, less than about 800 μm, less than about 700 μm, less than about 600 μm, less than about 500 μm, less than about 400 μm, less than about 300 μm, or less than about 200 μm.

In some embodiments, the first and second circuit components are in different layers of the circuit, and the third circuit component is a via made of a composition of the present disclosure and electrically connects the first and second circuit components. As used herein, the term “via” refers to a vertical interconnect access having a nominal (e.g., mean or average) diameter or width less than a diameter or width threshold. A cross section of a via can be, but does not necessarily have to be, a circle. For instance, a cross section of a via can be any regular closed form shape such as a circle or a polygon of the form N-gon, where here N is a positive integer of 3 or greater, or an irregular closed form shape, or the like.

In some embodiments, the nominal diameter or a width of a cross-section of the via is between 10 μm and 500 μm. For instance, in some embodiments, the nominal diameter or a width of a cross-section of the via is between 5 μm and 1000 μm (e.g., 0.1 centimeters (cm)), between 5 μm and 975 μm, between 5 μm and 950 μm, between 5 μm and 925 μm, between 5 μm and 900 μm, between 5 μm and 875 μm, between 5 μm and 850 μm, between 5 μm and 825 μm, between 5 μm and 800 μm, between 5 μm and 775 μm, between 5 μm and 750 μm, between 5 μm and 725 μm, between 5 μm and 700 μm, between 5 μm and 675 μm, between 5 μm and 650 μm, between 5 μm and 625 μm, between 5 μm and 600 μm, between 5 μm and 575 μm, between 5 μm and 550 μm, between 5 μm and 525 μm, between 5 μm and 500 μm, between 5 μm and 475 μm, between 5 μm and 450 μm, between 5 μm and 425 μm, between 5 μm and 400 μm, between 5 μm and 375 μm, between 5 μm and 350 μm, between 5 μm and 325 μm, between 5 μm and 300 μm, between 5 μm and 275 μm, between 5 μm and 250 μm, between 5 μm and 225 μm, between 5 μm and 200 μm, between 5 μm and 175 μm, between 5 μm and 150 μm, between 5 μm and 125 μm, between 5 μm and 100 μm, between 5 μm and 75 μm, between 5 μm and 50 μm, between 5 μm and 25 μm, between 5 μm and 10 μm, between 10 μm and 975 μm, between 10 μm and 950 μm, between 10 μm and 925 μm, between 10 μm and 900 μm, between 10 μm and 875 μm, between 10 μm and 850 μm, between 10 μm and 825 μm, between 10 μm and 800 μm, between 10 μm and 775 μm, between 10 μm and 750 μm, between 10 μm and 725 μm, between 10 μm and 700 μm, between 10 μm and 675 μm, between 10 μm and 650 μm, between 10 μm and 625 μm, between 10 μm and 600 μm, between 10 μm and 575 μm, between 10 μm and 550 μm, between 10 μm and 525 μm, between 10 μm and 500 μm, between 10 μm and 475 μm, between 10 μm and 450 μm, between 10 μm and 425 μm, between 10 μm and 400 μm, between 10 μm and 375 μm, between 10 μm and 350 μm, between 10 μm and 325 μm, between 10 μm and 300 μm, between 10 μm and 275 μm, between 10 μm and 250 μm, between 10 μm and 225 μm, between 10 μm and 200 μm, between 10 μm and 175 μm, between 10 μm and 150 μm, between 10 μm and 125 μm, between 10 μm and 100 μm, between 10 μm and 75 μm, between 10 μm and 50 μm, between 10 μm and 25 μm, between 30 μm and 975 μm, between 30 μm and 950 μm, between 30 μm and 925 μm, between 30 μm and 900 μm, between 30 μm and 875 μm, between 30 μm and 850 μm, between 30 μm and 825 μm, between 30 μm and 800 μm, between 30 μm and 775 μm, between 30 μm and 750 μm, between 30 μm and 725 μm, between 30 μm and 700 μm, between 30 μm and 675 μm, between 30 μm and 650 μm, between 30 μm and 625 μm, between 30 μm and 600 μm, between 30 μm and 575 μm, between 30 μm and 550 μm, between 30 μm and 525 μm, between 30 μm and 500 μm, between 30 μm and 475 μm, between 30 μm and 450 μm, between 30 μm and 425 μm, between 30 μm and 400 μm, between 30 μm and 375 μm, between 30 μm and 350 μm, between 30 μm and 325 μm, between 30 μm and 300 μm, between 30 μm and 275 μm, between 30 μm and 250 μm, between 30 μm and 225 μm, between 30 μm and 200 μm, between 30 μm and 175 μm, between 30 μm and 150 μm, between 30 μm and 125 μm, between 30 μm and 100 μm, between 30 μm and 75 μm, between 30 μm and 50 μm, between 50 μm and 975 μm, between 50 μm and 950 μm, between 50 μm and 925 μm, between 50 μm and 900 μm, between 50 μm and 875 μm, between 50 μm and 850 μm, between 50 μm and 825 μm, between 50 μm and 800 μm, between 50 μm and 775 μm, between 50 μm and 750 μm, between 50 μm and 725 μm, between 50 μm and 700 μm, between 50 μm and 675 μm, between 50 μm and 650 μm, between 50 μm and 625 μm, between 50 μm and 600 μm, between 50 μm and 575 μm, between 50 μm and 550 μm, between 50 μm and 525 μm, between 50 μm and 500 μm, between 50 μm and 475 μm, between 50 μm and 450 μm, between 50 μm and 425 μm, between 50 μm and 400 μm, between 50 μm and 375 μm, between 50 μm and 350 μm, between 50 μm and 325 μm, between 50 μm and 300 μm, between 50 μm and 275 μm, between 50 μm and 250 μm, between 50 μm and 225 μm, between 50 μm and 200 μm, between 50 μm and 175 μm, between 50 μm and 150 μm, between 50 μm and 125 μm, between 50 μm and 100 μm, between 50 μm and 75 μm, between 70 μm and 975 μm, between 70 μm and 950 μm, between 70 μm and 925 μm, between 70 μm and 900 μm, between 70 μm and 875 μm, between 70 μm and 850 μm, between 70 μm and 825 μm, between 70 μm and 800 μm, between 70 μm and 775 μm, between 70 μm and 750 μm, between 70 μm and 725 μm, between 70 μm and 700 μm, between 70 μm and 675 μm, between 70 μm and 650 μm, between 70 μm and 625 μm, between 70 μm and 600 μm, between 70 μm and 575 μm, between 70 μm and 550 μm, between 70 μm and 525 μm, between 70 μm and 500 μm, between 70 μm and 475 μm, between 70 μm and 450 μm, between 70 μm and 425 μm, between 70 μm and 400 μm, between 70 μm and 375 μm, between 70 μm and 350 μm, between 70 μm and 325 μm, between 70 μm and 300 μm, between 70 μm and 275 μm, between 70 μm and 250 μm, between 70 μm and 225 μm, between 70 μm and 200 μm, between 70 μm and 175 μm, between 70 μm and 150 μm, between 70 μm and 125 μm, between 70 μm and 100 μm, between 70 μm and 75 μm, between 90 μm and 975 μm, between 90 μm and 950 μm, between 90 μm and 925 μm, between 90 μm and 900 μm, between 90 μm and 875 μm, between 90 μm and 850 μm, between 90 μm and 825 μm, between 90 μm and 800 μm, between 90 μm and 775 μm, between 90 μm and 750 μm, between 90 μm and 725 μm, between 90 μm and 700 μm, between 90 μm and 675 μm, between 90 μm and 650 μm, between 90 μm and 625 μm, between 90 μm and 600 μm, between 90 μm and 575 μm, between 90 μm and 550 μm, between 90 μm and 525 μm, between 90 μm and 500 μm, between 90 μm and 475 μm, between 90 μm and 450 μm, between 90 μm and 425 μm, between 90 μm and 400 μm, between 90 μm and 375 μm, between 90 μm and 350 μm, between 90 μm and 325 μm, between 90 μm and 300 μm, between 90 μm and 275 μm, between 90 μm and 250 μm, between 90 μm and 225 μm, between 90 μm and 200 μm, between 90 μm and 175 μm, between 90 μm and 150 μm, between 90 μm and 125 μm, between 90 μm and 100 μm, between 110 μm and 975 μm, between 110 μm and 950 μm, between 110 μm and 925 μm, between 110 μm and 900 μm, between 110 μm and 875 μm, between 110 μm and 850 μm, between 110 μm and 825 μm, between 110 μm and 800 μm, between 110 μm and 775 μm, between 110 μm and 750 μm, between 110 μm and 725 μm, between 110 μm and 700 μm, between 110 μm and 675 μm, between 110 μm and 650 μm, between 110 μm and 625 μm, between 110 μm and 600 μm, between 110 μm and 575 μm, between 110 μm and 550 μm, between 110 μm and 525 μm, between 110 μm and 500 μm, between 110 μm and 475 μm, between 110 μm and 450 μm, between 110 μm and 425 μm, between 110 μm and 400 μm, between 110 μm and 375 μm, between 110 μm and 350 μm, between 110 μm and 325 μm, between 110 μm and 300 μm, between 110 μm and 275 μm, between 110 μm and 250 μm, between 110 μm and 225 μm, between 110 μm and 200 μm, between 110 μm and 175 μm, between 110 μm and 150 μm, between 110 μm and 125 μm, between 130 μm and 975 μm, between 130 μm and 950 μm, between 130 μm and 925 μm, between 130 μm and 900 μm, between 130 μm and 875 μm, between 130 μm and 850 μm, between 130 μm and 825 μm, between 130 μm and 800 μm, between 130 μm and 775 μm, between 130 μm and 750 μm, between 130 μm and 725 μm, between 130 μm and 700 μm, between 130 μm and 675 μm, between 130 μm and 650 μm, between 130 μm and 625 μm, between 130 μm and 600 μm, between 130 μm and 575 μm, between 130 μm and 550 μm, between 130 μm and 525 μm, between 130 μm and 500 μm, between 130 μm and 475 μm, between 130 μm and 450 μm, between 130 μm and 425 μm, between 130 μm and 400 μm, between 130 μm and 375 μm, between 130 μm and 350 μm, between 130 μm and 325 μm, between 130 μm and 300 μm, between 130 μm and 275 μm, between 130 μm and 250 μm, between 130 μm and 225 μm, between 130 μm and 200 μm, between 130 μm and 175 μm, between 130 μm and 150 μm, between 150 μm and 975 μm, between 150 μm and 950 μm, between 150 μm and 925 μm, between 150 μm and 900 μm, between 150 μm and 875 μm, between 150 μm and 850 μm, between 150 μm and 825 μm, between 150 μm and 800 μm, between 150 μm and 775 μm, between 150 μm and 750 μm, between 150 μm and 725 μm, between 150 μm and 700 μm, between 150 μm and 675 μm, between 150 μm and 650 μm, between 150 μm and 625 μm, between 150 μm and 600 μm, between 150 μm and 575 μm, between 150 μm and 550 μm, between 150 μm and 525 μm, between 150 μm and 500 μm, between 150 μm and 475 μm, between 150 μm and 450 μm, between 150 μm and 425 μm, between 150 μm and 400 μm, between 150 μm and 375 μm, between 150 μm and 350 μm, between 150 μm and 325 μm, between 150 μm and 300 μm, between 150 μm and 275 μm, between 150 μm and 250 μm, between 150 μm and 225 μm, between 150 μm and 200 μm, between 150 μm and 175 μm, between 170 μm and 975 μm, between 170 μm and 950 μm, between 170 μm and 925 μm, between 170 μm and 900 μm, between 170 μm and 875 μm, between 170 μm and 850 μm, between 170 μm and 825 μm, between 170 μm and 800 μm, between 170 μm and 775 μm, between 170 μm and 750 μm, between 170 μm and 725 μm, between 170 μm and 700 μm, between 170 μm and 675 μm, between 170 μm and 650 μm, between 170 μm and 625 μm, between 170 μm and 600 μm, between 170 μm and 575 μm, between 170 μm and 550 μm, between 170 μm and 525 μm, between 170 μm and 500 μm, between 170 μm and 475 μm, between 170 μm and 450 μm, between 170 μm and 425 μm, between 170 μm and 400 μm, between 170 μm and 375 μm, between 170 μm and 350 μm, between 170 μm and 325 μm, between 170 μm and 300 μm, between 170 μm and 275 μm, between 170 μm and 250 μm, between 170 μm and 225 μm, between 170 μm and 200 μm, between 170 μm and 175 μm, between 190 μm and 975 μm, between 190 μm and 950 μm, between 190 μm and 925 μm, between 190 μm and 900 μm, between 190 μm and 875 μm, between 190 μm and 850 μm, between 190 μm and 825 μm, between 190 μm and 800 μm, between 190 μm and 775 μm, between 190 μm and 750 μm, between 190 μm and 725 μm, between 190 μm and 700 μm, between 190 μm and 675 μm, between 190 μm and 650 μm, between 190 μm and 625 μm, between 190 μm and 600 μm, between 190 μm and 575 μm, between 190 μm and 550 μm, between 190 μm and 525 μm, between 190 μm and 500 μm, between 190 μm and 475 μm, between 190 μm and 450 μm, between 190 μm and 425 μm, between 190 μm and 400 μm, between 190 μm and 375 μm, between 190 μm and 350 μm, between 190 μm and 325 μm, between 190 μm and 300 μm, between 190 μm and 275 μm, between 190 μm and 250 μm, between 190 μm and 225 μm, between 190 μm and 200 μm, between 210 μm and 975 μm, between 210 μm and 950 μm, between 210 μm and 925 μm, between 210 μm and 900 μm, between 210 μm and 875 μm, between 210 μm and 850 μm, between 210 μm and 825 μm, between 210 μm and 800 μm, between 210 μm and 775 μm, between 210 μm and 750 μm, between 210 μm and 725 μm, between 210 μm and 700 μm, between 210 μm and 675 μm, between 210 μm and 650 μm, between 210 μm and 625 μm, between 210 μm and 600 μm, between 210 μm and 575 μm, between 210 μm and 550 μm, between 210 μm and 525 μm, between 210 μm and 500 μm, between 210 μm and 475 μm, between 210 μm and 450 μm, between 210 μm and 425 μm, between 210 μm and 400 μm, between 210 μm and 375 μm, between 210 μm and 350 μm, between 210 μm and 325 μm, between 210 μm and 300 μm, between 210 μm and 275 μm, between 210 μm and 250 μm, between 210 μm and 225 μm, between 230 μm and 975 μm, between 230 μm and 950 μm, between 230 μm and 925 μm, between 230 μm and 900 μm, between 230 μm and 875 μm, between 230 μm and 850 μm, between 230 μm and 825 μm, between 230 μm and 800 μm, between 230 μm and 775 μm, between 230 μm and 750 μm, between 230 μm and 725 μm, between 230 μm and 700 μm, between 230 μm and 675 μm, between 230 μm and 650 μm, between 230 μm and 625 μm, between 230 μm and 600 μm, between 230 μm and 575 μm, between 230 μm and 550 μm, between 230 μm and 525 μm, between 230 μm and 500 μm, between 230 μm and 475 μm, between 230 μm and 450 μm, between 230 μm and 425 μm, between 230 μm and 400 μm, between 230 μm and 375 μm, between 230 μm and 350 μm, between 230 μm and 325 μm, between 230 μm and 300 μm, between 230 μm and 275 μm, between 230 μm and 250 μm, between 250 μm and 975 μm, between 250 μm and 950 μm, between 250 μm and 925 μm, between 250 μm and 900 μm, between 250 μm and 875 μm, between 250 μm and 850 μm, between 250 μm and 825 μm, between 250 μm and 800 μm, between 250 μm and 775 μm, between 250 μm and 750 μm, between 250 μm and 725 μm, between 250 μm and 700 μm, between 250 μm and 675 μm, between 250 μm and 650 μm, between 250 μm and 625 μm, between 250 μm and 600 μm, between 250 μm and 575 μm, between 250 μm and 550 μm, between 250 μm and 525 μm, between 250 μm and 500 μm, between 250 μm and 475 μm, between 250 μm and 450 μm, between 250 μm and 425 μm, between 250 μm and 400 μm, between 250 μm and 375 μm, between 250 μm and 350 μm, between 250 μm and 325 μm, between 250 μm and 300 μm, between 250 μm and 275 μm, between 270 μm and 975 μm, between 270 μm and 950 μm, between 270 μm and 925 μm, between 270 μm and 900 μm, between 270 μm and 875 μm, between 270 μm and 850 μm, between 270 μm and 825 μm, between 270 μm and 800 μm, between 270 μm and 775 μm, between 270 μm and 750 μm, between 270 μm and 725 μm, between 270 μm and 700 μm, between 270 μm and 675 μm, between 270 μm and 650 μm, between 270 μm and 625 μm, between 270 μm and 600 μm, between 270 μm and 575 μm, between 270 μm and 550 μm, between 270 μm and 525 μm, between 270 μm and 500 μm, between 270 μm and 475 μm, between 270 μm and 450 μm, between 270 μm and 425 μm, between 270 μm and 400 μm, between 270 μm and 375 μm, between 270 μm and 350 μm, between 270 μm and 325 μm, between 270 μm and 300 μm, between 270 μm and 275 μm, between 290 μm and 975 μm, between 290 μm and 950 μm, between 290 μm and 925 μm, between 290 μm and 900 μm, between 290 μm and 875 μm, between 290 μm and 850 μm, between 290 μm and 825 μm, between 290 μm and 800 μm, between 290 μm and 775 μm, between 290 μm and 750 μm, between 290 μm and 725 μm, between 290 μm and 700 μm, between 290 μm and 675 μm, between 290 μm and 650 μm, between 290 μm and 625 μm, between 290 μm and 600 μm, between 290 μm and 575 μm, between 290 μm and 550 μm, between 290 μm and 525 μm, between 290 μm and 500 μm, between 290 μm and 475 μm, between 290 μm and 450 μm, between 290 μm and 425 μm, between 290 μm and 400 μm, between 290 μm and 375 μm, between 290 μm and 350 μm, between 290 μm and 325 μm, between 290 μm and 300 μm, between 310 μm and 975 μm, between 310 μm and 950 μm, between 310 μm and 925 μm, between 310 μm and 900 μm, between 310 μm and 875 μm, between 310 μm and 850 μm, between 310 μm and 825 μm, between 310 μm and 800 μm, between 310 μm and 775 μm, between 310 μm and 750 μm, between 310 μm and 725 μm, between 310 μm and 700 μm, between 310 μm and 675 μm, between 310 μm and 650 μm, between 310 μm and 625 μm, between 310 μm and 600 μm, between 310 μm and 575 μm, between 310 μm and 550 μm, between 310 μm and 525 μm, between 310 μm and 500 μm, between 310 μm and 475 μm, between 310 μm and 450 μm, between 310 μm and 425 μm, between 310 μm and 400 μm, between 310 μm and 375 μm, between 310 μm and 350 μm, between 310 μm and 325 μm, between 330 μm and 975 μm, between 330 μm and 950 μm, between 330 μm and 925 μm, between 330 μm and 900 μm, between 330 μm and 875 μm, between 330 μm and 850 μm, between 330 μm and 825 μm, between 330 μm and 800 μm, between 330 μm and 775 μm, between 330 μm and 750 μm, between 330 μm and 725 μm, between 330 μm and 700 μm, between 330 μm and 675 μm, between 330 μm and 650 μm, between 330 μm and 625 μm, between 330 μm and 600 μm, between 330 μm and 575 μm, between 330 μm and 550 μm, between 330 μm and 525 μm, between 330 μm and 500 μm, between 330 μm and 475 μm, between 330 μm and 450 μm, between 330 μm and 425 μm, between 330 μm and 400 μm, between 330 μm and 375 μm, between 330 μm and 350 μm, between 350 μm and 975 μm, between 350 μm and 950 μm, between 350 μm and 925 μm, between 350 μm and 900 μm, between 350 μm and 875 μm, between 350 μm and 850 μm, between 350 μm and 825 μm, between 350 μm and 800 μm, between 350 μm and 775 μm, between 350 μm and 750 μm, between 350 μm and 725 μm, between 350 μm and 700 μm, between 350 μm and 675 μm, between 350 μm and 650 μm, between 350 μm and 625 μm, between 350 μm and 600 μm, between 350 μm and 575 μm, between 350 μm and 550 μm, between 350 μm and 525 μm, between 350 μm and 500 μm, between 350 μm and 475 μm, between 350 μm and 450 μm, between 350 μm and 425 μm, between 350 μm and 400 μm, between 350 μm and 375 μm, between 370 μm and 975 μm, between 370 μm and 950 μm, between 370 μm and 925 μm, between 370 μm and 900 μm, between 370 μm and 875 μm, between 370 μm and 850 μm, between 370 μm and 825 μm, between 370 μm and 800 μm, between 370 μm and 775 μm, between 370 μm and 750 μm, between 370 μm and 725 μm, between 370 μm and 700 μm, between 370 μm and 675 μm, between 370 μm and 650 μm, between 370 μm and 625 μm, between 370 μm and 600 μm, between 370 μm and 575 μm, between 370 μm and 550 μm, between 370 μm and 525 μm, between 370 μm and 500 μm, between 370 μm and 475 μm, between 370 μm and 450 μm, between 370 μm and 425 μm, between 370 μm and 400 μm, between 370 μm and 375 μm, between 390 μm and 975 μm, between 390 μm and 950 μm, between 390 μm and 925 μm, between 390 μm and 900 μm, between 390 μm and 875 μm, between 390 μm and 850 μm, between 390 μm and 825 μm, between 390 μm and 800 μm, between 390 μm and 775 μm, between 390 μm and 750 μm, between 390 μm and 725 μm, between 390 μm and 700 μm, between 390 μm and 675 μm, between 390 μm and 650 μm, between 390 μm and 625 μm, between 390 μm and 600 μm, between 390 μm and 575 μm, between 390 μm and 550 μm, between 390 μm and 525 μm, between 390 μm and 500 μm, between 390 μm and 475 μm, between 390 μm and 450 μm, between 390 μm and 425 μm, between 390 μm and 400 μm, between 410 μm and 975 μm, between 410 μm and 950 μm, between 410 μm and 925 μm, between 410 μm and 900 μm, between 410 μm and 875 μm, between 410 μm and 850 μm, between 410 μm and 825 μm, between 410 μm and 800 μm, between 410 μm and 775 μm, between 410 μm and 750 μm, between 410 μm and 725 μm, between 410 μm and 700 μm, between 410 μm and 675 μm, between 410 μm and 650 μm, between 410 μm and 625 μm, between 410 μm and 600 μm, between 410 μm and 575 μm, between 410 μm and 550 μm, between 410 μm and 525 μm, between 410 μm and 500 μm, between 410 μm and 475 μm, between 410 μm and 450 μm, between 410 μm and 425 μm, between 410 μm and 400 μm, between 430 μm and 975 μm, between 430 μm and 950 μm, between 430 μm and 925 μm, between 430 μm and 900 μm, between 430 μm and 875 μm, between 430 μm and 850 μm, between 430 μm and 825 μm, between 430 μm and 800 μm, between 430 μm and 775 μm, between 430 μm and 750 μm, between 430 μm and 725 μm, between 430 μm and 700 μm, between 430 μm and 675 μm, between 430 μm and 650 μm, between 430 μm and 625 μm, between 430 μm and 600 μm, between 430 μm and 575 μm, between 430 μm and 550 μm, between 430 μm and 525 μm, between 430 μm and 500 μm, between 430 μm and 475 μm, between 430 μm and 450 μm, between 450 μm and 975 μm, between 450 μm and 950 μm, between 450 μm and 925 μm, between 450 μm and 900 μm, between 450 μm and 875 μm, between 450 μm and 850 μm, between 450 μm and 825 μm, between 450 μm and 800 μm, between 450 μm and 775 μm, between 450 μm and 750 μm, between 450 μm and 725 μm, between 450 μm and 700 μm, between 450 μm and 675 μm, between 450 μm and 650 μm, between 450 μm and 625 μm, between 450 μm and 600 μm, between 450 μm and 575 μm, between 450 μm and 550 μm, between 450 μm and 525 μm, between 450 μm and 500 μm, between 450 μm and 475 μm, between 470 μm and 975 μm, between 470 μm and 950 μm, between 470 μm and 925 μm, between 470 μm and 900 μm, between 470 μm and 875 μm, between 470 μm and 850 μm, between 470 μm and 825 μm, between 470 μm and 800 μm, between 470 μm and 775 μm, between 470 μm and 750 μm, between 470 μm and 725 μm, between 470 μm and 700 μm, between 470 μm and 675 μm, between 470 μm and 650 μm, between 470 μm and 625 μm, between 470 μm and 600 μm, between 470 μm and 575 μm, between 470 μm and 550 μm, between 470 μm and 525 μm, between 470 μm and 500 μm, between 470 μm and 475 μm, between 490 μm and 975 μm, between 490 μm and 950 μm, between 490 μm and 925 μm, between 490 μm and 900 μm, between 490 μm and 875 μm, between 490 μm and 850 μm, between 490 μm and 825 μm, between 490 μm and 800 μm, between 490 μm and 775 μm, between 490 μm and 750 μm, between 490 μm and 725 μm, between 490 μm and 700 μm, between 490 μm and 675 μm, between 490 μm and 650 μm, between 490 μm and 625 μm, between 490 μm and 600 μm, between 490 μm and 575 μm, between 490 μm and 550 μm, between 490 μm and 525 μm, between 490 μm and 500 μm, between 510 μm and 975 μm, between 510 μm and 950 μm, between 510 μm and 925 μm, between 510 μm and 900 μm, between 510 μm and 875 μm, between 510 μm and 850 μm, between 510 μm and 825 μm, between 510 μm and 800 μm, between 510 μm and 775 μm, between 510 μm and 750 μm, between 510 μm and 725 μm, between 510 μm and 700 μm, between 510 μm and 675 μm, between 510 μm and 650 μm, between 510 μm and 625 μm, between 510 μm and 600 μm, between 510 μm and 575 μm, between 510 μm and 550 μm, between 510 μm and 525 μm, between 530 μm and 975 μm, between 530 μm and 950 μm, between 530 μm and 925 μm, between 530 μm and 900 μm, between 530 μm and 875 μm, between 530 μm and 850 μm, between 530 μm and 825 μm, between 530 μm and 800 μm, between 530 μm and 775 μm, between 530 μm and 750 μm, between 530 μm and 725 μm, between 530 μm and 700 μm, between 530 μm and 675 μm, between 530 μm and 650 μm, between 530 μm and 625 μm, between 530 μm and 600 μm, between 530 μm and 575 μm, between 530 μm and 550 μm, between 550 μm and 975 μm, between 550 μm and 950 μm, between 550 μm and 925 μm, between 550 μm and 900 μm, between 550 μm and 875 μm, between 550 μm and 850 μm, between 550 μm and 825 μm, between 550 μm and 800 μm, between 550 μm and 775 μm, between 550 μm and 750 μm, between 550 μm and 725 μm, between 550 μm and 700 μm, between 550 μm and 675 μm, between 550 μm and 650 μm, between 550 μm and 625 μm, between 550 μm and 600 μm, between 550 μm and 575 μm, between 570 μm and 975 μm, between 570 μm and 950 μm, between 570 μm and 925 μm, between 570 μm and 900 μm, between 570 μm and 875 μm, between 570 μm and 850 μm, between 570 μm and 825 μm, between 570 μm and 800 μm, between 570 μm and 775 μm, between 570 μm and 750 μm, between 570 μm and 725 μm, between 570 μm and 700 μm, between 570 μm and 675 μm, between 570 μm and 650 μm, between 570 μm and 625 μm, between 570 μm and 600 μm, between 570 μm and 575 μm, between 590 μm and 975 μm, between 590 μm and 950 μm, between 590 μm and 925 μm, between 590 μm and 900 μm, between 590 μm and 875 μm, between 590 μm and 850 μm, between 590 μm and 825 μm, between 590 μm and 800 μm, between 590 μm and 775 μm, between 590 μm and 750 μm, between 590 μm and 725 μm, between 590 μm and 700 μm, between 590 μm and 675 μm, between 590 μm and 650 μm, between 590 μm and 625 μm, between 590 μm and 600 μm, between 610 μm and 975 μm, between 610 μm and 950 μm, between 610 μm and 925 μm, between 610 μm and 900 μm, between 610 μm and 875 μm, between 610 μm and 850 μm, between 610 μm and 825 μm, between 610 μm and 800 μm, between 610 μm and 775 μm, between 610 μm and 750 μm, between 610 μm and 725 μm, between 610 μm and 700 μm, between 610 μm and 675 μm, between 610 μm and 650 μm, between 610 μm and 625 μm, between 630 μm and 975 μm, between 630 μm and 950 μm, between 630 μm and 925 μm, between 630 μm and 900 μm, between 630 μm and 875 μm, between 630 μm and 850 μm, between 630 μm and 825 μm, between 630 μm and 800 μm, between 630 μm and 775 μm, between 630 μm and 750 μm, between 630 μm and 725 μm, between 630 μm and 700 μm, between 630 μm and 675 μm, between 630 μm and 650 μm, between 650 μm and 975 μm, between 650 μm and 950 μm, between 650 μm and 925 μm, between 650 μm and 900 μm, between 650 μm and 875 μm, between 650 μm and 850 μm, between 650 μm and 825 μm, between 650 μm and 800 μm, between 650 μm and 775 μm, between 650 μm and 750 μm, between 650 μm and 725 μm, between 650 μm and 700 μm, between 650 μm and 675 μm, between 670 μm and 975 μm, between 670 μm and 950 μm, between 670 μm and 925 μm, between 670 μm and 900 μm, between 670 μm and 875 μm, between 670 μm and 850 μm, between 670 μm and 825 μm, between 670 μm and 800 μm, between 670 μm and 775 μm, between 670 μm and 750 μm, between 670 μm and 725 μm, between 670 μm and 700 μm, between 670 μm and 675 μm, between 690 μm and 975 μm, between 690 μm and 950 μm, between 690 μm and 925 μm, between 690 μm and 900 μm, between 690 μm and 875 μm, between 690 μm and 850 μm, between 690 μm and 825 μm, between 690 μm and 800 μm, between 690 μm and 775 μm, between 690 μm and 750 μm, between 690 μm and 725 μm, between 690 μm and 700 μm, between 710 μm and 975 μm, between 710 μm and 950 μm, between 710 μm and 925 μm, between 710 μm and 900 μm, between 710 μm and 875 μm, between 710 μm and 850 μm, between 710 μm and 825 μm, between 710 μm and 800 μm, between 710 μm and 775 μm, between 710 μm and 750 μm, between 710 μm and 725 μm, between 730 μm and 975 μm, between 730 μm and 950 μm, between 730 μm and 925 μm, between 730 μm and 900 μm, between 730 μm and 875 μm, between 730 μm and 850 μm, between 730 μm and 825 μm, between 730 μm and 800 μm, between 730 μm and 775 μm, between 730 μm and 750 μm, between 750 μm and 975 μm, between 750 μm and 950 μm, between 750 μm and 925 μm, between 750 μm and 900 μm, between 750 μm and 875 μm, between 750 μm and 850 μm, between 750 μm and 825 μm, between 750 μm and 800 μm, between 750 μm and 775 μm, between 770 μm and 975 μm, between 770 μm and 950 μm, between 770 μm and 925 μm, between 770 μm and 900 μm, between 770 μm and 875 μm, between 770 μm and 850 μm, between 770 μm and 825 μm, between 770 μm and 800 μm, between 770 μm and 775 μm, between 790 μm and 975 μm, between 790 μm and 950 μm, between 790 μm and 925 μm, between 790 μm and 900 μm, between 790 μm and 875 μm, between 790 μm and 850 μm, between 790 μm and 825 μm, between 790 μm and 800 μm, between 810 μm and 975 μm, between 810 μm and 950 μm, between 810 μm and 925 μm, between 810 μm and 900 μm, between 810 μm and 875 μm, between 810 μm and 850 μm, between 810 μm and 825 μm, between 830 μm and 975 μm, between 830 μm and 950 μm, between 830 μm and 925 μm, between 830 μm and 900 μm, between 830 μm and 875 μm, between 830 μm and 850 μm, between 850 μm and 975 μm, between 850 μm and 950 μm, between 850 μm and 925 μm, between 850 μm and 900 μm, between 850 μm and 875 μm, between 870 μm and 975 μm, between 870 μm and 950 μm, between 870 μm and 925 μm, between 870 μm and 900 μm, between 870 μm and 875 μm, between 890 μm and 975 μm, between 890 μm and 950 μm, between 890 μm and 925 μm, between 890 μm and 900 μm, between 910 μm and 975 μm, between 910 μm and 950 μm, between 910 μm and 925 μm, between 930 μm and 975 μm, between 930 μm and 950 μm, between 950 μm and 975 μm, or between 970 μm and 975 μm.

In some embodiments, the nominal diameter or a width of a cross-section of the via is at least 5 μm, at least 10 μm, at least 15 μm, at least 20 μm, at least 25 μm, at least 30 μm, at least 35 μm, at least 40 μm, at least 45 μm, at least 50 μm, at least 55 μm, at least 60 μm, at least 65 μm, at least 70 μm, at least 75 μm, at least 80 μm, at least 85 μm, at least 90 μm, at least 95 μm, at least 100 μm, at least 105 μm, at least 110 μm, at least 115 μm, at least 120 μm, at least 125 μm, at least 130 μm, at least 135 μm, at least 140 μm, at least 145 μm, at least 150 μm, at least 155 μm, at least 160 μm, at least 165 μm, at least 170 μm, at least 175 μm, at least 180 μm, at least 185 μm, at least 190 μm, at least 195 μm, at least 200 μm, at least 205 μm, at least 210 μm, at least 215 μm, at least 220 μm, at least 225 μm, at least 230 μm, at least 235 μm, at least 240 μm, at least 245 μm, at least 250 μm, at least 255 μm, at least 260 μm, at least 265 μm, at least 270 μm, at least 275 μm, at least 280 μm, at least 285 μm, at least 290 μm, at least 295 μm, at least 300 μm, at least 305 μm, at least 310 μm, at least 315 μm, at least 320 μm, at least 325 μm, at least 330 μm, at least 335 μm, at least 340 μm, at least 345 μm, at least 350 μm, at least 355 μm, at least 360 μm, at least 365 μm, at least 370 μm, at least 375 μm, at least 380 μm, at least 385 μm, at least 390 μm, at least 395 μm, at least 400 μm, at least 405 μm, at least 410 μm, at least 415 μm, at least 420 μm, at least 425 μm, at least 430 μm, at least 435 μm, at least 440 μm, at least 445 μm, at least 450 μm, at least 455 μm, at least 460 μm, at least 465 μm, at least 470 μm, at least 475 μm, at least 480 μm, at least 485 μm, at least 490 μm, at least 495 μm, at least 500 μm, at least 505 μm, at least 510 μm, at least 515 μm, at least 520 μm, at least 525 μm, at least 530 μm, at least 535 μm, at least 540 μm, at least 545 μm, at least 550 μm, at least 555 μm, at least 560 μm, at least 565 μm, at least 570 μm, at least 575 μm, at least 580 μm, at least 585 μm, at least 590 μm, at least 595 μm, at least 600 μm, at least 605 μm, at least 610 μm, at least 615 μm, at least 620 μm, at least 625 μm, at least 630 μm, at least 635 μm, at least 640 μm, at least 645 μm, at least 650 μm, at least 655 μm, at least 660 μm, at least 665 μm, at least 670 μm, at least 675 μm, at least 680 μm, at least 685 μm, at least 690 μm, at least 695 μm, at least 700 μm, at least 705 μm, at least 710 μm, at least 715 μm, at least 720 μm, at least 725 μm, at least 730 μm, at least 735 μm, at least 740 μm, at least 745 μm, at least 750 μm, at least 755 μm, at least 760 μm, at least 765 μm, at least 770 μm, at least 775 μm, at least 780 μm, at least 785 μm, at least 790 μm, at least 795 μm, at least 800 μm, at least 805 μm, at least 810 μm, at least 815 μm, at least 820 μm, at least 825 μm, at least 830 μm, at least 835 μm, at least 840 μm, at least 845 μm, at least 850 μm, at least 855 μm, at least 860 μm, at least 865 μm, at least 870 μm, at least 875 μm, at least 880 μm, at least 885 μm, at least 890 μm, at least 895 μm, at least 900 μm, at least 905 μm, at least 910 μm, at least 915 μm, at least 920 μm, at least 925 μm, at least 930 μm, at least 935 μm, at least 940 μm, at least 945 μm, at least 950 μm, at least 955 μm, at least 960 μm, at least 965 μm, at least 970 μm, at least 975 μm, at least 980 μm, at least 985 μm, at least 990 μm, at least 995 μm, or at least 1,000 μm.

In some embodiments, the nominal diameter or a width of a cross-section of the via is at most 5 μm, at most 10 μm, at most 15 μm, at most 20 μm, at most 25 μm, at most 30 μm, at most 35 μm, at most 40 μm, at most 45 μm, at most 50 μm, at most 55 μm, at most 60 μm, at most 65 μm, at most 70 μm, at most 75 μm, at most 80 μm, at most 85 μm, at most 90 μm, at most 95 μm, at most 100 μm, at most 105 μm, at most 110 μm, at most 115 μm, at most 120 μm, at most 125 μm, at most 130 μm, at most 135 μm, at most 140 μm, at most 145 μm, at most 150 μm, at most 155 μm, at most 160 μm, at most 165 μm, at most 170 μm, at most 175 μm, at most 180 μm, at most 185 μm, at most 190 μm, at most 195 μm, at most 200 μm, at most 205 μm, at most 210 μm, at most 215 μm, at most 220 μm, at most 225 μm, at most 230 μm, at most 235 μm, at most 240 μm, at most 245 μm, at most 250 μm, at most 255 μm, at most 260 μm, at most 265 μm, at most 270 μm, at most 275 μm, at most 280 μm, at most 285 μm, at most 290 μm, at most 295 μm, at most 300 μm, at most 305 μm, at most 310 μm, at most 315 μm, at most 320 μm, at most 325 μm, at most 330 μm, at most 335 μm, at most 340 μm, at most 345 μm, at most 350 μm, at most 355 μm, at most 360 μm, at most 365 μm, at most 370 μm, at most 375 μm, at most 380 μm, at most 385 μm, at most 390 μm, at most 395 μm, at most 400 μm, at most 405 μm, at most 410 μm, at most 415 μm, at most 420 μm, at most 425 μm, at most 430 μm, at most 435 μm, at most 440 μm, at most 445 μm, at most 450 μm, at most 455 μm, at most 460 μm, at most 465 μm, at most 470 μm, at most 475 μm, at most 480 μm, at most 485 μm, at most 490 μm, at most 495 μm, at most 500 μm, at most 505 μm, at most 510 μm, at most 515 μm, at most 520 μm, at most 525 μm, at most 530 μm, at most 535 μm, at most 540 μm, at most 545 μm, at most 550 μm, at most 555 μm, at most 560 μm, at most 565 μm, at most 570 μm, at most 575 μm, at most 580 μm, at most 585 μm, at most 590 μm, at most 595 μm, at most 600 μm, at most 605 μm, at most 610 μm, at most 615 μm, at most 620 μm, at most 625 μm, at most 630 μm, at most 635 μm, at most 640 μm, at most 645 μm, at most 650 μm, at most 655 μm, at most 660 μm, at most 665 μm, at most 670 μm, at most 675 μm, at most 680 μm, at most 685 μm, at most 690 μm, at most 695 μm, at most 700 μm, at most 705 μm, at most 710 μm, at most 715 μm, at most 720 μm, at most 725 μm, at most 730 μm, at most 735 μm, at most 740 μm, at most 745 μm, at most 750 μm, at most 755 μm, at most 760 μm, at most 765 μm, at most 770 μm, at most 775 μm, at most 780 μm, at most 785 μm, at most 790 μm, at most 795 μm, at most 800 μm, at most 805 μm, at most 810 μm, at most 815 μm, at most 820 μm, at most 825 μm, at most 830 μm, at most 835 μm, at most 840 μm, at most 845 μm, at most 850 μm, at most 855 μm, at most 860 μm, at most 865 μm, at most 870 μm, at most 875 μm, at most 880 μm, at most 885 μm, at most 890 μm, at most 895 μm, at most 900 μm, at most 905 μm, at most 910 μm, at most 915 μm, at most 920 μm, at most 925 μm, at most 930 μm, at most 935 μm, at most 940 μm, at most 945 μm, at most 950 μm, at most 955 μm, at most 960 μm, at most 965 μm, at most 970 μm, at most 975 μm, at most 980 μm, at most 985 μm, at most 990 μm, at most 995 μm, or at least 1,000 μm.

In some embodiments, the nominal diameter or a width of a cross-section of the via is between 0.1 mil and 40 mil, between 0.2 mil and 40 mil, between 0.2 mil and 35 mil, between 0.2 and 30 mil, between 0.2 mil and 25 mil, between 0.2 and 20 mil, between 0.2 mil and 15 mil, between 0.2 and 10 mil, between 0.2 mil and 5 mil, between 0.2 and 1 mil, between 0.4 mil and 40 mil, between 0.4 mil and 35 mil, between 0.4 and 30 mil, between 0.4 mil and 25 mil, between 0.4 and 20 mil, between 0.4 mil and 15 mil, between 0.4 and 10 mil, between 0.4 mil and 5 mil, between 0.4 and 1 mil, between 0.6 mil and 40 mil, between 0.6 mil and 35 mil, between 0.6 and 30 mil, between 0.6 mil and 25 mil, between 0.6 and 20 mil, between 0.6 mil and 15 mil, between 0.6 and 10 mil, between 0.6 mil and 5 mil, between 0.6 and 1 mil, between 0.8 mil and 40 mil, between 0.8 mil and 35 mil, between 0.8 and 30 mil, between 0.8 mil and 25 mil, between 0.8 and 20 mil, between 0.8 mil and 15 mil, between 0.8 and 10 mil, between 0.8 mil and 5 mil, between 0.8 and 1 mil, between 1.2 mil and 40 mil, between 1.2 mil and 35 mil, between 1.2 and 30 mil, between 1.2 mil and 25 mil, between 1.2 and 20 mil, between 1.2 mil and 15 mil, between 1.2 and 10 mil, between 1.2 mil and 5 mil, between 1.2 and 3 mil, between 1.7 mil and 40 mil, between 1.7 mil and 35 mil, between 1.7 and 30 mil, between 1.7 mil and 25 mil, between 1.7 and 20 mil, between 1.7 mil and 15 mil, between 1.7 and 10 mil, between 1.7 mil and 5 mil, between 1.7 and 3 mil, between 2.2 mil and 40 mil, between 2.2 mil and 35 mil, between 2.2 and 30 mil, between 2.2 mil and 25 mil, between 2.2 and 20 mil, between 2.2 mil and 15 mil, between 2.2 and 10 mil, between 2.2 mil and 5 mil, between 2.2 and 3 mil, between 2.7 mil and 40 mil, between 2.7 mil and 35 mil, between 2.7 and 30 mil, between 2.7 mil and 25 mil, between 2.7 and 20 mil, between 2.7 mil and 15 mil, between 2.7 and 10 mil, between 2.7 mil and 5 mil, between 2.7 and 3 mil, between 3.2 mil and 40 mil, between 3.2 mil and 35 mil, between 3.2 and 30 mil, between 3.2 mil and 25 mil, between 3.2 and 20 mil, between 3.2 mil and 15 mil, between 3.2 and 10 mil, between 3.2 mil and 5 mil, between 3.7 mil and 40 mil, between 3.7 mil and 35 mil, between 3.7 and 30 mil, between 3.7 mil and 25 mil, between 3.7 and 20 mil, between 3.7 mil and 15 mil, between 3.7 and 10 mil, between 3.7 mil and 5 mil, between 4.2 mil and 40 mil, between 4.2 mil and 35 mil, between 4.2 and 30 mil, between 4.2 mil and 25 mil, between 4.2 and 20 mil, between 4.2 mil and 15 mil, between 4.2 and 10 mil, between 4.2 mil and 5 mil, between 4.7 mil and 40 mil, between 4.7 mil and 35 mil, between 4.7 and 30 mil, between 4.7 mil and 25 mil, between 4.7 and 20 mil, between 4.7 mil and 15 mil, between 4.7 and 10 mil, between 4.7 mil and 5 mil, between 5.2 mil and 40 mil, between 5.2 mil and 35 mil, between 5.2 and 30 mil, between 5.2 mil and 25 mil, between 5.2 and 20 mil, between 5.2 mil and 15 mil, between 5.2 and 10 mil, between 5.7 mil and 40 mil, between 5.7 mil and 35 mil, between 5.7 and 30 mil, between 5.7 mil and 25 mil, between 5.7 and 20 mil, between 5.7 mil and 15 mil, between 5.7 and 10 mil, between 6.2 mil and 40 mil, between 6.2 mil and 35 mil, between 6.2 and 30 mil, between 6.2 mil and 25 mil, between 6.2 and 20 mil, between 6.2 mil and 15 mil, between 6.2 and 10 mil, between 6.7 mil and 40 mil, between 6.7 mil and 35 mil, between 6.7 and 30 mil, between 6.7 mil and 25 mil, between 6.7 and 20 mil, between 6.7 mil and 15 mil, between 6.7 and 10 mil, between 7.2 mil and 40 mil, between 7.2 mil and 35 mil, between 7.2 and 30 mil, between 7.2 mil and 25 mil, between 7.2 and 20 mil, between 7.2 mil and 15 mil, between 7.2 and 10 mil, between 7.7 mil and 40 mil, between 7.7 mil and 35 mil, between 7.7 and 30 mil, between 7.7 mil and 25 mil, between 7.7 and 20 mil, between 7.7 mil and 15 mil, between 7.7 and 10 mil, between 8.2 mil and 40 mil, between 8.2 mil and 35 mil, between 8.2 and 30 mil, between 8.2 mil and 25 mil, between 8.2 and 20 mil, between 8.2 mil and 15 mil, between 8.2 and 10 mil, between 8.7 mil and 40 mil, between 8.7 mil and 35 mil, between 8.7 and 30 mil, between 8.7 mil and 25 mil, between 8.7 and 20 mil, between 8.7 mil and 15 mil, between 8.7 and 10 mil, between 9.2 mil and 40 mil, between 9.2 mil and 35 mil, between 9.2 and 30 mil, between 9.2 mil and 25 mil, between 9.2 and 20 mil, between 9.2 mil and 15 mil, between 9.2 and 10 mil, between 9.7 mil and 40 mil, between 9.7 mil and 35 mil, between 9.7 and 30 mil, between 9.7 mil and 25 mil, between 9.7 and 20 mil, between 9.7 mil and 15 mil, between 9.7 and 10 mil, between 11.2 mil and 40 mil, between 11.2 mil and 35 mil, between 11.2 and 30 mil, between 11.2 mil and 25 mil, between 11.2 and 20 mil, between 11.2 mil and 15 mil, between 11.7 mil and 40 mil, between 11.7 mil and 35 mil, between 11.7 and 30 mil, between 11.7 mil and 25 mil, between 11.7 and 20 mil, between 11.7 mil and 15 mil, between 12.2 mil and 40 mil, between 12.2 mil and 35 mil, between 12.2 and 30 mil, between 12.2 mil and 25 mil, between 12.2 and 20 mil, between 12.2 mil and 15 mil, between 12.7 mil and 40 mil, between 12.7 mil and 35 mil, between 12.7 and 30 mil, between 12.7 mil and 25 mil, between 12.7 and 20 mil, between 12.7 mil and 15 mil, between 13.2 mil and 40 mil, between 13.2 mil and 35 mil, between 13.2 and 30 mil, between 13.2 mil and 25 mil, between 13.2 and 20 mil, between 13.2 mil and 15 mil, between 13.7 mil and 40 mil, between 13.7 mil and 35 mil, between 13.7 and 30 mil, between 13.7 mil and 25 mil, between 13.7 and 20 mil, between 13.7 mil and 15 mil, between 14.2 mil and 40 mil, between 14.2 mil and 35 mil, between 14.2 and 30 mil, between 14.2 mil and 25 mil, between 14.2 and 20 mil, between 14.2 mil and 15 mil, between 14.7 mil and 40 mil, between 14.7 mil and 35 mil, between 14.7 and 30 mil, between 14.7 mil and 25 mil, between 14.7 and 20 mil, between 14.7 mil and 15 mil, between 15.2 mil and 40 mil, between 15.2 mil and 35 mil, between 15.2 and 30 mil, between 15.2 mil and 25 mil, between 15.2 and 20 mil, between 15.7 mil and 40 mil, between 15.7 mil and 35 mil, between 15.7 and 30 mil, between 15.7 mil and 25 mil, between 15.7 and 20 mil, between 16.2 mil and 40 mil, between 16.2 mil and 35 mil, between 16.2 and 30 mil, between 16.2 mil and 25 mil, between 16.2 and 20 mil, between 16.7 mil and 40 mil, between 16.7 mil and 35 mil, between 16.7 and 30 mil, between 16.7 mil and 25 mil, between 16.7 and 20 mil, between 17.2 mil and 40 mil, between 17.2 mil and 35 mil, between 17.2 and 30 mil, between 17.2 mil and 25 mil, between 17.2 and 20 mil, between 17.7 mil and 40 mil, between 17.7 mil and 35 mil, between 17.7 and 30 mil, between 17.7 mil and 25 mil, between 17.7 and 20 mil, between 18.2 mil and 40 mil, between 18.2 mil and 35 mil, between 18.2 and 30 mil, between 18.2 mil and 25 mil, between 18.2 and 20 mil, between 18.7 mil and 40 mil, between 18.7 mil and 35 mil, between 18.7 and 30 mil, between 18.7 mil and 25 mil, between 18.7 and 20 mil, between 19.2 mil and 40 mil, between 19.2 mil and 35 mil, between 19.2 and 30 mil, between 19.2 mil and 25 mil, between 19.2 and 20 mil, between 19.7 mil and 40 mil, between 19.7 mil and 35 mil, between 19.7 and 30 mil, between 19.7 mil and 25 mil, between 19.7 and 20 mil, between 21.2 mil and 40 mil, between 21.2 mil and 35 mil, between 21.2 and 30 mil, between 21.2 mil and 25 mil, between 21.7 mil and 40 mil, between 21.7 mil and 35 mil, between 21.7 and 30 mil, between 21.7 mil and 25 mil, between 22.2 mil and 40 mil, between 22.2 mil and 35 mil, between 22.2 and 30 mil, between 22.2 mil and 25 mil, between 22.7 mil and 40 mil, between 22.7 mil and 35 mil, between 22.7 and 30 mil, between 22.7 mil and 25 mil, between 23.2 mil and 40 mil, between 23.2 mil and 35 mil, between 23.2 and 30 mil, between 23.2 mil and 25 mil, between 23.7 mil and 40 mil, between 23.7 mil and 35 mil, between 23.7 and 30 mil, between 23.7 mil and 25 mil, between 24.2 mil and 40 mil, between 24.2 mil and 35 mil, between 24.2 and 30 mil, between 24.2 mil and 25 mil, between 24.7 mil and 40 mil, between 24.7 mil and 35 mil, between 24.7 and 30 mil, between 24.7 mil and 25 mil, between 25.2 mil and 40 mil, between 25.2 mil and 35 mil, between 25.2 and 30 mil, between 25.7 mil and 40 mil, between 25.7 mil and 35 mil, between 25.7 and 30 mil, between 26.2 mil and 40 mil, between 26.2 mil and 35 mil, between 26.2 and 30 mil, between 26.7 mil and 40 mil, between 26.7 mil and 35 mil, between 26.7 and 30 mil, between 27.2 mil and 40 mil, between 27.2 mil and 35 mil, between 27.2 and 30 mil, between 27.7 mil and 40 mil, between 27.7 mil and 35 mil, between 27.7 and 30 mil, between 28.2 mil and 40 mil, between 28.2 mil and 35 mil, between 28.2 and 30 mil, between 28.7 mil and 40 mil, between 28.7 mil and 35 mil, between 28.7 and 30 mil, between 29.2 mil and 40 mil, between 29.2 mil and 35 mil, between 29.2 and 30 mil, between 29.7 mil and 40 mil, between 29.7 mil and 35 mil, between 29.7 and 30 mil, between 31.2 mil and 40 mil, between 31.2 mil and 35 mil, between 31.7 mil and 40 mil, between 31.7 mil and 35 mil, between 32.2 mil and 40 mil, between 32.2 mil and 35 mil, between 32.7 mil and 40 mil, between 32.7 mil and 35 mil, between 33.2 mil and 40 mil, between 33.2 mil and 35 mil, between 33.7 mil and 40 mil, between 33.7 mil and 35 mil, between 34.2 mil and 40 mil, between 34.2 mil and 35 mil, between 34.7 mil and 40 mil, between 34.7 mil and 35 mil, between 35.2 mil and 40 mil, between 35.7 mil and 40 mil, between 36.2 mil and 40 mil, between 36.7 mil and 40 mil, between 37.2 mil and 40 mil, between 37.7 mil and 40 mil, between 38.2 mil and 40 mil, between 38.7 mil and 40 mil, between 39.2 mil and 40 mil, or between 39.7 mil and 40 mil.

In some embodiments, the nominal diameter or a width of a cross-section of the via is at least 0.1 mil, at least 0.3 mil, at least 0.6 mil, at least 0.9 mil, at least 1.1 mil, at least 1.3 mil, at least 1.6 mil, at least 1.9 mil, at least 2.1 mil, at least 2.3 mil, at least 2.6 mil, at least 2.9 mil, at least 3.1 mil, at least 3.3 mil, at least 3.6 mil, at least 3.9 mil, at least 4.1 mil, at least 4.3 mil, at least 4.6 mil, at least 4.9 mil, at least 5.1 mil, at least 5.3 mil, at least 5.6 mil, at least 5.9 mil, at least 6.1 mil, at least 6.3 mil, at least 6.6 mil, at least 6.9 mil, at least 7.1 mil, at least 7.3 mil, at least 7.6 mil, at least 7.9 mil, at least 8.1 mil, at least 8.3 mil, at least 8.6 mil, at least 8.9 mil, at least 9.1 mil, at least 9.3 mil, at least 9.6 mil, at least 9.9 mil, at least 10.1 mil, at least 10.3 mil, at least 10.6 mil, at least 10.9 mil, at least 11.1 mil, at least 11.3 mil, at least 11.6 mil, at least 11.9 mil, at least 12.1 mil, at least 12.3 mil, at least 12.6 mil, at least 12.9 mil, at least 13.1 mil, at least 13.3 mil, at least 13.6 mil, at least 13.9 mil, at least 14.1 mil, at least 14.3 mil, at least 14.6 mil, at least 14.9 mil, at least 15.1 mil, at least 15.3 mil, at least 15.6 mil, at least 15.9 mil, at least 16.1 mil, at least 16.3 mil, at least 16.6 mil, at least 16.9 mil, at least 17.1 mil, at least 17.3 mil, at least 17.6 mil, at least 17.9 mil, at least 18.1 mil, at least 18.3 mil, at least 18.6 mil, at least 18.9 mil, at least 19.1 mil, at least 19.3 mil, at least 19.6 mil, at least 19.9 mil, at least 20.1 mil, at least 20.3 mil, at least 20.6 mil, at least 20.9 mil, at least 21.1 mil, at least 21.3 mil, at least 21.6 mil, at least 21.9 mil, at least 22.1 mil, at least 22.3 mil, at least 22.6 mil, at least 22.9 mil, at least 23.1 mil, at least 23.3 mil, at least 23.6 mil, at least 23.9 mil, at least 24.1 mil, at least 24.3 mil, at least 24.6 mil, at least 24.9 mil, at least 25.1 mil, at least 25.3 mil, at least 25.6 mil, at least 25.9 mil, at least 26.1 mil, at least 26.3 mil, at least 26.6 mil, at least 26.9 mil, at least 27.1 mil, at least 27.3 mil, at least 27.6 mil, at least 27.9 mil, at least 28.1 mil, at least 28.3 mil, at least 28.6 mil, at least 28.9 mil, at least 29.1 mil, at least 29.3 mil, at least 29.6 mil, at least 29.9 mil, at least 30.1 mil, at least 30.3 mil, at least 30.6 mil, at least 30.9 mil, at least 31.1 mil, at least 31.3 mil, at least 31.6 mil, at least 31.9 mil, at least 32.1 mil, at least 32.3 mil, at least 32.6 mil, at least 32.9 mil, at least 33.1 mil, at least 33.3 mil, at least 33.6 mil, at least 33.9 mil, at least 34.1 mil, at least 34.3 mil, at least 34.6 mil, at least 34.9 mil, at least 35.1 mil, at least 35.3 mil, at least 35.6 mil, at least 35.9 mil, at least 36.1 mil, at least 36.3 mil, at least 36.6 mil, at least 36.9 mil, at least 37.1 mil, at least 37.3 mil, at least 37.6 mil, at least 37.9 mil, at least 38.1 mil, at least 38.3 mil, at least 38.6 mil, at least 38.9 mil, at least 39.1 mil, at least 39.3 mil, at least 39.6 mil, or at least 39.9 mil.

In some embodiments, the nominal diameter or a width of a cross-section of the via is at most 0.1 mil, at most 0.3 mil, at most 0.6 mil, at most 0.9 mil, at most 1.1 mil, at most 1.3 mil, at most 1.6 mil, at most 1.9 mil, at most 2.1 mil, at most 2.3 mil, at most 2.6 mil, at most 2.9 mil, at most 3.1 mil, at most 3.3 mil, at most 3.6 mil, at most 3.9 mil, at most 4.1 mil, at most 4.3 mil, at most 4.6 mil, at most 4.9 mil, at most 5.1 mil, at most 5.3 mil, at most 5.6 mil, at most 5.9 mil, at most 6.1 mil, at most 6.3 mil, at most 6.6 mil, at most 6.9 mil, at most 7.1 mil, at most 7.3 mil, at most 7.6 mil, at most 7.9 mil, at most 8.1 mil, at most 8.3 mil, at most 8.6 mil, at most 8.9 mil, at most 9.1 mil, at most 9.3 mil, at most 9.6 mil, at most 9.9 mil, at most 10.1 mil, at most 10.3 mil, at most 10.6 mil, at most 10.9 mil, at most 11.1 mil, at most 11.3 mil, at most 11.6 mil, at most 11.9 mil, at most 12.1 mil, at most 12.3 mil, at most 12.6 mil, at most 12.9 mil, at most 13.1 mil, at most 13.3 mil, at most 13.6 mil, at most 13.9 mil, at most 14.1 mil, at most 14.3 mil, at most 14.6 mil, at most 14.9 mil, at most 15.1 mil, at most 15.3 mil, at most 15.6 mil, at most 15.9 mil, at most 16.1 mil, at most 16.3 mil, at most 16.6 mil, at most 16.9 mil, at most 17.1 mil, at most 17.3 mil, at most 17.6 mil, at most 17.9 mil, at most 18.1 mil, at most 18.3 mil, at most 18.6 mil, at most 18.9 mil, at most 19.1 mil, at most 19.3 mil, at most 19.6 mil, at most 19.9 mil, at most 20.1 mil, at most 20.3 mil, at most 20.6 mil, at most 20.9 mil, at most 21.1 mil, at most 21.3 mil, at most 21.6 mil, at most 21.9 mil, at most 22.1 mil, at most 22.3 mil, at most 22.6 mil, at most 22.9 mil, at most 23.1 mil, at most 23.3 mil, at most 23.6 mil, at most 23.9 mil, at most 24.1 mil, at most 24.3 mil, at most 24.6 mil, at most 24.9 mil, at most 25.1 mil, at most 25.3 mil, at most 25.6 mil, at most 25.9 mil, at most 26.1 mil, at most 26.3 mil, at most 26.6 mil, at most 26.9 mil, at most 27.1 mil, at most 27.3 mil, at most 27.6 mil, at most 27.9 mil, at most 28.1 mil, at most 28.3 mil, at most 28.6 mil, at most 28.9 mil, at most 29.1 mil, at most 29.3 mil, at most 29.6 mil, at most 29.9 mil, at most 30.1 mil, at most 30.3 mil, at most 30.6 mil, at most 30.9 mil, at most 31.1 mil, at most 31.3 mil, at most 31.6 mil, at most 31.9 mil, at most 32.1 mil, at most 32.3 mil, at most 32.6 mil, at most 32.9 mil, at most 33.1 mil, at most 33.3 mil, at most 33.6 mil, at most 33.9 mil, at most 34.1 mil, at most 34.3 mil, at most 34.6 mil, at most 34.9 mil, at most 35.1 mil, at most 35.3 mil, at most 35.6 mil, at most 35.9 mil, at most 36.1 mil, at most 36.3 mil, at most 36.6 mil, at most 36.9 mil, at most 37.1 mil, at most 37.3 mil, at most 37.6 mil, at most 37.9 mil, at most 38.1 mil, at most 38.3 mil, at most 38.6 mil, at most 38.9 mil, at most 39.1 mil, at most 39.3 mil, at most 39.6 mil, or at most 39.9 mil.

As used herein, the term “electrically connect” refers to formation of an electronic connection maintained through a portion of circuit having a resistance below a resistance threshold. In some embodiments, the resistance threshold is between 0.1 Ω/cm and 100 Ω/cm, between 0.1 Ω/cm and 90 Ω/cm, between 0.1 Ω/cm and 700 Ω/cm, between 0.1 Ω/cm and 50 Ω/cm, between 0.1 Ω/cm and 40 Ω/cm, between 0.1 Ω/cm and 30 Ω/cm, between 0.1 Ω/cm and 25 Ω/cm, between 0.1 Ω/cm and 20 Ω/cm, between 0.1 Ω/cm and 10 Ω/cm, between 0.1 Ω/cm and 5 Ω/cm, between 0.1 Ω/cm and 3 Ω/cm, between 0.5 Ω/cm and 100 Ω/cm, between 0.5 Ω/cm and 90 Ω/cm, between 0.5 Ω/cm and 70 Ω/cm, between 0.5 Ω/cm and 50 Ω/cm, between 0.5 Ω/cm and 40 Ω/cm, between 0.5 Ω/cm and 30 Ω/cm, between 0.5 Ω/cm and 25 Ω/cm, between 0.5 Ω/cm and 20 Ω/cm, between 0.5 Ω/cm and 10 Ω/cm, between 0.5 Ω/cm and 5 Ω/cm, between 0.5 Ω/cm and 3 Ω/cm, between 1 Ω/cm and 100 Ω/cm, between 1 Ω/cm and 90 Ω/cm, between 1 Ω/cm and 70 Ω/cm, between 1 Ω/cm and 50 Ω/cm, between 1 Ω/cm and 40 Ω/cm, between 1 Ω/cm and 30 Ω/cm, between 1 Ω/cm and 25 Ω/cm, between 1 Ω/cm and 20 Ω/cm, between 1 Ω/cm and 10 Ω/cm, between 1 Ω/cm and 5 Ω/cm, between 1 Ω/cm and 3 Ω/cm, between 2.5 Ω/cm and 100 Ω/cm, between 2.5 Ω/cm and 90 Ω/cm, between 2.5 Ω/cm and 70 Ω/cm, between 2.5 Ω/cm and 50 Ω/cm, between 2.5 Ω/cm and 40 Ω/cm, between 2.5 Ω/cm and 30 Ω/cm, between 2.5 Ω/cm and 25 Ω/cm, between 2.5 Ω/cm and 20 Ω/cm, between 2.5 Ω/cm and 10 Ω/cm, between 2.5 Ω/cm and 5 Ω/cm, between 2.5 Ω/cm and 3 Ω/cm, between 8 Ω/cm and 100 Ω/cm, between 8 Ω/cm and 90 Ω/cm, between 8 Ω/cm and 70 Ω/cm, between 8 Ω/cm and 50 Ω/cm, between 8 Ω/cm and 40 Ω/cm, between 8 Ω/cm and 30 Ω/cm, between 8 Ω/cm and 25 Ω/cm, between 8 Ω/cm and 20 Ω/cm, between 8 Ω/cm and 10 Ω/cm, between 13 Ω/cm and 100 Ω/cm, between 13 Ω/cm and 90 Ω/cm, between 13 Ω/cm and 70 Ω/cm, between 13 Ω/cm and 50 Ω/cm, between 13 Ω/cm and 40 Ω/cm, between 13 Ω/cm and 30 Ω/cm, between 13 Ω/cm and 25 Ω/cm, between 13 Ω/cm and 20 Ω/cm, between 25 Ω/cm and 100 Ω/cm, between 25 Ω/cm and 90 Ω/cm, between 25 Ω/cm and 70 Ω/cm, between 25 Ω/cm and 50 Ω/cm, between 25 Ω/cm and 40 Ω/cm, between 25 Ω/cm and 30 Ω/cm, between 45 Ω/cm and 100 Ω/cm, between 45 Ω/cm and 90 Ω/cm, between 45 Ω/cm and 70 Ω/cm, between 45 Ω/cm and 50 Ω/cm, between 60 Ω/cm and 100 Ω/cm, between 60 Ω/cm and 90 Ω/cm, between 60 Ω/cm and 70 Ω/cm, between 85 Ω/cm and 100 Ω/cm, or between 85 Ω/cm and 90 Ω/cm.

In some embodiments, the resistance threshold is at least 0.1 Ω/cm, at least 0.4 Ω/cm, at least 0.8 Ω/cm, at least 1 Ω/cm, at least 1.5 Ω/cm, at least 2 Ω/cm, at least 2.5 Ω/cm, at least 3 Ω/cm, at least 3.5 Ω/cm, at least 4 Ω/cm, at least 4.5 Ω/cm, at least 5 Ω/cm, at least 5.5 Ω/cm, at least 6 Ω/cm, at least 6.5 Ω/cm, at least 7 Ω/cm, at least 7.5 Ω/cm, at least 8 Ω/cm, at least 8.5 Ω/cm, at least 9 Ω/cm, at least 9.5 Ω/cm, at least 10 Ω/cm, at least 10.5 Ω/cm, at least 11 Ω/cm, at least 11.5 Ω/cm, at least 12 Ω/cm, at least 12.5 Ω/cm, at least 13 Ω/cm, at least 13.5 Ω/cm, at least 14 Ω/cm, at least 14.5 Ω/cm, at least 15 Ω/cm, at least 15.5 Ω/cm, at least 16 Ω/cm, at least 16.5 Ω/cm, at least 17 Ω/cm, at least 17.5 Ω/cm, at least 18 Ω/cm, at least 18.5 Ω/cm, at least 19 Ω/cm, at least 19.5 Ω/cm, at least 20 Ω/cm, at least 20.5 Ω/cm, at least 21 Ω/cm, at least 21.5 Ω/cm, at least 22 Ω/cm, at least 22.5 Ω/cm, at least 23 Ω/cm, at least 23.5 Ω/cm, at least 24 Ω/cm, at least 24.5 Ω/cm, at least 25 Ω/cm, at least 25.5 Ω/cm, at least 26 Ω/cm, at least 26.5 Ω/cm, at least 27 Ω/cm, at least 27.5 Ω/cm, at least 28 Ω/cm, at least 28.5 Ω/cm, at least 29 Ω/cm, at least 29.5 Ω/cm, at least 30 Ω/cm, at least 30.5 Ω/cm, at least 31 Ω/cm, at least 31.5 Ω/cm, at least 32 Ω/cm, at least 32.5 Ω/cm, at least 33 Ω/cm, at least 33.5 Ω/cm, at least 34 Ω/cm, at least 34.5 Ω/cm, at least 35 Ω/cm, at least 35.5 Ω/cm, at least 36 Ω/cm, at least 36.5 Ω/cm, at least 37 Ω/cm, at least 37.5 Ω/cm, at least 38 Ω/cm, at least 38.5 Ω/cm, at least 39 Ω/cm, at least 39.5 Ω/cm, at least 40 Ω/cm, at least 40.5 Ω/cm, at least 41 Ω/cm, at least 41.5 Ω/cm, at least 42 Ω/cm, at least 42.5 Ω/cm, at least 43 Ω/cm, at least 43.5 Ω/cm, at least 44 Ω/cm, at least 44.5 Ω/cm, at least 45 Ω/cm, at least 45.5 Ω/cm, at least 46 Ω/cm, at least 46.5 Ω/cm, at least 47 Ω/cm, at least 47.5 Ω/cm, at least 48 Ω/cm, at least 48.5 Ω/cm, at least 49 Ω/cm, at least 49.5 Ω/cm, at least 50 Ω/cm, at least 50.5 Ω/cm, at least 51 Ω/cm, at least 51.5 Ω/cm, at least 52 Ω/cm, at least 52.5 Ω/cm, at least 53 Ω/cm, at least 53.5 Ω/cm, at least 54 Ω/cm, at least 54.5 Ω/cm, at least 55 Ω/cm, at least 55.5 Ω/cm, at least 56 Ω/cm, at least 56.5 Ω/cm, at least 57 Ω/cm, at least 57.5 Ω/cm, at least 58 Ω/cm, at least 58.5 Ω/cm, at least 59 Ω/cm, at least 59.5 Ω/cm, at least 60 Ω/cm, at least 60.5 Ω/cm, at least 61 Ω/cm, at least 61.5 Ω/cm, at least 62 Ω/cm, at least 62.5 Ω/cm, at least 63 Ω/cm, at least 63.5 Ω/cm, at least 64 Ω/cm, at least 64.5 Ω/cm, at least 65 Ω/cm, at least 65.5 Ω/cm, at least 66 Ω/cm, at least 66.5 Ω/cm, at least 67 Ω/cm, at least 67.5 Ω/cm, at least 68 Ω/cm, at least 68.5 Ω/cm, at least 69 Ω/cm, at least 69.5 Ω/cm, at least 70 Ω/cm, at least 70.5 Ω/cm, at least 71 Ω/cm, at least 71.5 Ω/cm, at least 72 Ω/cm, at least 72.5 Ω/cm, at least 73 Ω/cm, at least 73.5 Ω/cm, at least 74 Ω/cm, at least 74.5 Ω/cm, at least 75 Ω/cm, at least 75.5 Ω/cm, at least 76 Ω/cm, at least 76.5 Ω/cm, at least 77 Ω/cm, at least 77.5 Ω/cm, at least 78 Ω/cm, at least 78.5 Ω/cm, at least 79 Ω/cm, at least 79.5 Ω/cm, at least 80 Ω/cm, at least 80.5 Ω/cm, at least 81 Ω/cm, at least 81.5 Ω/cm, at least 82 Ω/cm, at least 82.5 Ω/cm, at least 83 Ω/cm, at least 83.5 Ω/cm, at least 84 Ω/cm, at least 84.5 Ω/cm, at least 85 Ω/cm, at least 85.5 Ω/cm, at least 86 Ω/cm, at least 86.5 Ω/cm, at least 87 Ω/cm, at least 87.5 Ω/cm, at least 88 Ω/cm, at least 88.5 Ω/cm, at least 89 Ω/cm, at least 89.5 Ω/cm, at least 90 Ω/cm, at least 90.5 Ω/cm, at least 91 Ω/cm, at least 91.5 Ω/cm, at least 92 Ω/cm, at least 92.5 Ω/cm, at least 93 Ω/cm, at least 93.5 Ω/cm, at least 94 Ω/cm, at least 94.5 Ω/cm, at least 95 Ω/cm, at least 95.5 Ω/cm, at least 96 Ω/cm, at least 96.5 Ω/cm, at least 97 Ω/cm, at least 97.5 Ω/cm, at least 98 Ω/cm, at least 98.5 Ω/cm, at least 99 Ω/cm, at least 99.5 Ω/cm, or at least 100 Ω/cm.

In some embodiments, the resistance threshold is at most 0.1 Ω/cm, at most 0.4 Ω/cm, at most 0.8 Ω/cm, at most 1 Ω/cm, at most 1.5 Ω/cm, at most 2 Ω/cm, at most 2.5 Ω/cm, at most 3 Ω/cm, at most 3.5 Ω/cm, at most 4 Ω/cm, at most 4.5 Ω/cm, at most 5 Ω/cm, at most 5.5 Ω/cm, at most 6 Ω/cm, at most 6.5 Ω/cm, at most 7 Ω/cm, at most 7.5 Ω/cm, at most 8 Ω/cm, at most 8.5 Ω/cm, at most 9 Ω/cm, at most 9.5 Ω/cm, at most 10 Ω/cm, at most 10.5 Ω/cm, at most 11 Ω/cm, at most 11.5 Ω/cm, at most 12 Ω/cm, at most 12.5 Ω/cm, at most 13 Ω/cm, at most 13.5 Ω/cm, at most 14 Ω/cm, at most 14.5 Ω/cm, at most 15 Ω/cm, at most 15.5 Ω/cm, at most 16 Ω/cm, at most 16.5 Ω/cm, at most 17 Ω/cm, at most 17.5 Ω/cm, at most 18 Ω/cm, at most 18.5 Ω/cm, at most 19 Ω/cm, at most 19.5 Ω/cm, at most 20 Ω/cm, at most 20.5 Ω/cm, at most 21 Ω/cm, at most 21.5 Ω/cm, at most 22 Ω/cm, at most 22.5 Ω/cm, at most 23 Ω/cm, at most 23.5 Ω/cm, at most 24 Ω/cm, at most 24.5 Ω/cm, at most 25 Ω/cm, at most 25.5 Ω/cm, at most 26 Ω/cm, at most 26.5 Ω/cm, at most 27 Ω/cm, at most 27.5 Ω/cm, at most 28 Ω/cm, at most 28.5 Ω/cm, at most 29 Ω/cm, at most 29.5 Ω/cm, at most 30 Ω/cm, at most 30.5 Ω/cm, at most 31 Ω/cm, at most 31.5 Ω/cm, at most 32 Ω/cm, at most 32.5 Ω/cm, at most 33 Ω/cm, at most 33.5 Ω/cm, at most 34 Ω/cm, at most 34.5 Ω/cm, at most 35 Ω/cm, at most 35.5 Ω/cm, at most 36 Ω/cm, at most 36.5 Ω/cm, at most 37 Ω/cm, at most 37.5 Ω/cm, at most 38 Ω/cm, at most 38.5 Ω/cm, at most 39 Ω/cm, at most 39.5 Ω/cm, at most 40 Ω/cm, at most 40.5 Ω/cm, at most 41 Ω/cm, at most 41.5 Ω/cm, at most 42 Ω/cm, at most 42.5 Ω/cm, at most 43 Ω/cm, at most 43.5 Ω/cm, at most 44 Ω/cm, at most 44.5 Ω/cm, at most 45 Ω/cm, at most 45.5 Ω/cm, at most 46 Ω/cm, at most 46.5 Ω/cm, at most 47 Ω/cm, at most 47.5 Ω/cm, at most 48 Ω/cm, at most 48.5 Ω/cm, at most 49 Ω/cm, at most 49.5 Ω/cm, at most 50 Ω/cm, at most 50.5 Ω/cm, at most 51 Ω/cm, at most 51.5 Ω/cm, at most 52 Ω/cm, at most 52.5 Ω/cm, at most 53 Ω/cm, at most 53.5 Ω/cm, at most 54 Ω/cm, at most 54.5 Ω/cm, at most 55 Ω/cm, at most 55.5 Ω/cm, at most 56 Ω/cm, at most 56.5 Ω/cm, at most 57 Ω/cm, at most 57.5 Ω/cm, at most 58 Ω/cm, at most 58.5 Ω/cm, at most 59 Ω/cm, at most 59.5 Ω/cm, at most 60 Ω/cm, at most 60.5 Ω/cm, at most 61 Ω/cm, at most 61.5 Ω/cm, at most 62 Ω/cm, at most 62.5 Ω/cm, at most 63 Ω/cm, at most 63.5 Ω/cm, at most 64 Ω/cm, at most 64.5 Ω/cm, at most 65 Ω/cm, at most 65.5 Ω/cm, at most 66 Ω/cm, at most 66.5 Ω/cm, at most 67 Ω/cm, at most 67.5 Ω/cm, at most 68 Ω/cm, at most 68.5 Ω/cm, at most 69 Ω/cm, at most 69.5 Ω/cm, at most 70 Ω/cm, at most 70.5 Ω/cm, at most 71 Ω/cm, at most 71.5 Ω/cm, at most 72 Ω/cm, at most 72.5 Ω/cm, at most 73 Ω/cm, at most 73.5 Ω/cm, at most 74 Ω/cm, at most 74.5 Ω/cm, at most 75 Ω/cm, at most 75.5 Ω/cm, at most 76 Ω/cm, at most 76.5 Ω/cm, at most 77 Ω/cm, at most 77.5 Ω/cm, at most 78 Ω/cm, at most 78.5 Ω/cm, at most 79 Ω/cm, at most 79.5 Ω/cm, at most 80 Ω/cm, at most 80.5 Ω/cm, at most 81 Ω/cm, at most 81.5 Ω/cm, at most 82 Ω/cm, at most 82.5 Ω/cm, at most 83 Ω/cm, at most 83.5 Ω/cm, at most 84 Ω/cm, at most 84.5 Ω/cm, at most 85 Ω/cm, at most 85.5 Ω/cm, at most 86 Ω/cm, at most 86.5 Ω/cm, at most 87 Ω/cm, at most 87.5 Ω/cm, at most 88 Ω/cm, at most 88.5 Ω/cm, at most 89 Ω/cm, at most 89.5 Ω/cm, at most 90 Ω/cm, at most 90.5 Ω/cm, at most 91 Ω/cm, at most 91.5 Ω/cm, at most 92 Ω/cm, at most 92.5 Ω/cm, at most 93 Ω/cm, at most 93.5 Ω/cm, at most 94 Ω/cm, at most 94.5 Ω/cm, at most 95 Ω/cm, at most 95.5 Ω/cm, at most 96 Ω/cm, at most 96.5 Ω/cm, at most 97 Ω/cm, at most 97.5 Ω/cm, at most 98 Ω/cm, at most 98.5 Ω/cm, at most 99 Ω/cm, at most 99.5 Ω/cm, or at most 100 Ω/cm.

In some embodiments, the first circuit component 921 is a pad, an electrode, a line, or a via. Similarly, in some embodiments, the second circuit component is a pad, an electrode, a line, or a via.

In some embodiments, the first circuit includes at least 3 circuit components, at least 5 circuit components, at least 10 circuit components, at least 50 circuit components, at least 100 circuit components, at least 500 circuit components, at least 1,000 circuit components, at least 5,000 circuit components, at least 10,000 circuit components, at least 25,000 circuit components, at least 40,000 circuit components, at least 100,000 circuit components, at least 250,000 circuit components, at least 500,000 circuit components, at least 1 million circuit components, at least 5 million circuit components, or at least 10 million circuit components.

In some embodiments, the plurality of circuit components of the first circuit includes capacitors, inductors, resistors, metal pads, diodes, transistors, amplifiers, or any combination thereof. In some embodiments, the electronic device includes one, two, three, four, five, or more than five additional circuits. For instance, the electronic device includes an antenna circuit configured to receive or transmit wireless signals in communications with an external device and the first circuit is in communication with the antenna circuit. In some embodiments, the first circuit includes an antenna circuit configured to receive or transmit wireless signals in communications with an external device. In some embodiments, the electronic device includes one, two, three, four, five, or more than five semiconductor chips, and the one, two, three, four, five, or more than five semiconductor chips in combination with the first circuit can perform some specific functions. For instance, in an embodiment, the electronic device includes one or more semiconductor chips, and the one or more semiconductor chips in combination with the first circuit are able to wirelessly communicate with an external device based on near field communication (NFC), Wi-Fi, Bluetooth, RFID wireless communication standard, or the like.

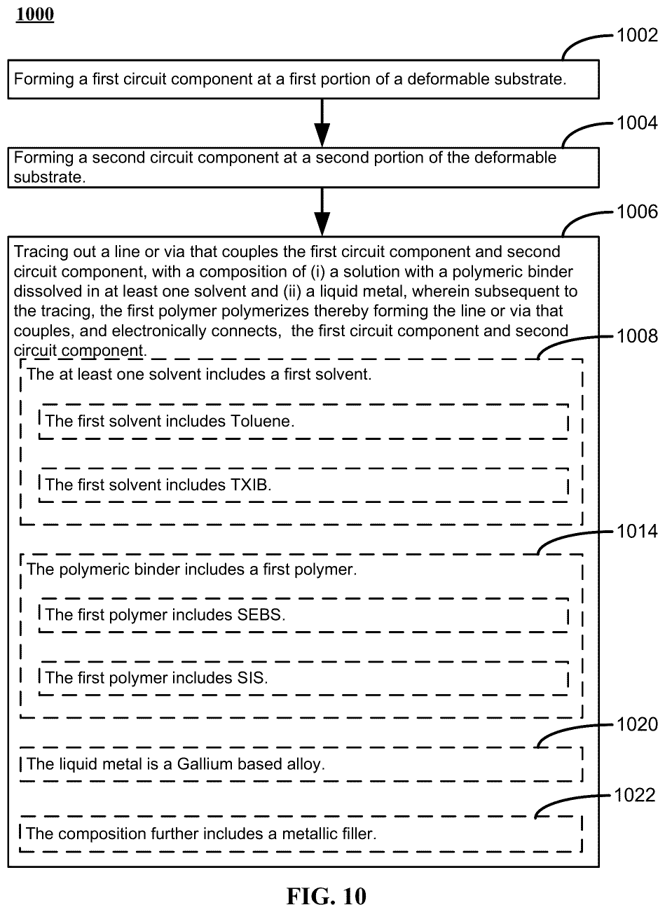

FIG. 10 is a flow chart illustrating an exemplary method 100 for manufacturing an electronic device such as the electronic device 900. The method includes forming a first circuit component at a first portion of a deformable substrate (block 1002), and forming a second circuit component at a second portion of the deformable substrate (block 1004). The method also includes tracing out a line or via that couples the first circuit component and second circuit component, with a composition of (i) a solution with a polymeric binder dissolved in at least one solvent and (ii) a liquid metal (block 1006).

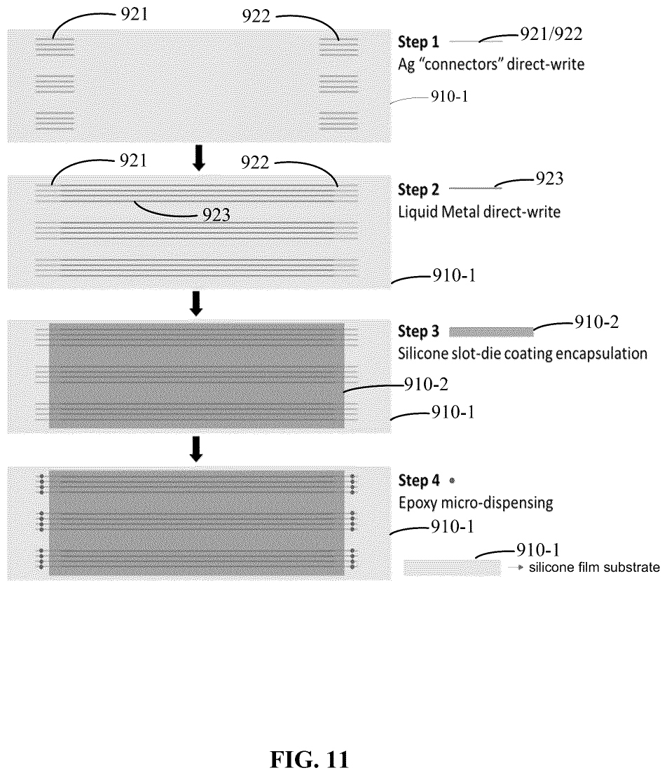

For instance, to trace out a line that couples the first circuit component and second circuit component, in some embodiments, the method forms the first and second circuit components on a common layer of the substrate. As a non-limiting example, FIG. 11 illustrates that the method forms a first set of first circuit components 921 and a second set of second circuit components 922 on a common layer, e.g., a first layer 910-1, of the deformable substrate 910. In particular, the first set of first circuit components 921 is formed on a first portion of the common layer of the deformable substrate 910, and the second set of second circuit components 922 is formed on a second portion of the common layer of the deformable substrate 910. In some embodiments, each of the first and second circuit components is made of a material including Cu, Au, Ag, or a combination thereof. The method then forms a third set of third circuit components 923, each being a line, to couple the first set of first circuit components and a second set of second circuit components. In some embodiments, a second layer 910-2 is applied to encapsulate at least a portion of the first layer 910-1, for instance, using a slot-die coating technique. In some embodiments, the second layer 910-2 is made of a material including Si.

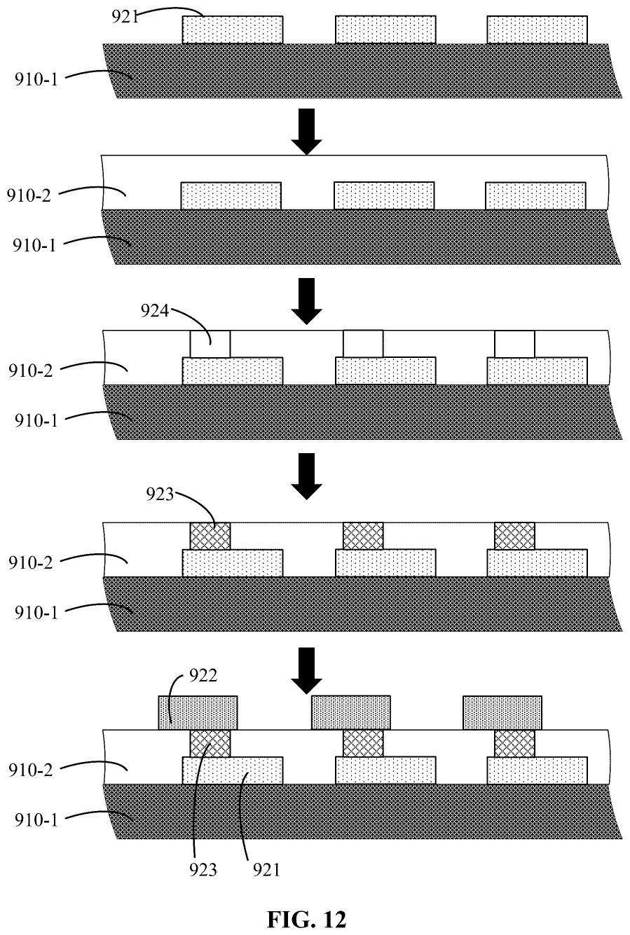

To form a via that couples the first circuit component and second circuit component, in some embodiments, the method forms the first and second circuit components on two different layers (one layer being a first portion and the other being a second portion) of the deformable substrate 910. As a non-limiting example, FIG. 12 illustrates that the method forms a first set of first circuit components 921 on a first layer 910-1 of the deformable substrate 910, and then overlays a second layer 910-2 on the first layer 910-1, for instance, using a slot-die coating technique. The second layer 910-2 encapsulates at least a portion of the first set of first circuit components 921. The method then creates a set of channels 924, for instance, using a laser or the like, through the second layer 910-2. In some embodiments, each channel is extended to a first circuit component in the first set of the first circuit components. The set of channels is filled, for instance, using extrusion-based additive manufacturing method such as direct printing techniques, with a composition of the present disclosure to form a third set of third circuit components 923. In some embodiments, each third circuit component is a via. After that, the method forms a second set of second circuit components 922 on the second layer 910-2. In some embodiments, each second circuit in the second set of second circuit components 922 contacts a third circuit component in the third set of third circuit components 923.

In some embodiments, the first set of first circuit components 921 consists of a single first circuit component. Alternatively, in some embodiments, the first set of first circuit components 921 includes at least 2, at least 3, at least 4, at least 5, at least 10, at least 20, at least 30, at least 40, or at least 50 first circuit components. Similarly, in some embodiments, the second set of second circuit components 922 consists of a single second circuit component. Alternatively, in some embodiments, the second set of second circuit components 922 includes at least 2, at least 3, at least 4, at least 5, at least 10, at least 20, at least 30, at least 40, or at least 50 second circuit components. In some embodiments, the third set of third circuit components 922 consists of a single third circuit component. Alternatively, in some embodiments, the third set of third circuit components 922 includes at least 2, at least 3, at least 4, at least 5, at least 10, at least 20, at least 30, at least 40, or at least 50 third circuit components.

The line or via can be traced using, for instance, an extrusion-based additive manufacturing method such as direct printing techniques. Subsequent to the tracing, the polymeric binder or at least a portion of it polymerizes thereby forming the line or via that couples, and electrically connects, the first circuit component and second circuit component. For instance, in some embodiments, to obtain higher conductivity, after the tracing, the circuit is allowed to cure. In an embodiment, the circuit is allowed to cure at room temperature for at least 4 hours, at least 6 hours, at least 8 hours, at least 10 hours, at least 12 hours, at least 14 hours, at least 16 hours, at least 18 hours, at least 20 hours, at least 22 hours, or at least 24 hours. In another embodiment, the circuit is allowed to cure at an elevated temperature, for instance, between 40° C. to 80° C., for less than 10 hours, less than 8 hours, less than 6 hours, less than 4 hours, less than 2 hours, or less than 1 hour.

The at least one solvent can include any solvent or solvent mixture disclosed herein. For instance, in some embodiments, the at least one solvent includes a first solvent (block 1008). In an embodiment, the first solvent includes toluene. In another embodiment, the first solvent includes TXIB.

The polymeric binder can include any one or more polymers disclosed herein. For instance, in some embodiments, the polymeric binder includes a first polymer (block 1014). In an embodiment, the first polymer includes SEBS. In another embodiment, the first polymer includes SIS.

In some embodiments, the solution is composed of any one or more polymers (e.g., SIS, SEBS, silicone, or the like) dissolved in TXIB, or in a solvent mixture including TXIB. In some embodiments, the solution is composed of SEBS or a polymer mixture including SEBS dissolved in any solvent or solvent mixture. For instance, in some embodiments, the solution is a solution of SIS dissolved in TXIB, a solution of SIS dissolved in a mixture of TXIB and toluene, a solution of a polymer mixture including SIS dissolved in TXIB, a solution of SEBS dissolved in toluene, a solution of a polymer mixture including SEBS dissolved in toluene, or a solution of SEBS dissolved in a mixture of TXIB and toluene.

The liquid metal can be any liquid metal or liquid metal alloy disclosed herein. In some exemplary embodiments, the liquid metal is a Ga-based alloy (block 1020).

In some embodiments, additionally or optionally, the composition further includes a metallic filler (block 1022). Non-limiting examples of a metallic filler include, but not limited to, including but not limited to aluminum, titanium, cobalt, nickel, copper, zinc, silver, gold, titanium, nitinol, or indium. In some embodiments, the metallic filler is in a form of microflakes, nanoflakes, microparticles, nanoparticles, nanowires, nanotubes, or a combination thereof.

In some embodiments, at least one of the first and second circuit components is made of a material different than the composition. For instance, in an embodiment, the first or second circuit component is a metal pad. In some embodiments, at least one of the first and second circuit components is made of a material substantially the same as the composition. For instance, in an embodiment, the first or second circuit component is a line or via made of the same composition.

In some embodiments, the first circuit component and the second circuit component form part of an active-matrix array. For instance, in some embodiments, the first circuit component or the second circuit component is a transistor, an electrode, or a capacitor disposed on the deformable substrate 910, and the other of the first circuit component or the second circuit component is different than the transistor, the electrode, or the capacitor of the first circuit component or the second circuit component.

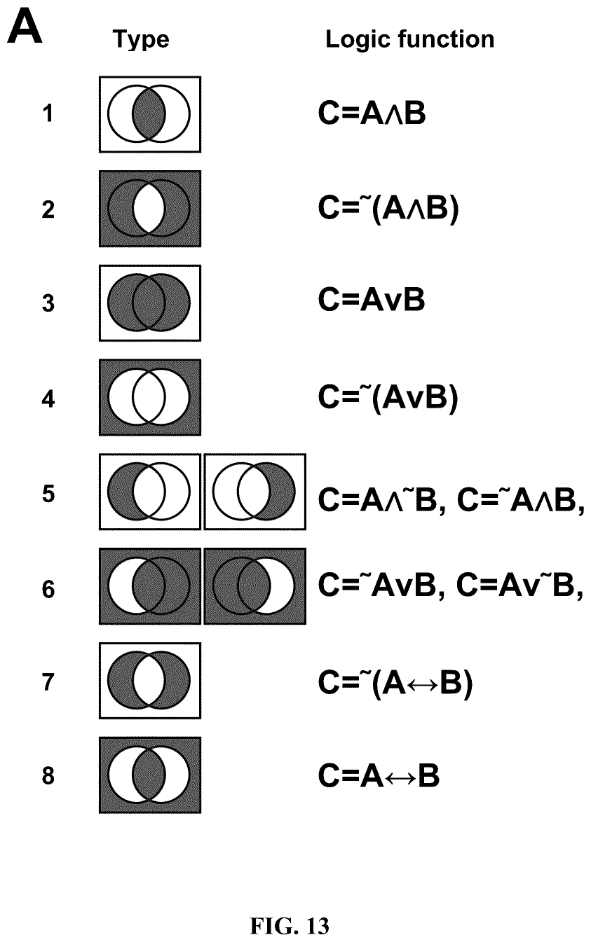

In some embodiments, the first circuit component and the second circuit component are part of a transistor switch. For instance, in some embodiments, the transistor switch is configured to control an electronical communication through the circuit 920 using a logic function, such as an OR logic function based on either a cutoff or saturation of the electronical communication. In some embodiments, two or more transistor switches are arranged (e.g., in series and/or parallel) in order to implement a logic function, such as one or more logic functions of FIG. 13.

In some embodiments, the tracing 1006 of the method 1000 includes tracing out one or more lines, one or more vias, or any combination of one or more lines and one or more vias to form the interconnect between the first circuit component and the second circuit component using the composition.

In some embodiments, the electronic device is a display.

In some embodiments, the first circuit component and the second circuit component form part of an active-matrix array.

In some embodiments, the interconnect is free of degradation in conductivity when the deformable substrate is bent around a cylinder that has a radius of between 2 centimeters (cm) and 10 cm for a period of time and then released.

In some embodiments, the period of time is between 10 seconds and five minutes.

In some embodiments, the first circuit component and the second circuit component are part of a transistor switch.

In some embodiments, the interconnect is free of degradation in conductivity when the deformable substrate 302 is bent, such as bent around a cylinder. In some embodiments, the interconnect is free of degradation in conductivity when the deformable substrate 302 is that has a radius of between 2 centimeters (cm) and 10 cm, between 2 cm and 8 cm, between 2 cm and 6 cm, between 2 cm and 4 cm, 4 cm and 10 cm, between 4 cm and 8 cm, between 4 cm and 6 cm, between 6 cm and 10 cm, between 6 cm and 8 cm, or between 8 cm and 10 cm for a period of time and then released. In some embodiments, the radius of the cylinder is at least 2 cm, at least 3 cm, at least 4 cm, at least 5 cm, at least 6 cm, at least 7 cm, at least 8 cm, at least 9 cm, or at least 10 cm. In some embodiments, the radius of the cylinder is at most 2 cm, at most 3 cm, at most 4 cm, at most 5 cm, at most 6 cm, at most 7 cm, at most 8 cm, at most 9 cm, or at most 10 cm.

In some embodiments, the period of time is between 10 seconds and 5 minutes, between 10 seconds and 4 minutes, between 10 seconds and 3 minutes, between 10 seconds and 2 minutes, between 10 seconds and 1 minute, between 10 seconds and 30 seconds, between 30 seconds and 5 minutes, between 10 seconds and 4 minutes, between 10 seconds and 3 minutes, between 10 seconds and 2 minutes, between 10 seconds and 1 minute, between 1 minute and 5 minutes, between 1 minute and 4 minutes, between 1 minute and 3 minutes, between 1 minute and 2 minutes, or between 3 minutes and 5 minutes. In some embodiments, the period of time is at least 10 seconds, at least 20 seconds, at least 30 seconds, at least 60 seconds, at least 1.5 minutes, at least 2 minutes, at least 2.5 minutes, at least 3 minutes, at least 3.5 minutes, at least 4 minutes, at least 4.5 minutes, or at least 5 minutes. In some embodiments, the period of time is at most 10 seconds, at most 20 seconds, at most 30 seconds, at most 60 seconds, at most 1.5 minutes, at most 2 minutes, at most 2.5 minutes, at most 3 minutes, at most 3.5 minutes, at most 4 minutes, at most 4.5 minutes, or at most 5 minutes.

For instance, in some embodiments, the interconnect is free of degradation when the second conductivity satisfies a threshold ratio in comparison against the first conductivity of the interconnect. In some embodiments, the threshold ratio is between 0.99 and 1.01, between 0.995 and 1.005, or between 0.999 and 1.001. In some embodiments, the threshold ratio is at least 0.9, at least 0.95, at least 1, at least 1.05, or at least 1.1. In some embodiments, the threshold ratio is at most 0.95, at most 0.96, at most 0.97, at most 0.98, at most 0.99, at most 0.999, at most 0.9999, at most 1, at most 1.0001, at most 1.001, at most 1.01, at most 1.02, at most 1.03, at most 1.04, at most 1.05, or at most 1.1.

In some embodiments, the thickness of the interconnect is between 1 μm and 500 μm, between 1 μm and 450 μm, between 1 μm and 400 μm, between 1 μm and 350 μm, between 1 μm and 300 μm, between 1 μm and 250 μm, between 1 μm and 200 μm, between 1 μm and 150 μm, between 1 μm and 100 μm, between 1 μm and 50 μm, between 1 μm and 10 μm, between 2 μm and 500 μm, between 2 μm and 450 μm, between 2 μm and 400 μm, between 2 μm and 350 μm, between 2 μm and 300 μm, between 2 μm and 250 μm, between 2 μm and 200 μm, between 2 μm and 150 μm, between 2 μm and 100 μm, between 2 μm and 50 μm, between 2 μm and 10 μm, between 3 μm and 500 μm, between 3 μm and 450 μm, between 3 μm and 400 μm, between 3 μm and 350 μm, between 3 μm and 300 μm, between 3 μm and 250 μm, between 3 μm and 200 μm, between 3 μm and 150 μm, between 3 μm and 100 μm, between 3 μm and 50 μm, between 3 μm and 10 μm, between 4 μm and 500 μm, between 4 μm and 450 μm, between 4 μm and 400 μm, between 4 μm and 350 μm, between 4 μm and 300 μm, between 4 μm and 250 μm, between 4 μm and 200 μm, between 4 μm and 150 μm, between 4 μm and 100 μm, between 4 μm and 50 μm, between 4 μm and 10 μm, between 5 μm and 500 μm, between 5 μm and 450 μm, between 5 μm and 400 μm, between 5 μm and 350 μm, between 5 μm and 300 μm, between 5 μm and 250 μm, between 5 μm and 200 μm, between 5 μm and 150 μm, between 5 μm and 100 μm, between 5 μm and 50 μm, between 5 μm and 10 μm, between 6 μm and 500 μm, between 6 μm and 450 μm, between 6 μm and 400 μm, between 6 μm and 350 μm, between 6 μm and 300 μm, between 6 μm and 250 μm, between 6 μm and 200 μm, between 6 μm and 150 μm, between 6 μm and 100 μm, between 6 μm and 50 μm, between 6 μm and 10 μm, between 10 μm and 500 μm, between 10 μm and 450 μm, between 10 μm and 400 μm, between 10 μm and 350 μm, between 10 μm and 300 μm, between 10 μm and 250 μm, between 10 μm and 200 μm, between 10 μm and 150 μm, between 10 μm and 100 μm, between 10 μm and 90 μm, between 10 μm and 50 μm, between 75 μm and 500 μm, between 75 μm and 450 μm, between 75 μm and 400 μm, between 75 μm and 350 μm, between 75 μm and 300 μm, between 75 μm and 250 μm, between 75 μm and 200 μm, between 75 μm and 150 μm, between 75 μm and 100 μm, between 150 μm and 500 μm, between 150 μm and 450 μm, between 150 μm and 400 μm, between 150 μm and 350 μm, between 150 μm and 300 μm, between 150 μm and 250 μm, between 150 μm and 200 μm, between 225 μm and 500 μm, between 225 μm and 450 μm, between 225 μm and 400 μm, between 225 μm and 350 μm, between 225 μm and 300 μm, between 225 μm and 250 μm, between 300 μm and 550 μm, between 300 μm and 500 μm, between 300 μm and 450 μm, between 300 μm and 400 μm, between 300 μm and 350 μm between 375 μm and 500 μm, between 375 μm and 450 μm, between 375 μm and 400 μm, or between 450 μm and 500 μm.

In some embodiments, the thickness of the interconnect changes as a function of length and/or depth of the interconnect. For instance, in some embodiments, the width of the interconnect is at least 1, 2, 3, 5, 10, 15, 20, or 25 percent larger at one point in the length of the interconnect as it is at a second point in the length of the interconnect. In some embodiments, the first point in the length of the interconnect is the first point at which the interconnect has the largest cross-section and the second point is the point at which the interconnect has the smallest cross-section. In some embodiments, the in thickness of the interconnect does not appreciably or measurably change as a function of length and/or depth of the interconnect.

In some embodiments, the thickness of the interconnect is at least 1 μm, at least 2 μm, at least 3 μm, at least 4 μm, at least 5 μm, at least 6 μm, at least 10 μm, at least 15 μm, at least 20 μm, at least 25 μm, at least 30 μm, at least 35 μm, at least 40 μm, at least 45 μm, at least 50 μm, at least 55 μm, at least 60 μm, at least 65 μm, at least 70 μm, at least 75 μm, at least 80 μm, at least 85 μm, at least 90 μm, at least 95 μm, at least 100 μm, at least 105 μm, at least 110 μm, at least 115 μm, at least 120 μm, at least 125 μm, at least 130 μm, at least 135 μm, at least 140 μm, at least 145 μm, at least 150 μm, at least 155 μm, at least 160 μm, at least 165 μm, at least 170 μm, at least 175 μm, at least 180 μm, at least 185 μm, at least 190 μm, at least 195 μm, at least 200 μm, at least 205 μm, at least 210 μm, at least 215 μm, at least 220 μm, at least 225 μm, at least 230 μm, at least 235 μm, at least 240 μm, at least 245 μm, at least 250 μm, at least 255 μm, at least 260 μm, at least 265 μm, at least 270 μm, at least 275 μm, at least 280 μm, at least 285 μm, at least 290 μm, at least 295 μm, at least 300 μm, at least 305 μm, at least 310 μm, at least 315 μm, at least 320 μm, at least 325 μm, at least 330 μm, at least 335 μm, at least 340 μm, at least 345 μm, at least 350 μm, at least 355 μm, at least 360 μm, at least 365 μm, at least 370 μm, at least 375 μm, at least 380 μm, at least 385 μm, at least 390 μm, at least 395 μm, at least 400 μm, at least 405 μm, at least 410 μm, at least 415 μm, at least 420 μm, at least 425 μm, at least 430 μm, at least 435 μm, at least 440 μm, at least 445 μm, at least 450 μm, at least 455 μm, at least 460 μm, at least 465 μm, at least 470 μm, at least 475 μm, at least 480 μm, at least 485 μm, at least 490 μm, at least 495 μm, or at least 500 μm.

In some embodiments, the thickness of the interconnect is at most 1 μm, at most 2 μm, at most 3 μm, at most 4 μm, at most 5 μm, at most 6 μm, at most 10 μm, at most 15 μm, at most 20 μm, at most 25 μm, at most 30 μm, at most 35 μm, at most 40 μm, at most 45 μm, at most 50 μm, at most 55 μm, at most 60 μm, at most 65 μm, at most 70 μm, at most 75 μm, at most 80 μm, at most 85 μm, at most 90 μm, at most 95 μm, at most 100 μm, at most 105 μm, at most 110 μm, at most 115 μm, at most 120 μm, at most 125 μm, at most 130 μm, at most 135 μm, at most 140 μm, at most 145 μm, at most 150 μm, at most 155 μm, at most 160 μm, at most 165 μm, at most 170 μm, at most 175 μm, at most 180 μm, at most 185 μm, at most 190 μm, at most 195 μm, at most 200 μm, at most 205 μm, at most 210 μm, at most 215 μm, at most 220 μm, at most 225 μm, at most 230 μm, at most 235 μm, at most 240 μm, at most 245 μm, at most 250 μm, at most 255 μm, at most 260 μm, at most 265 μm, at most 270 μm, at most 275 μm, at most 280 μm, at most 285 μm, at most 290 μm, at most 295 μm, at most 300 μm, at most 305 μm, at most 310 μm, at most 315 μm, at most 320 μm, at most 325 μm, at most 330 μm, at most 335 μm, at most 340 μm, at most 345 μm, at most 350 μm, at most 355 μm, at most 360 μm, at most 365 μm, at most 370 μm, at most 375 μm, at most 380 μm, at most 385 μm, at most 390 μm, at most 395 μm, at most 400 μm, at most 405 μm, at most 410 μm, at most 415 μm, at most 420 μm, at most 425 μm, at most 430 μm, at most 435 μm, at most 440 μm, at most 445 μm, at most 450 μm, at most 455 μm, at most 460 μm, at most 465 μm, at most 470 μm, at most 475 μm, at most 480 μm, at most 485 μm, at most 490 μm, at most 495 μm, or at most 500 μm.

In some embodiments, the width of the interconnect is between 1 μm and 500 μm, between 1 μm and 450 μm, between 1 μm and 400 μm, between 1 μm and 350 μm, between 1 μm and 300 μm, between 1 μm and 250 μm, between 1 μm and 200 μm, between 1 μm and 150 μm, between 1 μm and 100 μm, between 1 μm and 50 μm, between 1 μm and 10 μm, between 2 μm and 500 μm, between 2 μm and 450 μm, between 2 μm and 400 μm, between 2 μm and 350 μm, between 2 μm and 300 μm, between 2 μm and 250 μm, between 2 μm and 200 μm, between 2 μm and 150 μm, between 2 μm and 100 μm, between 2 μm and 50 μm, between 2 μm and 10 μm, between 3 μm and 500 μm, between 3 μm and 450 μm, between 3 μm and 400 μm, between 3 μm and 350 μm, between 3 μm and 300 μm, between 3 μm and 250 μm, between 3 μm and 200 μm, between 3 μm and 150 μm, between 3 μm and 100 μm, between 3 μm and 50 μm, between 3 μm and 10 μm, between 4 μm and 500 μm, between 4 μm and 450 μm, between 4 μm and 400 μm, between 4 μm and 350 μm, between 4 μm and 300 μm, between 4 μm and 250 μm, between 4 μm and 200 μm, between 4 μm and 150 μm, between 4 μm and 100 μm, between 4 μm and 50 μm, between 4 μm and 10 μm, between 5 μm and 500 μm, between 5 μm and 450 μm, between 5 μm and 400 μm, between 5 μm and 350 μm, between 5 μm and 300 μm, between 5 μm and 250 μm, between 5 μm and 200 μm, between 5 μm and 150 μm, between 5 μm and 100 μm, between 5 μm and 50 μm, between 5 μm and 10 μm, between 6 μm and 500 μm, between 6 μm and 450 μm, between 6 μm and 400 μm, between 6 μm and 350 μm, between 6 μm and 300 μm, between 6 μm and 250 μm, between 6 μm and 200 μm, between 6 μm and 150 μm, between 6 μm and 100 μm, between 6 μm and 50 μm, between 6 μm and 10 μm, between 10 μm and 500 μm, between 10 μm and 450 μm, between 10 μm and 400 μm, between 10 μm and 350 μm, between 10 μm and 300 μm, between 10 μm and 250 μm, between 10 μm and 200 μm, between 10 μm and 150 μm, between 10 μm and 100 μm, between 10 μm and 90 μm, between 10 μm and 50 μm, between 75 μm and 500 μm, between 75 μm and 450 μm, between 75 μm and 400 μm, between 75 μm and 350 μm, between 75 μm and 300 μm, between 75 μm and 250 μm, between 75 μm and 200 μm, between 75 μm and 150 μm, between 75 μm and 100 μm, between 150 μm and 500 μm, between 150 μm and 450 μm, between 150 μm and 400 μm, between 150 μm and 350 μm, between 150 μm and 300 μm, between 150 μm and 250 μm, between 150 μm and 200 μm, between 225 μm and 500 μm, between 225 μm and 450 μm, between 225 μm and 400 μm, between 225 μm and 350 μm, between 225 μm and 300 μm, between 225 μm and 250 μm, between 300 μm and 550 μm, between 300 μm and 500 μm, between 300 μm and 450 μm, between 300 μm and 400 μm, between 300 μm and 350 μm between 375 μm and 500 μm, between 375 μm and 450 μm, between 375 μm and 400 μm, or between 450 μm and 500 μm.

In some embodiments, the width of the interconnect changes as a function of length and/or depth of the interconnect. For instance, in some embodiments, the width of the interconnect is at least 1, 2, 3, 5, 10, 15, 20, or 25 percent larger at one point in the length of the interconnect as it is at a second point in the length of the interconnect. In some embodiments, the first point in the length of the interconnect is the first point at which the interconnect has the largest cross-section and the second point is the point at which the interconnect has the smallest cross-section. In some embodiments, the in width of the interconnect does not appreciably or measurably change as a function of length and/or depth of the interconnect.

In some embodiments, the width of the interconnect is at least 1 μm, at least 2 μm, at least 3 μm, at least 4 μm, at least 5 μm, at least 6 μm, at least 10 μm, at least 15 μm, at least 20 μm, at least 25 μm, at least 30 μm, at least 35 μm, at least 40 μm, at least 45 μm, at least 50 μm, at least 55 μm, at least 60 μm, at least 65 μm, at least 70 μm, at least 75 μm, at least 80 μm, at least 85 μm, at least 90 μm, at least 95 μm, at least 100 μm, at least 105 μm, at least 110 μm, at least 115 μm, at least 120 μm, at least 125 μm, at least 130 μm, at least 135 μm, at least 140 μm, at least 145 μm, at least 150 μm, at least 155 μm, at least 160 μm, at least 165 μm, at least 170 μm, at least 175 μm, at least 180 μm, at least 185 μm, at least 190 μm, at least 195 μm, at least 200 μm, at least 205 μm, at least 210 μm, at least 215 μm, at least 220 μm, at least 225 μm, at least 230 μm, at least 235 μm, at least 240 μm, at least 245 μm, at least 250 μm, at least 255 μm, at least 260 μm, at least 265 μm, at least 270 μm, at least 275 μm, at least 280 μm, at least 285 μm, at least 290 μm, at least 295 μm, at least 300 μm, at least 305 μm, at least 310 μm, at least 315 μm, at least 320 μm, at least 325 μm, at least 330 μm, at least 335 μm, at least 340 μm, at least 345 μm, at least 350 μm, at least 355 μm, at least 360 μm, at least 365 μm, at least 370 μm, at least 375 μm, at least 380 μm, at least 385 μm, at least 390 μm, at least 395 μm, at least 400 μm, at least 405 μm, at least 410 μm, at least 415 μm, at least 420 μm, at least 425 μm, at least 430 μm, at least 435 μm, at least 440 μm, at least 445 μm, at least 450 μm, at least 455 μm, at least 460 μm, at least 465 μm, at least 470 μm, at least 475 μm, at least 480 μm, at least 485 μm, at least 490 μm, at least 495 μm, or at least 500 μm.

In some embodiments, the width of the interconnect is at most 1 μm, at most 2 μm, at most 3 μm, at most 4 μm, at most 5 μm, at most 6 μm, at most 10 μm, at most 15 μm, at most 20 μm, at most 25 μm, at most 30 μm, at most 35 μm, at most 40 μm, at most 45 μm, at most 50 μm, at most 55 μm, at most 60 μm, at most 65 μm, at most 70 μm, at most 75 μm, at most 80 μm, at most 85 μm, at most 90 μm, at most 95 μm, at most 100 μm, at most 105 μm, at most 110 μm, at most 115 μm, at most 120 μm, at most 125 μm, at most 130 μm, at most 135 μm, at most 140 μm, at most 145 μm, at most 150 μm, at most 155 μm, at most 160 μm, at most 165 μm, at most 170 μm, at most 175 μm, at most 180 μm, at most 185 μm, at most 190 μm, at most 195 μm, at most 200 μm, at most 205 μm, at most 210 μm, at most 215 μm, at most 220 μm, at most 225 μm, at most 230 μm, at most 235 μm, at most 240 μm, at most 245 μm, at most 250 μm, at most 255 μm, at most 260 μm, at most 265 μm, at most 270 μm, at most 275 μm, at most 280 μm, at most 285 μm, at most 290 μm, at most 295 μm, at most 300 μm, at most 305 μm, at most 310 μm, at most 315 μm, at most 320 μm, at most 325 μm, at most 330 μm, at most 335 μm, at most 340 μm, at most 345 μm, at most 350 μm, at most 355 μm, at most 360 μm, at most 365 μm, at most 370 μm, at most 375 μm, at most 380 μm, at most 385 μm, at most 390 μm, at most 395 μm, at most 400 μm, at most 405 μm, at most 410 μm, at most 415 μm, at most 420 μm, at most 425 μm, at most 430 μm, at most 435 μm, at most 440 μm, at most 445 μm, at most 450 μm, at most 455 μm, at most 460 μm, at most 465 μm, at most 470 μm, at most 475 μm, at most 480 μm, at most 485 μm, at most 490 μm, at most 495 μm, or at most 500 μm.

### EXEMPLARY IMPLEMENTATIONS

Implementation 1. A composition includes: a solution including at least one solvent and a polymeric binder dissolved in the at least one solvent; and a liquid metal mixed with the solution, wherein the at least one solvent includes a first solvent, the first solvent including:

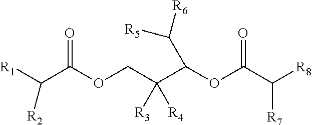

wherein R₁, R₂, R₃, R₄, R₅, R₆, R₇, and R₈ are each independently selected from substituted or unsubstituted alkyl, or substituted or unsubstituted heteroalkyl.

Implementation 2. The composition of Implementation 1, wherein the substituted or unsubstituted alkyl has between three and ten carbon atoms.

Implementation 3. The composition of Implementation 1 or Implementation 2, wherein the first solvent includes:

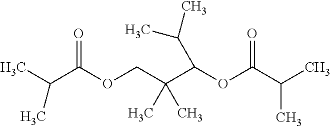 [SMILES: CC(C)C(=O)OCC(C)(C)C(OC(=O)C(C)C)C(C)C]

Implementation 4. The composition of any one of Implementations 1-3, wherein the at least one solvent consists of only the first solvent.

Implementation 5. The composition of any one of Implementations 1-3, wherein the at least one solvent is a solvent mixture including two, three, four or more than four solvents.

Implementation 6. The composition of Implementation 5, wherein the at least one solvent includes a second solvent.

Implementation 7. The composition of Implementation 6, wherein the second solvent is toluene.

Implementation 8. The composition of Implementation 6, wherein the second solvent is THF, cycolohexane, xylene, decane, or octyle acelate.

Implementation 9. The composition of Implementation 5 or Implementation 8, wherein the at least one solvent includes the first solvent at an amount from about 3% to about 5%, from about 5% to 10%, from about 10% to 20%, from about 30% to 40%, from about 40% to 50%, or more than 50% by volume.

Implementation 10. The composition of Implementation 9, wherein the first solvent is TXIB, the second solvent is toluene, and TXIB is at an amount from about 2% to about 5%, from about 5% to 10%, or from about 10% to 20% by volume of toluene.

Implementation 11. The composition of any one of Implementations 1-10, wherein the polymeric binder includes styrene isoprene styrene (SIS), styrene ethylene butylene styrene (SEBS), silicones or a combination thereof.

Implementation 12. The composition of any one of Implementations 1-11, wherein the solution includes the polymeric binder at an amount from about 10% to about 20% by weight of the solution.

Implementation 13. The composition of any one of Implementations 1-12, wherein the composition includes the liquid metal at an amount from about 50% to about 60%, from about 60% to about 70%, from about 70% to about 80%, or from about 80% to about 90% by weight of the composition.

Implementation 14. The composition of any one of Implementations 1-13, wherein the liquid metal is a Ga-based alloy.

Implementation 15. The composition of Implementation 14, wherein the Ga-based alloy includes gallium at an amount of from about 50 wt % to about 55 wt %, from about 55 wt % to about 60 wt %, from about 60 wt % to about 65 wt %, from about 65 wt % to about 70 wt %, from about 70 wt % to about 80 wt %, or from about 80 wt % to about 85 wt % with respect to the Ga-based alloy.

Implementation 16. The composition of Implementation 14, wherein the Ga-based alloy includes at least one of gallium indium alloy, gallium tin alloy, gallium indium tin alloy, or gallium indium tin zinc alloy.

Implementation 17. The composition of any one of Implementations 1-16, further including a metallic filler mixed with the solution in a form of microflakes, nanoflakes, microparticles, nanoparticles, nanowires, nanotubes, or a combination thereof.

Implementation 18. The composition of Implementation 17, wherein the metallic filler is at an amount from about 10% to about 20%, from about 20% to 30%, from about 30% to about 40%, or from about 40% to about 50% by weight of the liquid metal.

Implementation 19. The composition of Implementation 17 or Implementation 18, wherein the metallic filler includes silver, copper, gold, platinum, titanium, nitinol, or any combination thereof.

Implementation 20. The composition of any one of Implementations 1-19, wherein the composition has a decap time of at least 1 minute, at least 2 minutes, at least 5 minutes, at least 15 minutes, at least 20 minutes, or greater than 20 minutes.

Implementation 21. A method for preparing the composition of any one of Implementations 1-20.

Implementation 22. A method of preparing a composition, the method includes: producing a solution including at least one solvent and a polymeric binder dissolved in the at least one solvent; and mixing a liquid metal with the solution, wherein the at least one solvent includes a first solvent, the first solvent including:

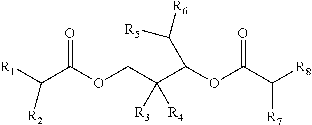

wherein R₁, R₂, R₃, R₄, R₅, R₆, R₇, and R₈ are each independently selected from substituted or unsubstituted alkyl, or substituted or unsubstituted heteroalkyl.

Implementation 23. The method of Implementation 22, wherein the substituted or unsubstituted alkyl has between three and ten carbon atoms.

Implementation 24. The method of Implementation 22 or Implementation 23, wherein the first solvent includes:

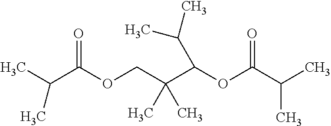 [SMILES: CC(C)C(=O)OCC(C)(C)C(OC(=O)C(C)C)C(C)C]

Implementation 25. The method of any one of Implementations 22-24, further includes: adding, prior to mixing the liquid metal with the solution, a metallic filler into the solution, wherein the metallic filler is in a form of microflakes, nanoflakes, microparticles, nanoparticles, nanowires, nanotubes, or a combination thereof.

Implementation 26. A method of manufacturing an electronic device includes: forming a first circuit component at a first portion of a deformable substrate; forming a second circuit component at a second portion of the deformable substrate; and tracing out one or more lines, one or more vias, or any combination of one or more lines and one or more vias to form an interconnect between the first circuit component and the second circuit component using any composition disclosed herein.

Implementation 27. The method of Implementation 26, wherein the electronic device is a display.

Implementation 28. The method of Implementation 26 or 27, wherein the first circuit component and the second circuit component form part of an active-matrix array.

Implementation 29. The method of any one of Implementations 26-28, wherein the interconnect is free of degradation in conductivity when the deformable substrate is bent around a cylinder that has a radius of between 2 centimeters (cm) and 10 cm for a period of time and then released.

Implementation 30. The method of Implementation 29, wherein the period of time is between 10 seconds and five minutes.

Implementation 31. The method of any one of Implementations 26-30, wherein the first circuit component and the second circuit component are part of a transistor switch.

Implementation 32. A method of manufacturing an electronic device includes: A) forming a first circuit component at a first portion of a deformable substrate; B) forming a second circuit component at a second portion of the deformable substrate; C) tracing out a line or via that couples the first circuit component and second circuit component, with a composition of (i) a solution with a polymeric binder dissolved in at least one solvent and (ii) a liquid metal, wherein the polymeric binder includes a first polymer, the first polymer including:

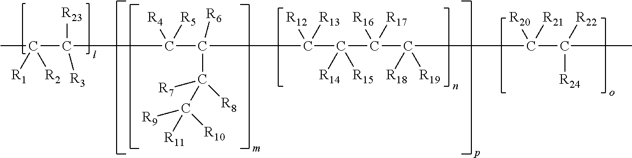

l, m, n, p, and o are the same or different and are each a positive integer;
R₁, R₂, R₃, R₄, R₅, R₆, R₇, R₈, R₉, R₁₀, R₁₁, R₁₂, R₁₃, R₁₄, R₁₅, R₁₆, R₁₇, R₁₈, R₁₉, R₂₀, R₂₁, and R₂₂ are each independently hydrogen, halogen, or hydroxyl; and
R₂₃, and R₂₄ are each independently substituted or unsubstituted aryl, or substituted or unsubstituted heteroaryl; and wherein
   subsequent to the tracing, the first polymer polymerizes thereby forming the line or via that couples, and electrically connects, the first circuit component and second circuit component.

Implementation 33. The method of Implementation 32, wherein the substituted or unsubstituted aryl or substituted or unsubstituted heteroaryl has between three and ten carbon atoms.

Implementation 34. The method of Implementation 32 or Implementation 33, wherein the first polymer includes:

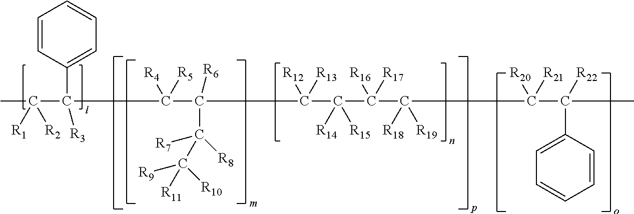

Implementation 35. The method of any one of Implementations 32-34, wherein the first polymer, at the time of tracing, has a molecular weight of greater than 50 kg/mol, greater than about 100 kg/mol, greater than about 150 kg/mol, greater than about 200 kg/mol, greater than about 250 kg/mol, greater than about 300 kg/mol, greater than about 350 kg/mol, or greater than about 400 kg/mol.

Implementation 36. The method of any one of Implementations 32-35, wherein, at a time during the tracing, a styrene content in the first polymer is from about 10 wt % to about 15 wt %, from about 15 wt % to about 20 wt %, from about 25 wt % to about 30 wt %, from about 30 wt % to about 35 wt %, from about 35 wt % to about 40 wt %, or from about 40 wt % to about 45 wt %.

Implementation 37. The method of any one of Implementations 32-36, wherein, at a time during the tracing, a styrene block in the first polymer has a molar mass of less than about 50 kg/mol, less than about 45 kg/mol, less than about 40 kg/mol, less than about 35 kg/mol, less than about 30 kg/mol, less than about 25 kg/mol, less than about 20 kg/mol, less than about 15 kg/mol, less than about 10 kg/mol, or less than about 8 kg/mol.

Implementation 38. The method of any one of Implementations 32-37, wherein, at a time during the tracing, an ethylene/butylene ratio in the first polymer is from about 2:10 to about 3:10, from about 3:10 to about 4:10, from about 4:10 to about 5:10, from about 5:10 to about 6:10, or from about 6:10 to about 7:10

Implementation 39. The method of any one of Implementations 32-38, wherein the polymeric binder consists of only the first polymer.

Implementation 40. The method of any one of Implementations 32-39, wherein the polymeric binder includes two, three, four or more than four polymers.

Implementation 41. The method of Implementation 40, wherein the polymeric binder includes a second polymer.

Implementation 42. The method of Implementation 41, wherein the second polymer is cellulose, poly(vinyl alcohol), poly(acrylic acid), polyvinylidene fluoride, polyvinyl acetate-polyvinylpyrrolidone, poly(ethylene glycol), amine, silicone, styrene isoprene styrene (SIS), styrene ethylene, or any combination thereof.

Implementation 43. The method of any one of Implementations 32-42, wherein, at a time during the tracing, the polymeric binder includes the first polymer at an amount of more than about 10 wt %, more than about 20 wt %, more than about 30 wt %, more than about 40 wt %, more than about 50 wt %, more than about 60 wt %, more than about 70 wt %, or more than about 80 wt %.

Implementation 44. The method of any one of Implementations 32-43, wherein the at least one solvent includes toluene, THF, Cycolohexane, xylene, decane, octyle acelate, TXIB, or any combination thereof.

Implementation 45. The method of any one of Implementations 32-44, wherein, at a time during the tracing, a ratio of the polymeric binder to the at least one solvent by weight is from about 5 wt % to about 10 wt %, from about 10 wt % to about 15 wt %, from about 15 wt % to about 20 wt %, from about 20 wt % to about 25 wt %, or from about 25 wt % to about 30 wt %.

Implementation 46. The method of any one of Implementations 32-45, wherein, at a time during the tracing, the composition includes the liquid metal at an amount from about 50% to about 60%, from about 60% to about 70%, from about 70% to about 80%, or from about 80% to about 90% by weight.

Implementation 47. The method of any one of Implementations 32-46, wherein the liquid metal is a Ga-based alloy.

Implementation 48. The method of Implementation 47, wherein, at a time during the tracing, the Ga-based alloy includes gallium at an amount of from about 50 wt % to about 55 wt %, from about 55 wt % to about 60 wt %, from about 60 wt % to about 65 wt %, from about 65 wt % to about 70 wt %, from about 70 wt % to about 80 wt %, or from about 80 wt % to about 85 wt %.

Implementation 49. The method of Implementation 47, wherein the Ga-based alloy includes at least one of gallium indium alloy, gallium tin alloy, gallium indium tin alloy, or gallium indium tin zinc alloy.

Implementation 50. The method of any one of Implementations 32-49, wherein the composition further includes a metallic filler in a form of microflakes, nanoflakes, microparticles, nanoparticles, nanowires, nanotubes, or a combination thereof.

Implementation 51. The method of Implementation 50, wherein, at a time during the tracing, the metallic filler is at an amount from about 10% to about 20%, from about 20% to 30%, from about 30% to about 40%, or from about 40% to about 50% by weight of the liquid metal.

Implementation 52. The method of Implementation 50 or Implementation 51, wherein the metallic filler includes silver, copper, gold, titanium, nitinol, or any combination thereof.

Implementation 53. The method of any one of Implementations 32-52, wherein the composition has a decap time of at least 1 minute, at least 2 minutes, at least 5 minutes, at least 15 minutes, at least 20 minutes, or greater than 20 minutes.

Implementation 54. The method of any one of Implementations 32-53, wherein at least one of the first and second circuit components is made of a material different than the composition.

Implementation 55. The method of any one of Implementations 32-53, wherein at least one of the first and second circuit components is made of a material substantially the same as the composition.

Implementation 56. A method of manufacturing an electronic device includes: A) forming a first circuit component at a first portion of a deformable substrate; B) forming a second circuit component at a second portion of the deformable substrate; and C) tracing out one or more lines, one or more vias, or any combination of one or more lines and one or more vias to form an interconnect between the first circuit component and the second circuit component using any composition disclosed herein.

Implementation 57. The method of Implementation 56, wherein the electronic device is a display.

Implementation 58. The method of Implementation 56 or 57, wherein the first circuit component and the second circuit component form part of an active-matrix array.

Implementation 59. The method of any one of Implementations 56-58, wherein the interconnect is free of degradation in conductivity when the deformable substrate is bent around a cylinder that has a radius of between 2 centimeters (cm) and 10 cm for a period of time and then released.

Implementation 60. The method of Implementation 59, wherein the period of time is between 10 seconds and five minutes.

Implementation 61. The method of any one of Implementations 56-60, wherein the first circuit component and the second circuit component are part of a transistor switch.

### CONCLUSION

It is understood that the examples and embodiments described herein are for illustrative purposes only and that various modifications or changes in light thereof will be suggested to persons skilled in the art and are to be included within the spirit and purview of this application and scope of the appended claims. All publications, patents, and patent applications cited herein are hereby incorporated by reference in their entirety for all purposes.

We claim:

1. A composition, comprising:
a solution comprising at least one solvent and a polymeric binder dissolved in the at least one solvent; and
a liquid metal mixed with the solution,
wherein the at least one solvent comprises a first solvent, the first solvent comprising: 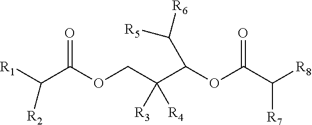
wherein R₁, R₂, R₃, R₄, R₅, R₆, R₇, and R₈ are each independently selected from substituted or unsubstituted alkyl, or substituted or unsubstituted heteroalkyl.

2. The composition of claim 1, wherein the first solvent comprises:

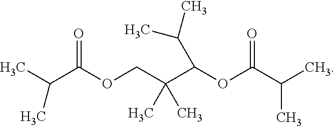 [SMILES: CC(C)C(=O)OCC(C)(C)C(OC(=O)C(C)C)C(C)C]

3. The composition of claim 1, wherein the at least one solvent comprises a second solvent, wherein the second solvent is toluene, THF, cycolohexane, xylene, decane, or octyle acelate.

4. The composition of claim 3, wherein the at least one solvent comprises the first solvent at an amount from about 3% to about 5%, from about 5% to 10%, from about 10% to 20%, from about 30% to 40%, from about 40% to 50%, or more than 50% by volume.

5. The composition of claim 4, wherein the first solvent is TXIB, the second solvent is toluene, and TXIB is at an amount from about 2% to about 5%, from about 5% to 10%, or from about 10% to 20% by volume of toluene.

6. The composition of claim 1, wherein the polymeric binder comprises styrene isoprene styrene (SIS), styrene ethylene butylene styrene (SEBS), silicones or a combination thereof.

7. The composition of claim 1, wherein the solution comprises the polymeric binder at an amount from about 10% to about 20% by weight of the solution.

8. The composition of claim 1, wherein the composition comprises the liquid metal at an amount from about 50% to about 60%, from about 60% to about 70%, from about 70% to about 80%, or from about 80% to about 90% by weight of the composition.

9. The composition of claim 1, wherein the liquid metal is a Ga-based alloy.

10. The composition of claim 9, wherein the Ga-based alloy comprises gallium at an amount of from about 50 wt % to about 55 wt %, from about 55 wt % to about 60 wt %, from about 60 wt % to about 65 wt %, from about 65 wt % to about 70 wt %, from about 70 wt % to about 80 wt %, or from about 80 wt % to about 85 wt % with respect to the Ga-based alloy.

11. The composition of claim 9, wherein the Ga-based alloy comprises at least one of gallium indium alloy, gallium tin alloy, gallium indium tin alloy, or gallium indium tin zinc alloy.

12. The composition of claim 1, further comprising a metallic filler mixed with the solution in a form of microflakes, nanoflakes, microparticles, nanoparticles, nanowires, nanotubes, or a combination thereof.

13. The composition of claim 12, wherein the metallic filler is at an amount from about 10% to about 20%, from about 20% to 30%, from about 30% to about 40%, or from about 40% to about 50% by weight of the liquid metal.

14. The composition of claim 12, wherein the metallic filler comprises silver, copper, gold, platinum, titanium, nitinol, or any combination thereof.

15. A method of manufacturing an electronic device comprising:
forming a first circuit component at a first portion of a deformable substrate;
forming a second circuit component at a second portion of the deformable substrate;
tracing out a line or via that couples the first circuit component and second circuit component, with a composition of (i) a solution with a polymeric binder dissolved in at least one solvent and (ii) a liquid metal, wherein
the polymeric binder comprises a first polymer, the first polymer comprising: 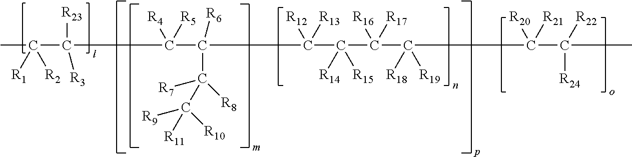
l, m, n, p, and o are the same or different and are each a positive integer;
R₁, R₂, R₃, R₄, R₅, R₆, R₇, R₈, R₉, R₁₀, R₁₁, R₁₂, R₁₃, R₁₄, R₁₅, R₁₆, R₁₇, R₁₈, R₁₉, R₂₀, R₂₁, and R₂₂ are each independently hydrogen, halogen, or hydroxyl; and
R₂₃, and R₂₄ are each independently substituted or unsubstituted aryl, or substituted or unsubstituted heteroaryl; and wherein
subsequent to the tracing, the first polymer polymerizes thereby forming the line or via that couples, and electrically connects, the first circuit component and second circuit component.

16. The method of claim 15, wherein the first polymer comprises:

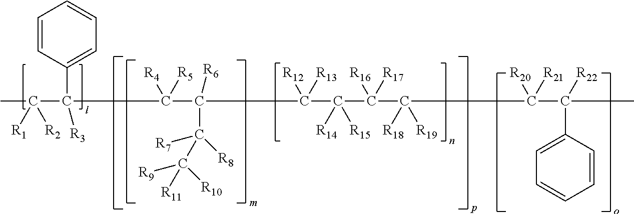

17. The method of claim 15, wherein the first polymer, at the time of tracing, has a molecular weight of greater than 50 kg/mol, greater than about 100 kg/mol, greater than about 150 kg/mol, greater than about 200 kg/mol, greater than about 250 kg/mol, greater than about 300 kg/mol, greater than about 350 kg/mol, or greater than about 400 kg/mol.

18. The method of claim 15, wherein, at a time during the tracing:
a styrene content in the first polymer is from about 10 wt % to about 15 wt %, from about 15 wt % to about 20 wt %, from about 25 wt % to about 30 wt %, from about 30 wt % to about 35 wt %, from about 35 wt % to about 40 wt %, or from about 40 wt % to about 45 wt %; or
a styrene block in the first polymer has a molar mass of less than about 50 kg/mol, less than about 45 kg/mol, less than about 40 kg/mol, less than about 35 kg/mol, less than about 30 kg/mol, less than about 25 kg/mol, less than about 20 kg/mol, less than about 15 kg/mol, less than about 10 kg/mol, or less than about 8 kg/mol.

19. The method of claim 15, wherein, at a time during the tracing, an ethylene/butylene ratio in the first polymer is from about 2:10 to about 3:10, from about 3:10 to about 4:10, from about 4:10 to about 5:10, from about 5:10 to about 6:10, or from about 6:10 to about 7:10.

20. The method of claim 15, wherein the polymeric binder comprises a second polymer, and the second polymer is cellulose, poly(vinyl alcohol), poly(acrylic acid), polyvinylidene fluoride, polyvinyl acetate-polyvinylpyrrolidone, poly(ethylene glycol), amine, silicone, styrene isoprene styrene (SIS), styrene ethylene, or any combination thereof.
